(19) United States
(12) Patent Application Publication
(10) Pub. No.: US 2026/0333888 A1
(43) Pub. Date: Oct. 22, 2026

(54) OPTOELECTRONIC SYSTEM, METHODS OF FORMING AND OPERATING THE SAME

(71) Applicant: Nanyang Technological University, Singapore (SG)

(72) Inventors: Fakun Wang, Singapore (SG); Fangchen Hu, Singapore (SG); Mingjin Dai, Singapore (SG); Qijie Wang, Singapore (SG)

(21) Appl. No.: 19/115,008

(22) PCT Filed: Sep. 21, 2023
(86) PCT No.: PCT/SG2023/050639

§ 371 Date: Mar. 25, 2025

(30) Foreign Application Priority Data
Oct. 25, 2022 (SG) 10202251479R

(51) Int. Cl. H10F 30/222; G06N 3/049; G06N 3/067; H10F 77/00; H10F 77/12; H10F 77/121

(52) U.S. Cl. CPC H10F 30/222; G06N 3/049; G06N 3/0675; H10F 77/12; H10F 77/1215; H10F 77/933

(57) ABSTRACT

Various embodiments may relate to an optoelectronic system. The optoelectronic system may include an optoelectronic device for receiving a first electromagnetic wave of a first wavelength and a second electromagnetic wave of a second wavelength. The optoelectronic device may include a substrate. The optoelectronic device may also include a first contact electrode and a second contact electrode over the substrate. The optoelectronic device may additionally include a first two-dimensional van der Waal material layer in contact with the first contact electrode, and a second two-dimensional van der Waal material layer in contact with the second contact electrode, the second two-dimensional van der Waal material layer also forming a heterojunction with the first two-dimensional van der Waal material layer. The optoelectronic system may further include a neural network for identifying or determining an object providing or transmitting the first electromagnetic wave. The neural network may be coupled to the optoelectronic device.

### CROSS-REFERENCE TO RELATED APPLICATION

This application claims the benefit of priority of Singapore Application No. 10202251479R filed Oct. 25, 2022, the contents of it being hereby incorporated by reference in its entirety for all purposes.

### TECHNICAL FIELD

Various embodiments of this disclosure may relate to an optoelectronic system. Various embodiments of this disclosure may relate to a method of forming an optoelectronic system. Various embodiments of this disclosure may relate to a method of operating an optoelectronic system.

### BACKGROUND

Infrared machine vision (IRMV) that can efficiently perceive, convert, and process a massive amount of infrared information of the observed objects has become an important technology for various scenarios requiring crucial decisions, which include autonomous driving, intelligent night vision, military defense and medical diagnosis. The current IRMV systems usually rely on physically separated infrared imaging devices and von-Neumann computing architectures to perform real-time information perception and processing, respectively. This system generates large amounts of redundant data being exchanged between sensory terminals and processing units, resulting in high data latency, large computing load and low energy efficiency. The lack of compactness and computing efficiency are rapidly making the existing system obsolete in the era of big data and the internet of things.

In contrast to the inefficient IRMV system, the human visual system includes very compact retina that can perceive, encode and process a huge visual dataset by harnessing distributed and parallel neural networks. Real-world visual information is received by the retina in the form of continuous light stimuli, which are encoded as discrete spike trains generated via a set of neural algorithms. The encoded electrical signals are subsequently transmitted to the visual cortex of the brain for information processing. The discretization and stochasticity of spike-encoded information allow long-distance communication and efficient neural computation. It may be highly desirable to have the perception and encoding of external optical stimuli integrated in one neuromorphic device, based on the structural and operating mechanism of the human retina, for realizing a compact, efficient, and intelligent IRMV.

### SUMMARY

Various embodiments may provide an optoelectronic system. The optoelectronic system may include an optoelectronic device for receiving a first electromagnetic wave of a first wavelength and a second electromagnetic wave of a second wavelength. The optoelectronic device may include a substrate. The optoelectronic device may also include a first contact electrode over the substrate. The optoelectronic device may further include a second contact electrode over the substrate. The optoelectronic device may additionally include a first two-dimensional van der Waal (vdW) material layer in contact with the first contact electrode. The optoelectronic device may also include a second two-dimensional van der Waal (vdW) material layer in contact with the second contact electrode, the second two-dimensional van der Waal material layer also forming a heterojunction with the first two-dimensional van der Waal material layer. The optoelectronic system may further include a neural network for identifying or determining an object providing or transmitting the first electromagnetic wave. The neural network may be coupled to the optoelectronic device.

Various embodiments may provide a method of forming an optoelectronic system. The method may include providing an optoelectronic device for receiving a first electromagnetic wave of a first wavelength and a second electromagnetic wave of a second wavelength. The optoelectronic device may include a substrate. The optoelectronic device may also include a first contact electrode over the substrate. The optoelectronic device may further include a second contact electrode over the substrate. The optoelectronic device may additionally include a first two-dimensional van der Waal (vdW) material layer in contact with the first contact electrode. The optoelectronic device may also include a second two-dimensional van der Waal (vdW) material layer in contact with the second contact electrode, the second two-dimensional van der Waal material layer also forming a heterojunction with the first two-dimensional van der Waal material layer. The method may also include coupling a neural network for identifying or determining an object providing or transmitting the first electromagnetic wave to the optoelectronic device.

Various embodiments may provide a method of operating an optoelectronic system. The method may include providing a first electromagnetic wave of a first wavelength and a second electromagnetic wave of a second wavelength different from the first wavelength to an optoelectronic device. The optoelectronic device may include a substrate. The optoelectronic device may also include a first contact electrode over the substrate. The optoelectronic device may further include a second contact electrode over the substrate. The optoelectronic device may additionally include a first two-dimensional van der Waal (vdW) material layer in contact with the first contact electrode. The optoelectronic device may also include a second two-dimensional van der Waal (vdW) material layer in contact with the second contact electrode, the second two-dimensional van der Waal material layer also forming a heterojunction with the first two-dimensional van der Waal material layer. The optoelectronic system may also include a neural network for identifying or determining an object providing or transmitting the first electromagnetic wave. The neural network may be coupled to the optoelectronic device.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 is a general illustration of an optoelectronic system according to various embodiments.

FIG. 2 shows a general illustration of a method of forming an optoelectronic system according to various embodiments.

FIG. 3 shows a general illustration of a method of forming an optoelectronic system according to various embodiments.

FIG. 4 shows (above) the implementation of perception, encoding and processing of stimulus signals from external objects in the human visual system; and (below) illustrates the optoelectronic system that can mimic the key functionalities according to various embodiments.

FIG. 5 shows morphology characterization and electrical properties of black phosphorus-arsenic (b-AsP): (a) a microscopic image of b-AsP according to various embodiments; (b) an atomic force microscopic (AFM) image of a two-dimensional (2D) b-AsP-based back-gate field-effect transistor according to various embodiments; (c) a plot of height (in nanometers or nm) as a function of distance (in micrometers or μm) illustrating the height profile of the 2D b-AsP flake according to various embodiments (thickness of ~26 nm); (d) a plot of the transduction current I_{DS} (in micro-Amperes or μA) as a function of source-drain voltage V_{DS} (in volts or V) illustrating the output characteristic curve of the 2D b-AsP-based transistor according to various embodiments (linear I_{DS}−V_{DS} indicates that Ohmic contact was formed between the 2D b-AsP flake and gold (Au) electrodes); and (e) a plot of the transduction current I_{DS} (in micro-Amperes or μA) as a function of gate voltage V_{GS} (in volts or V) illustrating the transfer characteristic curve of the 2D b-AsP-based transistor at V_{DS}=0.1 V according to various embodiments.

FIG. 6 shows morphology characterization and electrical properties of molybdenum (IV) telluride (MoTe₂): (a) a microscopic image of MoTe₂ according to various embodiments; (b) an atomic force microscopic (AFM) image of a two-dimensional (2D) MoTe₂-based back-gate field-effect transistor according to various embodiments; (c) a plot of height (in nanometers or nm) as a function of distance (in micrometers or μm) illustrating the height profile of the 2D MoTe₂ flake according to various embodiments (thickness of ~12 nm); (d) a plot of the transduction current I_{DS} (in nano-Amperes or nA) as a function of source-drain voltage V_{DS} (in volts or V) illustrating the output characteristic curve of the 2D MoTe₂-based transistor according to various embodiments (near linear I_{DS}−V_{DS} indicates that negligible Schottky barriers at the interface between 2D MoTe₂ flake and gold (Au) electrodes); and (e) a plot of the transduction current I_{DS} (in nano-Amperes or nA) as a function of gate voltage V_{GS} (in volts or V) illustrating the transfer characteristic curve of the 2D MoTe₂-based transistor at V_{DS}=0.1 V according to various embodiments.

FIG. 7 shows a plot of the transduction current I_{DS} (in nano-Amperes or nA) as a function of source-drain voltage V_{DS} (in volts or V) illustrating of the black phosphorus-arsenic/molybdenum (IV) telluride (b-AsP/MoTe₂) optoelectronic device according to various embodiments in dark, under mid-infrared (MIR) (4.6 μm) and under near-infrared (NIR) (730 nm).

FIG. 8 shows the characterizations and band alignments of the black phosphorus-arsenic/molybdenum (IV) telluride (b-AsP/MoTe₂) optoelectronic device according to various embodiments: (a) microscopic image of the b-AsP and MoTe₂ flakes placed on a silicon dioxide/silicon (SiO₂/Si) substrate according to various embodiments; (b) a plot of intensity (in arbitrary units or a.u.) as a function of Raman shift (per centimeter or cm⁻¹) illustrating the Raman spectra of MoTe₂ and b-AsP according to various embodiments; (c) a plot of transduction current I_{DS} (in micro-Amperes or μA/Amperes or A) as a function of source-drain voltage V_{DS} (in volts or V) illustrating the output characteristic curve of the b-AsP/MoTe₂ heterostructure according to various embodiments; (d) the band profiles of chromium (Cr), MoTe₂ and b-AsP before contact; and (e) band alignment of the b-AsP/MoTe₂ heterostructure according to various embodiments at different biasing voltages according to various embodiments.

FIG. 9 shows the photothermoelectric (PTE) response characteristics of the black phosphorus-arsenic/molybdenum (IV) telluride (b-AsP/MoTe₂) optoelectronic device according to various embodiments under 4.6 μm laser illumination: (a) a plot of transduction current I_{DS} (in micro-Amperes or μA) as a function of source-drain voltage V_{DS} (in volts or V) illustrating the output characteristics of the optoelectronic device according to various embodiments in dark and under illumination with power densities ranging from 0.56 to 80.21 W cm⁻²; (b) a plot of transduction current I_{DS} (in nano-Amperes or nA) as a function of source-drain voltage V_{DS} (in volts or V) showing a magnified view of the area enclosed by dotted lines in (a); (c) a plot of photocurrent (in nano-amperes or nA) as a function of source-drain voltage V_{DS} (in volts or V) illustrating the output characteristics of the optoelectronic device according to various embodiments at different power densities ((c) shows an independence of photocurrent on bias voltage, which is an important feature of photo thermoelectric effect); (d) a plot of photocurrent (in nano-amperes or nA) as a function of time (in seconds or s) illustrating the photoswitching response of the optoelectronic device according to various embodiments at V_{DS}=0V; (e) a plot of photocurrent Iₚₕ (in nano-Amperes or nA) as a function of power density (in Watts per square centimeter or W/cm²) illustrating a relationship of Iₚₕ=4.72×P^{0.66} according to various embodiments; and (f) the band diagram of the optoelectronic device according to various embodiments under mid-infrared (MIR) laser illumination at V_{DS}=0V.

FIG. 10 shows the photovoltaic (PV) response characteristics of the b-AsP/MoTe₂ optoelectronic device according to various embodiments under 730 nm laser illumination: (a) a plot of transduction current I_{DS} (in micro-Amperes or μA) as a function of source-drain voltage V_{DS} (in volts or V) illustrating the output characteristics of the optoelectronic device according to various embodiments in dark and under illumination with power densities ranging from 28.01 mW cm⁻² to 226.64 mW cm⁻²; (b) a plot of transduction current I_{DS} (in nano-Amperes or nA) as a function of source-drain voltage V_{DS} (in volts or V) showing a magnified view of the area enclosed by dotted lines in (a); (c) a plot of short current I_{SC} (in nano-Amperes or nA) as a function of power density (in milli-Watts per square centimeter or mW/cm²) illustrating the dependence of short-circuit current (I_{SC}) and open-circuit voltage (V_{OC}) on the power density according to various embodiments; (d) a plot of output electrical power Pet (in nano-Watts or nW) as a function of source-drain voltage V_{DS} (in volts or V) illustrating the variation of Pₑₗ as a function of the applied bias V_{DS} at different power densities according to various embodiments; (e) a plot of fill factor FF/power conversion efficiency PCE (in percent or %) illustrating the variation of FF and PCE with power density according to various embodiments; and (f) band diagrams of the optoelectronic device according to various embodiments under 730 nm laser illumination at V_{DS}=0V.

FIG. 11A shows the band schematic of the photothermoelectric (PTE) mode and the photovoltaic (PV) mode for perceiving mid-infrared (MIR) and near-infrared (NIR) respectively according to various embodiments.

FIG. 11B shows a plot of transduction current I_{DS} (in nano-Amperes or nA) as a function of time (in milliseconds or ms) illustrating time resolved I_{DS} of the optoelectronic device according to various embodiments under illumination with mid-infrared (MIR) and near-infrared (NIR) as well as simultaneous illumination of both MIR and NIR.

FIG. 12 shows transient behaviors and speed characteristics of the b-AsP/MoTe₂ optoelectronic device according to various embodiments under 4.6 μm laser illumination: (a) a plot of current (in nano-Amperes or nA) as a function of time (in milliseconds or ms) illustrating the transient photoresponse of the optoelectronic device according to various embodiments under pulsed 4.6 μm laser illumination with the frequency of 100 Hz; (b) a plot of current (in nano-Amperes or nA) as a function of time (in milliseconds or ms) illustrating the transient photoresponse of the optoelectronic device according to various embodiments under pulsed 4.6 μm laser illumination with the frequency of 2000 Hz; (c) a plot of current (in nano-Amperes or nA) as a function of time (in milliseconds or ms) illustrating the transient photoresponse of the optoelectronic device according to various embodiments under pulsed 4.6 μm laser illumination with the frequency of 3000 Hz; and (d) a plot of current (in nano-Amperes or nA) as a function of time (in milliseconds or ms) illustrating the response rate of the optoelectronic device according to various embodiments with a rising time of τᵣ=20 μs and a decay of τ_{d}=20 μs.

FIG. 13 shows transient behaviors and speed characteristics of the b-AsP/MoTe₂ optoelectronic device according to various embodiments under 730 nm laser illumination: (a) a plot of current (in nano-Amperes or nA) as a function of time (in milliseconds or ms) illustrating the transient photoresponse of the optoelectronic device according to various embodiments under pulsed 730 nm laser illumination with the frequency of 100 Hz; (b) a plot of current (in nano-Amperes or nA) as a function of time (in milliseconds or ms) illustrating the transient photoresponse of the optoelectronic device according to various embodiments under pulsed 730 nm laser illumination with the frequency of 2000 Hz; (c) a plot of current (in nano-Amperes or nA) as a function of time (in milliseconds or ms) illustrating the transient photoresponse of the optoelectronic device according to various embodiments under pulsed 730 nm laser illumination with the frequency of 3000 Hz; and (d) a plot of voltage (in volts or V) as a function of time (in milliseconds or ms) illustrating the response rate of the optoelectronic device according to various embodiments with a rising time of τᵣ=20 μs and a decay of τ_{d}=20 μs.

FIG. 14 shows a plot of noise current (in square Amperes per Hertz or A²/Hz) as a function of frequency (in Hertz or Hz) illustrating to noise characteristics of the b-AsP/MoTe₂ optoelectronic device according to various embodiments at a source-drain voltage V_{DS}=0V. It is observed that the noise of the heterostructure is dominated by flicker (1/f) noise, which is attributed to the trapping and detrapping of charge carriers.

FIG. 15 shows photodetection performance of the optoelectronic device according to various embodiments under 4.6 μm laser illumination: (a) a plot of noise equivalent power NEP (in picoWatts per square root Hertz or pW Hz^{0.5}) as a function of power density (in Watts per square centimeter or W/cm²) of the optoelectronic device according to various embodiments at source-drain voltage V_{DS}=0V and frequency f=2000 Hz; and (b) a plot of responsivity (in milli-Amperes per Watt or mA/W)/detectivity (in centimeter square root Hertz per Watt or cm·Hz^{0.5}/W) as a function of power density (in Watts per square centimeter or W/cm²) illustrating the power density-dependent responsivity and detectivity of the optoelectronic device according to various embodiments at source-drain voltage V_{DS}=0V.

FIG. 16 shows photodetection performance of the optoelectronic device according to various embodiments under 730 nm laser illumination: (a) a plot of current (in nano-Amperes or nA) as a function of time (in seconds or s) illustrating the photoresponse switching behavior of the optoelectronic device according to various embodiments under illumination with various power densities; (b) a plot of noise equivalent power NEP (in picoWatts per square root Hertz or pW Hz^{-0.5}) as a function of power density (in watts per square centimeter or W/cm²) of the optoelectronic device according to various embodiments at source-drain voltage V_{DS}=0V and frequency f=2000 Hz; and (c) a plot of responsivity (in Amperes per Watt or A/W)/detectivity (×10¹¹, in centimeter square root Hertz per Watt or cm·Hz^{0.5}/W) as a function of power density (in milli-Watts per square centimeter or mW/cm²) illustrating the power density-dependent responsivity and detectivity of the optoelectronic device according to various embodiments for 730 nm illumination.

FIG. 17 shows the broadband mid-infrared (MIR) photoresponse characteristics of the optoelectronic device according to various embodiments at source-drain voltage V_{DS}=0V: (a) a plot of current (in nano-Amperes or nA) as a function of time (in seconds or s) illustrating the time-resolved photoresponse of the optoelectronic device according to various embodiments under illumination with various wavelengths from 4.5 to 7.7 μm; (b) a plot of photocurrent (in Nano-amperes or nA)/power density (in Watts per square centimeter or W/cm²) as a function of wavelength (in micrometers or μm) illustrating the photocurrent and laser power density of the optoelectronic device according to various embodiments corresponding to each wavelength; (c) a plot of responsivity (in milli-Amperes per Watt or mA/W) as a function of wavelength (in micrometers or μm) illustrating the wavelength-dependent responsivity of the optoelectronic device according to various embodiments; and (d) a plot of noise equivalent power NEP (in picoWatts per square root Hertz or pW Hz^{-0.5})/detectivity (×10⁹, in centimeter square root Hertz per Watt or cm·Hz^{0.5}/W) as a function of wavelength (in micrometers or μm) illustrating variation of NEP and detectivity of the optoelectronic device according to various embodiments with wavelength.

FIG. 18 shows the reliability of the b-AsP/MoTe₂ optoelectronic device according to various embodiments under simultaneous illumination of both 4.6 μm and 730 nm: (a) illumination conditions (left) and corresponding current (in nano-Amperes or nA)-time (in milliseconds or ms) curves (right) when the 4.6 μm illumination is at 0.56 W/cm²; (b) illumination conditions (left) and corresponding current (in nano-Amperes or nA)-time (in milliseconds or ms) curves (right) when the 4.6 μm illumination is at 43.80 W/cm²; and (c) illumination conditions (left) and corresponding current (in nano-Amperes or nA)-time (in milliseconds or ms) curves (right) when the 4.6 μm illumination is at 80.21 W/cm².

FIG. 19 shows a plot of transduction current I_{DS} (in nano-Amperes or nA) as a function of mid-infrared power density P_{MIR} (in Watts per square centimeter or W/cm²) illustrating the dependence of output current of the optoelectronic device according to various embodiments on the MIR power density under the modulation of near-infrared (NIR light) with various power densities (P_{NIR}, in milli-Watts per square centimeter or mW/cm²).

FIG. 20A shows the measurement conditions of the optoelectronic device according to various embodiments, i.e. under simultaneous illumination of 4.6 μm illumination and various power densities of 730 nm illumination.

FIG. 20B shows a plot of current (in nano-Amperes or nA) as a function of time (in milliseconds or ms) illustrating the photoresponse of the optoelectronic device according to various embodiments under 0.56 W/cm² of 4.6 μm illumination and various power densities of 730 nm illumination.

FIG. 20C shows a plot of current (in nano-Amperes or nA) as a function of time (in milliseconds or ms) illustrating the photoresponse of the optoelectronic device according to various embodiments under 9.23 W/cm² of 4.6 μm illumination and various power densities of 730 nm illumination.

FIG. 20D shows a plot of current (in nano-Amperes or nA) as a function of time (in milliseconds or ms) illustrating the photoresponse of the optoelectronic device according to various embodiments under 21.01 W/cm² of 4.6 μm illumination and various power densities of 730 nm illumination.

FIG. 20E shows a plot of current (in nano-Amperes or nA) as a function of time (in milliseconds or ms) illustrating the photoresponse of the optoelectronic device according to various embodiments under 31.58 W/cm² of 4.6 μm illumination and various power densities of 730 nm illumination.

FIG. 20F shows a plot of current (in nano-Amperes or nA) as a function of time (in milliseconds or ms) illustrating the photoresponse of the optoelectronic device according to various embodiments under 43.80 W/cm² of 4.6 μm illumination and various power densities of 730 nm illumination.

FIG. 20G shows a plot of current (in nano-Amperes or nA) as a function of time (in milliseconds or ms) illustrating the photoresponse of the optoelectronic device according to various embodiments under 56.40 W/cm² of 4.6 μm illumination and various power densities of 730 nm illumination.

FIG. 20H shows a plot of current (in nano-Amperes or nA) as a function of time (in milliseconds or ms) illustrating the photoresponse of the optoelectronic device according to various embodiments under 69.26 W/cm² of 4.6 μm illumination and various power densities of 730 nm illumination.

FIG. 20I shows a plot of current (in nano-Amperes or nA) as a function of time (in milliseconds or ms) illustrating the photoresponse of the optoelectronic device according to various embodiments under 80.21 W/cm² of 4.6 μm illumination and various power densities of 730 nm illumination.

FIG. 21 is a plot of spiking threshold P_{MIR-ST} (in Watts per square centimeters or W/cm²) and a function of mid-infrared power density P_{MIR} (in milli-Watts per square centimeter or mW/cm²) illustrating the different P_{MIR-ST}−P_{MIR} at different threshold currents (I_{TC}, in nano-Amperes or nA) according to various embodiments.

FIG. 22A shows (above) one trail of near infrared (NIR) optical pulses (32 pulses for one trail) that is randomly sampled from a Gaussian distribution according to various embodiments for spike rate encoding; and (below) the Gaussian distribution of NIR power densities with mean of u=127.32 mW cm⁻² and a standard deviation of σ=63.66 mW cm⁻² according to various embodiments.

FIG. 22B shows plots of mid-infrared power density P_{MIR} (in Watts per square centimeter or mW/cm²) as a function of time (in milliseconds or ms) illustrating the analog values of various intensities of mid-infrared (MIR) illumination according to various embodiments.

FIG. 22C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 22B according to various embodiments.

FIG. 22D shows a plot of spike as a function of time (in milliseconds or ms) illustrating the corresponding spike train for each transduction current (I_{DS}) waveform in FIG. 22C when the spike threshold current (I_{TC}) is set to −6 nA according to various embodiments.

FIG. 22E shows a plot of mean spike rate (in kilo-Hertz or kHz) as a function of mid-infrared power density P_{MIR} (in Watts per square centimeter or W/cm²) of the optoelectronic device according to various embodiments when mean (u)=127.32 mW cm⁻², standard deviation (σ)=63.66 mW and threshold current (I_{TC})=−6 nA.

FIG. 23A shows plots of spike rate (in kilo-Hertz or kHz) as a function of mid-infrared power density P_{MIR} (in Watts per square centimeter or W/cm²) illustrating the simulation of spike rate with P_{MIR} for different mean (u), standard deviation (σ) and threshold current (I_{TC}) of the Gaussian distribution of sampling 730 nm light according to various embodiments. Clipping operation on the power density of 730 nm laser is essential to avoid excessive heat effect on the device.

FIG. 23B shows plots of spike rate (in kilo-Hertz or kHz) as a function of mid-infrared power density P_{MIR} (in Watts per square centimeter or W/cm²) illustrating the clipping operation on dynamic working range according to various embodiments.

FIG. 24A is a schematic showing a testing setup to evaluate perception and encoding ability of the optoelectronic device according to various embodiments.

FIG. 24B shows a photocurrent map illustrating the mid-infrared power densities (P_{MIR}) of the nine targets according to various embodiments.

FIG. 24C shows an encoded image after encoding the mid-infrared power densities (PMI) of the nine targets in FIG. 24B into corresponding spike rates ranging from 0 kHz to 2 KHz according to various embodiments.

FIG. 24D shows plots of spike rate (in kilo-Hertzs or kHz) as a function of mid-infrared power density P_{MIR} (in Watts per square centimeters or W/cm²) illustrating experimental results of spike rate P_{MIR} with different means u and standard deviations σ according to various embodiments.

FIG. 25A shows plots of standard deviation σ (in milli-Watts per square centimeters or mW/cm²) as a function of mean u (in milli-Watts per square centimeters or mW/cm²) illustrating results of encoding images under different sets of u and σ according to various embodiments.

FIG. 25B illustrates the correlation coefficients (CC) between the results in FIG. 25A and the corresponding results in FIG. 24B for different cases of mean u and standard deviation σ according to various embodiments, with the insets being the images of targets (ii) and (ix).

FIG. 26A shows the mid-infrared (MIR) image being perceived and rate-based encoded into spike trains which enter a trained fully-connected spiking neural network (SNN) to realize digit classification task according to various embodiments.

FIG. 26B illustrates the leaky integrate-and-fire (LIF) neuron model used in the spiking neural network (SNN) according to various embodiments.

FIG. 26C is a plot of accuracy (in percent or %) as a function of maximum power density Pₘₐₓ (in Watts per square centimeter or W/cm²) illustrating variation of accuracy with Pₘₐₓ at various standard deviations σ according to various embodiments.

FIG. 26D is a plot of accuracy (in percent or %) as a function of maximum power density Pₘₐₓ (in Watts per square centimeter or W/cm²) illustrating variation of accuracy with Pₘₐₓ at various means u according to various embodiments.

FIG. 26E shows a plot of accuracy (in percent or %) as a function of time steps illustrating the classification accuracy of the spiking neural network (SNN) according to various embodiments versus the time steps of one spike train when Pₘₐₓ is 31.83 W cm⁻², with insets (i)-(iii) showing the encoded images of “3” when the time steps are 1, 2 and 10, respectively.

FIG. 27 shows a plot of accuracy (in percent or %) as a function of mid-infrared power density P_{MIR} (in Watts per square centimeters or W/cm²) illustrating the classification accuracy distribution at different number of sampling points for low encoding precision cases according to various embodiments.

FIG. 28 shows (a) a plot of accuracy (in percent or %) as a function of hidden neurons illustrating dependence of accuracy on hidden neurons in an ideal linear encoder and the spiking neural network (labelled as “our encoder”) according to various embodiments for data set with maximum power density Pₘₐₓ of 59.30 W cm⁻²; (b) a plot of accuracy (in percent or %) as a function of membrane potential decay rate (β) illustrating dependence of accuracy on β in an ideal conventional linear encoder and the spiking neural network (labelled as “our encoder”) according to various embodiments for data set with maximum power density Pₘₐₓ of 59.30 W cm⁻²; and (c) a plot of loss as a function of iteration illustrating cross-entropy loss of the spiking neural network according to various embodiments versus iteration of the train and test sets.

FIG. 29 shows another optoelectronic system that can mimic the key functionalities according to various embodiments.

FIG. 30 shows (a) a plot of the transduction current I_{DS} (in micro-Amperes or p A) as a function of source-drain voltage V_{DS} (in volts or V) illustrating the output characteristic curve of a two-dimensional (2D) black phosphorus-arsenic (b-AsP)-based transistor according to various embodiments (linear I_{DS}−V_{DS} indicates that Ohmic contact was formed between the 2D b-AsP flake and gold (Au) electrodes); and (b) a plot of the transduction current I_{DS} (in micro-Amperes or μA) as a function of gate voltage V_{GS} (in volts or V) illustrating the transfer characteristic curve of the 2D b-AsP-based transistor at V_{DS}=0.1 V according to various embodiments.

FIG. 31 shows the temperature dependent characteristics of the black phosphorus-arsenic (b-AsP)-based transistor according to various embodiments: (a) a plot of transduction current I_{DS} (in micro-Amperes or μA) as a function of source-drain voltage V_{DS} (in volts or V) illustrating I_{DS}−V_{DS} curves of the transistor according to various embodiments at different temperatures; (b) a plot of the transduction current I_{DS} (in micro-Amperes or μA) as a function of gate voltage V_{GS} (in volts or V) illustrating I_{DS}−V_{GS} curves of the transistor according to various embodiments at different temperatures; (c) an Arrhenius plot of the black phosphorus-arsenic (b-AsP)/gold (Au) contact according to various embodiments; and (d) a plot of the Schottky barrier height Φ_{SB} (in milli-electron-volts or meV) as a function of gate voltage V_{GS} (in volts or V) illustrating the variation of extracted barrier height of the black phosphorus-arsenic (b-AsP)/gold (Au) contact according to various embodiments.

FIG. 32 shows (a) a plot of the transduction current I_{DS} (in micro-Amperes or μA) as a function of source-drain voltage V_{DS} (in volts or V) illustrating the output characteristic curve of a two-dimensional (2D) molybdenum (IV) telluride (MoTe₂)-based transistor according to various embodiments (near linear I_{DS}−V_{DS} indicates that negligible Schottky barriers at the interface between 2D MoTe₂ flake and gold (Au) electrodes); and (b) a plot of the transduction current I_{DS} (in micro-Amperes or μA) as a function of gate voltage V_{GS} (in volts or V) illustrating the transfer characteristic curve of the transistor according to various embodiments which features a p-type behavior with a mobility of ~15 cm² V⁻¹ s⁻¹ at room temperature.

FIG. 33 shows the temperature dependent characteristics of the molybdenum (IV) telluride (MoTe₂)-based transistor according to various embodiments: (a) a plot of transduction current I_{DS} (in micro-Amperes or μA) as a function of source-drain voltage V_{DS} (in volts or V) illustrating I_{DS}−V_{DS} curves of the transistor according to various embodiments at different temperatures; (b) a plot of the transduction current I_{DS} (in micro-Amperes or μA) as a function of gate voltage V_{GS} (in volts or V) illustrating I_{DS}−V_{GS} curves of the transistor according to various embodiments at different temperatures; (c) an Arrhenius plot of the molybdenum (IV) telluride (MoTe₂)/gold (Au) contact according to various embodiments; and (d) a plot of the Schottky barrier height Φ_{SB} (in milli-electron-volts or meV) as a function of gate voltage V_{GS} (in volts or V) illustrating the variation of extracted barrier height of the molybdenum (IV) telluride (MoTe₂)/gold (Au) contact according to various embodiments with V_{DS}.

FIG. 34 shows the rectification characterizations and band alignments of the black phosphorus-arsenic/molybdenum (IV) telluride (b-AsP/MoTe₂) optoelectronic device (optoelectronic device 1) according to various embodiments: (a) a microscopic image of the heterostructure encapsulated by a hexagonal-boron nitride (h-BN) flake according to various embodiments; (b) a schematic of the black phosphorus-arsenic/molybdenum (IV) telluride (b-AsP/MoTe₂) optoelectronic device according to various embodiments; (c) a plot of transduction current I_{DS} (in micro-Amperes or μA/Amperes or A) as a function of source-drain voltage V_{DS} (in volts or V) illustrating the output characteristic curve of the b-AsP/MoTe₂ heterostructure according to various embodiments; (d) the band profiles of gold (Au), MoTe₂ and b-AsP before contact (the curve shows a rectification characteristic); and (e) band alignment of the b-AsP/MoTe₂ heterostructure according to various embodiments at different biasing voltages according to various embodiments.

FIG. 35A shows (left) a microscopic image of optoelectronic device 1 according to various embodiments; (middle) a magnified portion including a junction between the black phosphorus-arsenic layer and the molybdenum (IV) telluride (b-AsP/MoTe₂) layer according to various embodiments; and (right) a plot of height (in nanometers or nm) as a function of position (in micrometers or μm) illustrating the height profile of the region indicated by the dashed line in the middle image according to various embodiments.

FIG. 35B shows (left) a microscopic image of optoelectronic device 4 according to various embodiments; (middle) a magnified portion including a junction between the black phosphorus-arsenic layer and the molybdenum (IV) telluride (b-AsP/MoTe₂) layer according to various embodiments; and (right) a plot of height (in nanometers or nm) as a function of position (in micrometers or μm) illustrating the height profile of the region indicated by the dashed line in the middle image according to various embodiments.

FIG. 35C shows microscopic images of optoelectronic devices 2, 3 and 5 according to various embodiments.

FIG. 36 shows the photoresponse characteristics of the optoelectronic device (optoelectronic device 1) according to various embodiments at drain-source voltage (V_{DS})=0V: (a) a plot of transduction current I_{DS} (in nano-Amperes or nA) as a function of time (in seconds or s) illustrating the near-infrared NIR (730 nm) photoresponse with negative photocurrent at different power densities according to various embodiments; (b) a plot of transduction current I_{DS} (in nano-Amperes or nA) as a function of time (in seconds or s) illustrating the mid-infrared MIR (4.6 μm) photoresponse with positive photocurrent at different power densities according to various embodiments; (c) a schematic illustrating the photoresponse mechanism of the device under NIR global illumination according to various embodiments; and (d) a schematic illustrating the photoresponse mechanism of the device under MIR global illumination according to various embodiments.

FIG. 37A shows (a) a microscopic image of optoelectronic device 1 according to various embodiments; (b) a corresponding photocurrent mapping of optoelectronic device 1 according to various embodiments; (c) a microscopic image of optoelectronic device 4 according to various embodiments; and (d) a corresponding photocurrent mapping of optoelectronic device 4 according to various embodiments.

FIG. 37B shows (left) a schematic for band alignment and photo-induced carriers flow direction of the black phosphorus-arsenic/molybdenum (IV) telluride (b-AsP/MoTe₂) optoelectronic device when laser is locally illuminated on the b-AsP/MoTe₂ junction according to various embodiments; and (right) a schematic for band alignment and photo-induced carriers flow direction of the black phosphorus-arsenic/molybdenum (IV) telluride (b-AsP/MoTe₂) optoelectronic device when laser is locally illuminated on the b-AsP/metal junction according to various embodiments.

FIG. 38A shows (left) the black phosphorus-arsenic (b-AsP) device structure for thermoelectric measurement according to various embodiments; and (right) a plot of resistance (in Ohms or Ω) as a function of temperature (in Kelvins or K) illustrating the temperature-dependent resistance of thermometer-1 and thermometer-2 according to various embodiments.

FIG. 38B shows (left) a plot of voltage drop ΔV (in milli-Volts or mV) as a function of heater power (in milli-Watts or mW) illustrating ΔV across black phosphorus-arsenic (b-AsP) and the resistance change (ΔR) of the two thermometers at different heater powers according to various embodiments; and (right) a plot of voltage drop ΔV (in milli-Volts or mV) as a function of temperature difference ΔT (in Kelvins or K) between the two thermometers according to various embodiments.

FIG. 39A shows the molybdenum (IV) telluride (MoTe₂) device structure for thermoelectric measurement according to various embodiments.

FIG. 39B shows (left) a plot of voltage drop ΔV (in milli-Volts or mV) as a function of heater power (in milli-Watts or mW) illustrating ΔV across molybdenum (IV) telluride (MoTe₂) and the resistance change (ΔR) of the two thermometers at different heater powers according to various embodiments; and (right) a plot of voltage drop ΔV (in milli-Volts or mV) as a function of temperature difference ΔT (in Kelvins or K) between the two thermometers according to various embodiments.

FIG. 40A shows (left) a plot of intensity (in arbitrary units or a.u.) as a function of Raman shift (per centimeter or cm⁻¹) illustrating the Raman spectra of black phosphorus-arsenic (b-AsP) according to various embodiments at different temperatures; and (right) a plot of intensity (in arbitrary units or a.u.) as a function of Raman shift (per centimeter or cm⁻¹) illustrating the Raman spectra of black phosphorus-arsenic (b-AsP) according to various embodiments at different power densities.

FIG. 40B shows (left) a plot of A_{g}¹ position (per centimeter or cm⁻¹) as a function of temperature (in Kelvins or K) illustrating variation of the A_{g}¹ peak position with temperature according to various embodiments; (middle) a plot of A_{g}¹ position (per centimeter or cm⁻¹) as a function of incident power (in milli-Watts or mW) illustrating variation of the A_{g}¹ peak position with incident power according to various embodiments; and (right) a plot of temperature (in Kelvins or K) as a function of incident power (in milli-Watts or mW) illustrating the estimated local temperature in black phosphorus-arsenic (b-AsP) according to various embodiments based on the relationship shown in the left and middle plots.

FIG. 41A shows (left) a schematic of photo-Seebeck coefficient measurement setup according to various embodiments; and (right) a plot of photo-induced thermal voltage Vₚₕ (in milli-Volts or mV) as a function of time (in seconds or s) illustrating time-resolved Vₚₕ at different incident powers according to various embodiments.

FIG. 41B shows (left) a plot of photo-induced thermal voltage (Vₚₕ) (in milli-Volts or mV) as a function of incident power (in milli-Watts or mW) according to various embodiments; and (right) a plot of photo-induced thermal voltage (Vₚₕ) (in micro-Volts or μV) as a function of temperature difference (ΔT) (in Kelvins or K) induced by the focused laser illumination according to various embodiments.

FIG. 42A shows a plot of current (in arbitrary units or a.u.) as a function of time (in micro-seconds or μs) illustrating the photoresponse of the optoelectronic device (optoelectronic device 1) at drain-source voltage V_{DS}=0 V under mid-infrared (MIR) illumination according to various embodiments.

FIG. 42B shows a plot of current (in arbitrary units or a.u.) as a function of time (in micro-seconds or μs) illustrating the photoresponse of the optoelectronic device (optoelectronic device 1) at drain-source voltage V_{DS}=0 V under near-infrared (NIR) illumination according to various embodiments.

FIG. 43A shows (left) a plot of normalized photoresponse as a function of time (in microseconds or μs) showing the transient behaviors and speed characteristics of the optoelectronic device (optoelectronic device 1) according to various embodiments under 730 nm laser illumination at 2.5 kHz; (middle) a plot of normalized photoresponse as a function of time (in microseconds or μs) showing the transient behaviors and speed characteristics of the optoelectronic device (optoelectronic device 1) according to various embodiments under 730 nm laser illumination at 25 kHz; and (right) a plot of normalized photoresponse as a function of time (in microseconds or μs) showing a rising time of 600 ns and a decay time of 3.7 μs of the optoelectronic device (optoelectronic device 1) under 730 nm laser illumination according to various embodiments.

FIG. 43B shows (left) a plot of normalized photoresponse as a function of time (in milliseconds or ms) showing the transient behaviors and speed characteristics of the optoelectronic device (optoelectronic device 1) according to various embodiments under 4.6 μm illumination at 2 kHz; (middle) a plot of normalized photoresponse as a function of time (in milliseconds or ms) showing the transient behaviors and speed characteristics of the optoelectronic device (optoelectronic device 1) according to various embodiments under 4.6 μm illumination at 3 KHz; and (right) a plot of normalized photoresponse as a function of time (in milliseconds or ms) showing a rising time of 2.3 μs and a decay time of 20 μs of the optoelectronic device (optoelectronic device 1) under 4.6 μm illumination according to various embodiments.

FIG. 44 shows a plot of noise current (in square Amperes per Hertz or A²/Hz) as a function of frequency (in Hertz or Hz) illustrating the noise characteristics of the optoelectronic devices (optoelectronic devices 1-5) according to various embodiments at drain-source voltage V_{DS}=0 V.

FIG. 45A shows (top) a plot of transduction current I_{DS} (in nano-Amperes or nA) as a function of time (in seconds or s) illustrating the time-resolved photoresponse of optoelectronic device 1 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 1 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 1 according to various embodiments under 730 nm illumination with power density.

FIG. 45B shows (top) a plot of transduction current I_{DS} (in nano-Amperes or nA) as a function of time (in seconds or s) illustrating the time-resolved photoresponse of optoelectronic device 2 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 2 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 2 according to various embodiments under 730 nm illumination with power density.

FIG. 45C shows (top) a plot of transduction current I_{DS} (in nano-Amperes or nA) as a function of time (in seconds or s) illustrating the time-resolved photoresponse of optoelectronic device 3 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 3 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 3 according to various embodiments under 730 nm illumination with power density.

FIG. 45D shows (top) a plot of transduction current I_{DS} (in nano-Amperes or nA) as a function of time (in seconds or s) illustrating the time-resolved photoresponse of optoelectronic device 4 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 4 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 4 according to various embodiments under 730 nm illumination with power density.

FIG. 45E shows (top) a plot of transduction current I_{DS} (in nano-Amperes or nA) as a function of time (in seconds or s) illustrating the time-resolved photoresponse of optoelectronic device 5 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 5 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 5 according to various embodiments under 730 nm illumination with power density.

FIG. 46A shows (top) a plot of transduction current I_{DS} (in nano-Amperes or nA) as a function of time (in seconds or s) illustrating the time-resolved photoresponse of optoelectronic device 1 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 1 according to various embodiments under 4.6 μm illumination; and (bottom) a plot of noise equivalent power NEP (in pico-Watts per square root Hertz or pW Hz^{-0.5})/detectivity (×10⁹, in centimeter square root Hertz per Watt or cm·Hz^{0.5}/W) as a function of power density (in Watts per square centimeter or W/cm²) illustrating variation of NEP and detectivity of optoelectronic device 1 according to various embodiments under 4.6 μm illumination with power density.

FIG. 46B shows (top) a plot of transduction current I_{DS} (in nano-Amperes or nA) as a function of time (in seconds or s) illustrating the time-resolved photoresponse of optoelectronic device 2 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 2 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 2 according to various embodiments under 4.6 μm illumination with power density.

FIG. 46C shows (top) a plot of transduction current I_{DS} (in nano-Amperes or nA) as a function of time (in seconds or s) illustrating the time-resolved photoresponse of optoelectronic device 3 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 3 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 3 according to various embodiments under 4.6 μm illumination with power density.

FIG. 46D shows (top) a plot of transduction current I_{DS} (in nano-Amperes or nA) as a function of time (in seconds or s) illustrating the time-resolved photoresponse of optoelectronic device 4 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 4 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 4 according to various embodiments under 4.6 μm illumination with power density.

FIG. 46E shows (top) a plot of transduction current I_{DS} (in nano-Amperes or nA) as a function of time (in seconds or s) illustrating the time-resolved photoresponse of optoelectronic device 5 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 5 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 5 according to various embodiments under 4.6 μm illumination with power density.

FIG. 47 shows a table comparing the photoresponse performances of the 5 optoelectronic devices with various thicknesses according to various embodiments.

FIG. 48A shows (left) a plot of transduction current (in nano-Amperes or nA) as a function of time (in seconds or s) illustrating time-resolved photoresponse of optoelectronic device 1 according to various embodiments under 532 nm at various power densities; (middle) a plot of transduction current (in nano-Amperes or nA) as a function of time (in seconds or s) illustrating time-resolved photoresponse of optoelectronic device 1 according to various embodiments under 730 nm at various power densities; and (right) a plot of transduction current (in nano-Amperes or nA) as a function of time (in seconds or s) illustrating time-resolved photoresponse of optoelectronic device 1 according to various embodiments under 1470 nm at various power densities.

FIG. 48B shows (left) a plot of absolute (abs) photocurrent (in nanometers or nm) as a function of power density (in milli-Watts per square centimeter or mW/cm²) illustrating the power dependence of photocurrent of optoelectronic device 1 according to various embodiments; (middle) a plot of responsivity (in Amperes per Watt or A/W) as a function of power density (in milli-Watts per square centimeter or mW/cm²) illustrating the power dependence of responsivity of optoelectronic device 1 according to various embodiments; and (right) a plot of detectivity (×10¹¹, in centimeter square root Hertz per Watt or cm·Hz^{0.5}/W) as a function of power density (in milli-Watts per square centimeter or mW/cm²) illustrating the power dependence of detectivity of optoelectronic device 1 according to various embodiments.

FIG. 49A shows (left) a plot of transduction current I_{DS} (in nano-Amperes or nA) as a function of time (in seconds or s) illustrating time-resolved photoresponse of optoelectronic device 1 under illumination according to various embodiments with various wavelengths from 4.5 μm to 10.5 μm; and (right) a plot of photocurrent (in nano-Amperes or nA)/power density (in Watts per square centimeters or W/cm²) illustrating the photocurrent and power density corresponding to each wavelength according to various embodiments.

FIG. 49B shows (left) a plot of responsivity (in milli-Amperes per Watt or mA/W) as a function of wavelength (in micrometers or μm) illustrating the wavelength-dependent responsivity of optoelectronic device 1 according to various embodiments, and (right) noise equivalent power NEP (in picoWatts per square root Hertz or pW Hz^{-0.5})/detectivity (×10⁹, in centimeter square root Hertz per Watt or cm·Hz^{0.5}/W) as a function of wavelength (in micrometers or μm) illustrating variation of NEP and detectivity with wavelength according to various embodiments.

FIG. 50A shows (left) a plot of transduction current I_{DS} (in nano-Amperes or nA) as a function of time (in seconds or s) illustrating time-resolved photoresponse of optoelectronic device 1 according to various embodiments under 5.7 μm laser illumination with various power densities; (middle) a plot of transduction current I_{DS} (in nano-Amperes or nA) as a function of time (in seconds or s) illustrating time-resolved photoresponse of optoelectronic device 1 according to various embodiments under 7.3 μm laser illumination with various power densities; and (right) a plot of transduction current I_{DS} (in nano-Amperes or nA) as a function of time (in seconds or s) illustrating time-resolved photoresponse of optoelectronic device 1 according to various embodiments under 10.5 μm laser illumination with various power densities.

FIG. 50B shows (left) a plot of photocurrent (in nano-Amperes or nA) as a function of power density (in Watts per square centimeter or W/cm²) illustrating the power dependence of photocurrent of optoelectronic device 1 according to various embodiments; (middle) a plot of responsivity (in milli-Amperes per Watt or mA/W) as a function of power density (in Watts per square centimeter or W/cm²) illustrating the power dependence of responsivity of optoelectronic device 1 according to various embodiments; and (right) a plot of detectivity (×10⁹, in centimeter square root Hertz per Watt or cm·Hz^{0.5}/W) as a function of power density (in Watts per square centimeter or W/cm²) illustrating the power dependence of detectivity of the device according to various embodiments.

FIG. 51 shows (above) input as a function of time (in micro-seconds or μs) illustrating the input illumination provided to optoelectronic device 1 according to various embodiments as a function of time (in micro-seconds or μs); and (below) a plot of the transduction current I_{DS} (in nano-Amperes of nA) as a function of time (in micro-seconds or μs) of optoelectronic device 1 according to various embodiments under the input illumination. The power densities of MIR and NIR are indicated in the upper panel.

FIG. 52A shows the measurement conditions of optoelectronic device 1 according to various embodiments, i.e. under simultaneous illumination of 4.6 μm illumination and various power densities of 730 nm illumination.

FIG. 52B shows a plot of current (in nano-Amperes or nA) as a function of time (in milliseconds or ms) illustrating the photoresponse of optoelectronic device 1 according to various embodiments under 0.56 W/cm² of 4.6 μm illumination and various power densities of 730 nm illumination.

FIG. 52C shows a plot of current (in nano-Amperes or nA) as a function of time (in milliseconds or ms) illustrating the photoresponse of optoelectronic device 1 according to various embodiments under 9.23 W/cm² of 4.6 μm illumination and various power densities of 730 nm illumination.

FIG. 52D shows a plot of current (in nano-Amperes or nA) as a function of time (in milliseconds or ms) illustrating the photoresponse of optoelectronic device 1 according to various embodiments under 21.01 W/cm² of 4.6 μm illumination and various power densities of 730 nm illumination.

FIG. 52E shows a plot of current (in nano-Amperes or nA) as a function of time (in milliseconds or ms) illustrating the photoresponse of optoelectronic device 1 according to various embodiments under 31.58 W/cm² of 4.6 μm illumination and various power densities of 730 nm illumination.

FIG. 52F shows a plot of current (in nano-Amperes or nA) as a function of time (in milliseconds or ms) illustrating the photoresponse of optoelectronic device 1 according to various embodiments under 43.80 W/cm² of 4.6 μm illumination and various power densities of 730 nm illumination.

FIG. 52G shows a plot of current (in nano-Amperes or nA) as a function of time (in milliseconds or ms) illustrating the photoresponse of the optoelectronic device (optoelectronic device 1) according to various embodiments under 56.40 W/cm² of 4.6 μm illumination and various power densities of 730 nm illumination.

FIG. 52H shows a plot of current (in nano-Amperes or nA) as a function of time (in milliseconds or ms) illustrating the photoresponse of optoelectronic device 1 according to various embodiments under 69.26 W/cm² of 4.6 μm illumination and various power densities of 730 nm illumination.

FIG. 52I shows a plot of current (in nano-Amperes or nA) as a function of time (in milliseconds or ms) illustrating the photoresponse of optoelectronic device 1 according to various embodiments under 80.21 W/cm² of 4.6 μm illumination and various power densities of 730 nm illumination.

FIG. 53 shows a plot of transduction current I_{DS} (in nano-Amperes or nA) as a function of mid-infrared power density P_{MIR} (in Watts per square centimeter or W/cm²) illustrating the dependence of output current of the optoelectronic device (optoelectronic device 1) according to various embodiments on the MIR power density under the modulation of near-infrared (NIR light) with various power densities (P_{NIR}, in milli-Watts per square centimeter or mW/cm²).

FIG. 54 shows a plot of a plot of transduction current Is (in nano-Amperes or nA) as a function of time (in microseconds or μs) illustrating the fast response of the optoelectronic device (optoelectronic device 1) according to various embodiments under simultaneous illuminations of both 4.6 μm and 730 nm.

FIG. 55 shows (a) a plot of transduction current I_{DS} (in micro-Amperes or μA) as a function of gate voltage V_{GS} (in volts or V) illustrating the I_{DS}−V_{GS} curves of the optoelectronic device (optoelectronic device 1) according to various embodiments in the air and in vacuum at room temperature; (b) a plot of mobility μ(in square centimeter per volt-second or cm²/Vs) as a function of gate voltage V_{GS} (in volts or V) illustrating the as-calculated carrier mobility from (a), showing a negligible change from the air to a vacuum; (c) a plot of transduction current I_{DS} (in nano-Amperes or nA) as a function of time (in seconds or s) illustrating the photoresponse characteristics of the optoelectronic device (optoelectronic device 1) according to various embodiments at drain-source voltage V_{DS}=0V in air; and (d) a plot of transduction current I_{DS} (in nano-Amperes or nA) as a function of time (in seconds or s) illustrating the photoresponse characteristics of the optoelectronic device (optoelectronic device 1) according to various embodiments at drain-source voltage V_{DS}=0V in vacuum. The almost unchanged carrier mobility and photoresponse indicates that the h-BN-encapsulated b-AsP/MoTe₂ device possesses good stability.

FIG. 56 shows (a) a plot of transduction current I_{DS} (in micro-Amperes or μA) as a function of gate voltage V_{GS} (in volts or V) illustrating the I_{DS}−V_{GS} curves of the optoelectronic device (optoelectronic device 1) according to various embodiments at various temperatures from 300 K to 310 K; (b) a plot of mobility μ (in square centimeter per volt-second or cm²/Vs) as a function of gate voltage V_{GS} (in volts or V) illustrating the as-calculated carrier mobility from (a), showing little change from 300 K to 310 K; and (c) a plot of transduction current I_{DS} (in nano-Amperes or nA) as a function of time (in seconds or s) illustrating the photoresponse characteristics of the optoelectronic device (optoelectronic device 1) according to various embodiments at different temperatures, showing a slight decrease (<2 nA) with increasing temperatures from 300 K to 310 K.

FIG. 57A shows (above) one train of near infrared (NIR) optical pulses (100 time-steps (pulses) for one train) that is randomly sampled from a Gaussian distribution according to various embodiments for spike rate encoding; and (below) the Gaussian distribution of NIR power densities with mean of u=130 mW cm⁻² and a standard deviation of σ=75 mW cm⁻² according to various embodiments.

FIG. 57B shows plots of mid-infrared power density P_{MIR} (in Watts per square centimeter or W/cm²) as a function of time (in milliseconds or ms) illustrating the analog values of various intensities of mid-infrared (MIR) illumination according to various embodiments.

FIG. 57C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 57B according to various embodiments.

FIG. 57D shows a plot of spike as a function of time (in milliseconds or ms) illustrating the corresponding spike train for each transduction current (IDS) waveform in FIG. 57C when the spike threshold current (I_{TC}) is set to 0 nA according to various embodiments.

FIG. 58 is a schematic diagram about how to determine the suitable encoding parameters (mean (u), variance (σ) and spiking threshold current (I_{TC})) to realize high encoding precision.

FIG. 59 shows a plot of mean spike rate (in kilo-Hertz or kHz) as a function of mid-infrared power density P_{MIR} (in Watts per square centimeter or W/cm²) of the optoelectronic device (optoelectronic device 1) according to various embodiments when mean (u)=130 mW cm⁻², standard deviation (σ)=75 mW cm⁻² and threshold current (I_{TC})=0 nA, respectively.

FIG. 60A shows (above) a plot of near infrared power density P_{NIR} (in milli-Watts per square centimeter or mW/cm²) as a function of time (in milli-seconds or ms) illustrating one train of near infrared (NIR) optical pulses that is randomly sampled from a Gaussian distribution according to various embodiments for spike rate encoding; and (below) a plot of count as a function of visible power density (in milli-Watts per square centimeter or mW/cm²) illustrating the Gaussian distribution of near infrared NIR power densities with mean of u=130 mW cm⁻² and a standard deviation of σ=75 mW cm⁻² according to various embodiments.

FIG. 60B shows plots of mid-infrared power density P_{MIR} (in Watts per square centimeter or mW/cm²) as a function of time (in milliseconds or ms) illustrating the analog values of various intensities of mid-infrared (MIR) illumination according to various embodiments.

FIG. 60C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 60B according to various embodiments.

FIG. 60D shows a plot of spike as a function of time (in milliseconds or ms) illustrating the corresponding spike train for each transduction current (I_{DS}) waveform in FIG. 60C when the spike threshold current (I_{TC}) is set to 0 nA according to various embodiments.

FIG. 60E shows a plot of mean spike rate (in kilo-Hertz or kHz) as a function of mid-infrared power density P_{MIR} (in Watts per square centimeter) of the optoelectronic device (optoelectronic device 1) according to various embodiments when mean (u)=130 mW/cm², standard deviation (σ)=75 mW cm⁻² and threshold current (I_{TC})=0 nA, respectively.

FIG. 60F shows (left) an original clock image (pixel values ranging from 0 to 255 are linearly mapped to mid-infrared MIR optical power density of 0 to 80.21 W/cm²; (middle) an encoded clock image at sampling period Tₛ of 100 μs according to various embodiments (the time-steps for encoding each pixel are 10; the maximal spike rate is 10 kHz; and (right) the encoded clock image at sampling period Tₛ of 10 μs according to various embodiments (the maximal spike rate is 100 kHz).

FIG. 61A shows a photocurrent map illustrating the mid-infrared power densities (P_{MIR}) of the nine targets according to various embodiments. For convenience, nine targets ‘3’ are named as (i) to (vii), (ix) and (x) in incremental order of P_{MIR}.

FIG. 61B shows an encoded image after encoding the mid-infrared power densities (P_{MIR}) of the nine targets in FIG. 61A into corresponding spike rates ranging from 0 kHz to 100 kHz according to various embodiments.

FIG. 61C shows plots of spike rate (in kilo-Hertz or kHz) as a function of mid-infrared power density P_{MIR} (in Watts per square centimeters or W/cm²) illustrating experimental results of spike rate P_{MIR} with different means u and standard deviations σ for sampling 730 nm light according to various embodiments.

FIG. 62 shows (a) a plot of spike rate (in kilo-Hertz or kHz) as a function of mid-infrared power density P_{MIR} (in Watts per square centimeter or W/cm²) illustrating variation of spike rate with P_{MIR} for different standard deviations σ of the Gaussian distribution used for sampling 730 nm light according to various embodiments; (b) a plot of spike rate (in kilo-Hertz or kHz) as a function of mid-infrared power density P_{MIR} (in Watts per square centimeter or W/cm²) illustrating variation of spike rate with P_{MIR} for different means u of the Gaussian distribution used for sampling 730 nm light according to various embodiments; and (c) a plot of spike rate (in kilo-Hertz or kHz) as a function of mid-infrared power density P_{MIR} (in Watts per square centimeter or W/cm²) illustrating variation of spike rate with PAR for different threshold currents I_{TC} according to various embodiments.

FIG. 63A shows plots of standard deviation σ (in milli-Watts per square centimeters or mW/cm²) as a function of mean u (in milli-Watts per square centimeters or mW/cm²) illustrating results of encoding images under different sets of u and σ according to various embodiments. Such parameter adjustment may allow the system to adjust dynamic working range and encoding precision to adapt different MIR targets with varied P_{MIR}.

FIG. 63B illustrates the correlation coefficients (CC) between the results in FIG. 63A and the corresponding results in FIG. 61A for different cases of mean u and standard deviation σ according to various embodiments.

FIG. 64A shows a schematic of the leaky integrated-and-fire (LIF) neuron model used in each node of the spiking neural network (SNN) according to various embodiments.

FIG. 64B is a plot of accuracy (in percent or %) as a function of maximum power density Pₘₐₓ (in Watts per square centimeter or W/cm²) illustrating variation of classification accuracy with Pₘₐₓ at various standard deviations σ according to various embodiments.

FIG. 64C is a plot of accuracy (in percent or %) as a function of maximum power density Pₘₐₓ (in Watts per square centimeters or W/cm²) illustrating variation of classification accuracy with Pₘₐₓ at various means u according to various embodiments.

FIG. 64D shows a plot of accuracy (in percent or %) as a function of sampling period Tₛ (in micro-seconds or μs)/time steps illustrating the classification accuracy of the spiking neural network (SNN) according to various embodiments versus the time steps of one spike train when Pₘₐₓ is 21 W cm⁻², with insets (i)-(iii) showing the encoded images of “3” when the time steps are 1, 5 and 10, respectively. σ and u are set to 25 mW/cm² and 70 mW/cm² respectively, with I_{TC} of 0 nA.

FIG. 65 shows (a) a plot of accuracy (in percent or %) as a function of number of hidden neurons for data set with Pₘₐₓ of 80.21 W/cm² according to various embodiments; (b) a plot of accuracy (in percent or %) as a function of membrane potential decay rate (β) for data set with Pₘₐₓ of 80.21 W/cm² according to various embodiments; and (c) a plot of loss as a function of iteration illustrating the cross-entropy loss of the spiking neural network verses iteration for the train set and the test set according to various embodiments.

FIG. 66 shows (a) a plot of accuracy (in percent or %) as a function of time steps illustrating the interference accuracy of the spiking neural network (SNN) when the optoelectronic device (optoelectronic device 1) according to various embodiments uses different time-steps for encoding mid-infrared (MIR) object with different maximum power densities Pₘₐₓ; and (b) the encoded images of the mid-infrared (MIR) object with Pₘₐₓ=80.21 W/cm² at time-steps of 1, 5, and 100.

FIG. 67A shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the Gaussian fitting curve (u=140 mW/cm² and σ=35 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments.

FIG. 67B shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the uniform fitting curve (u=140 mW/cm² and optical power density range for sampling NIR light (R) of 160 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments.

FIG. 67C shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the Laplace fitting curve (u=140 mW/cm² and σ=35 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments.

FIG. 68A shows (i) a plot of transduction current I_{DS} (in nano-Amperes or nA) as a function of mid-infrared power density P_{MIR} (in Watts per square centimeter or W/cm²) illustrating the photocurrent response of optoelectronic device 1 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 1 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 1 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 1 according to various embodiments towards mid-infrared Modified National Institute of Standards and Technology (MIR MNIST) data sets.

FIG. 68B shows (i) a plot of transduction current I_{DS} (in nano-Amperes or nA) as a function of mid-infrared power density P_{MIR} (in Watts per square centimeter or W/cm²) illustrating the photocurrent response of optoelectronic device 2 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 2 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 2 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 2 according to various embodiments towards mid-infrared Modified National Institute of Standards and Technology (MIR MNIST) data sets.

FIG. 68C shows (i) a plot of transduction current I_{DS} (in nano-Amperes or nA) as a function of mid-infrared power density P_{MIR} (in Watts per square centimeter or W/cm²) illustrating the photocurrent response of optoelectronic device 3 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 3 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 3 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 3 according to various embodiments towards mid-infrared Modified National Institute of Standards and Technology (MIR MNIST) data sets.

FIG. 68D shows (i) a plot of transduction current I_{DS} (in nano-Amperes or nA) as a function of mid-infrared power density P_{MIR} (in Watts per square centimeter or W/cm²) illustrating the photocurrent response of optoelectronic device 4 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 4 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 4 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 4 according to various embodiments towards mid-infrared Modified National Institute of Standards and Technology (MIR MNIST) data sets.

FIG. 68E shows (i) a plot of transduction current I_{DS} (in nano-Amperes or nA) as a function of mid-infrared power density P_{MIR} (in Watts per square centimeter or W/cm²) illustrating the photocurrent response of optoelectronic device 5 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 5 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 5 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 5 according to various embodiments towards mid-infrared Modified National Institute of Standards and Technology (MIR MNIST) data sets.

FIG. 69A shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 532 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 532 nm light according to various embodiments; and (iii) a plot of spike rate (in kilo-Hertz or kHz) as a function of mid-infrared power density P_{MIR} (in Watts per square centimeter or W/cm²) illustrating variation of spike rate with P_{MIR} under different standard deviations σ of sampling (in milli-Watts or mW/cm²) with 532 nm light according to various embodiments.

FIG. 69B shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 730 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 730 nm light according to various embodiments; and (iii) a plot of spike rate (in kilo-Hertz or kHz) as a function of mid-infrared power density P_{MIR} (in Watts per square centimeter or W/cm²) illustrating variation of spike rate with P_{MIR} under different standard deviations σ of sampling (in milli-Watts or mW/cm²) with 730 nm light according to various embodiments.

FIG. 69C shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 1470 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 1470 nm light according to various embodiments; and (iii) a plot of spike rate (in kilo-Hertz or kHz) as a function of mid-infrared power density P_{MIR} (in Watts per square centimeter or W/cm²) illustrating variation of spike rate with P_{MIR} under different standard deviations σ of sampling (in milli-Watts or mW/cm²) with 1470 nm light according to various embodiments.

FIG. 69D shows (i) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 35 mW/cm²; (ii) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 55 mW/cm²; and (iii) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 75 mW/cm².

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the terms “about” or “approximately” as applied to a numeric value encompasses the exact value and a reasonable variance, e.g. within 10% of the specified value. The symbol “~” is used herein to denote the terms “about” or “approximately”.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Owing to their superior optical functionalities such as strong light-matter interaction, tunable bandgap and the potential compatibility with complementary metal oxide semiconductor (CMOS) platform, two-dimensional (2D) van der Waals (vdW) heterostructures have become promising candidates for achieving such a goal. Recently, notable progress has been made with 2D van der Waals heterostructures in developing neuromorphic sensors, encoders and processors, presenting a development trend towards all-in-one devices with functionalities integration. However, these studies focus only on the visible and near-infrared spectral ranges, while such integrated neuromorphic devices operating in the mid-infrared (MIR) range would greatly advance IRMV systems for autonomous driving, intelligent night visions, defense, and medical applications, and improve the versatility of neuromorphic systems. In addition, the demonstrations of encoding functionality in previous studies are limited in electronic approaches. An integrated MIR neuromorphic device with the perception and encoding functionalities driven by an all-optical approach is expected to shed light on the technological development of high information coding of IRMV.

Various embodiments may be compact and/or may provide improved computing efficiencies compared to existing IRMV systems.

Embodiments described in the context of one of the systems/devices are analogously valid for the other systems/devices. Similarly, embodiments described in the context of a method are analogously valid for a system/device, and vice versa.

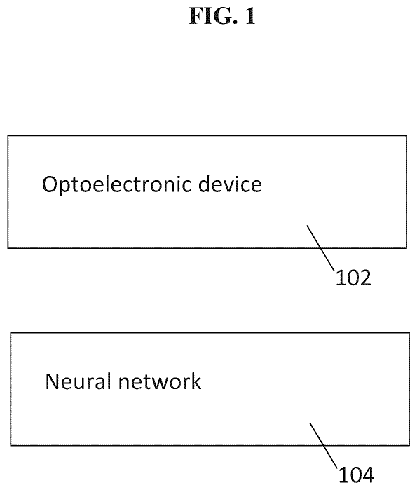

FIG. 1 is a general illustration of an optoelectronic system according to various embodiments. The optoelectronic system may include an optoelectronic device 102 for receiving a first electromagnetic wave of a first wavelength and a second electromagnetic wave of a second wavelength. The optoelectronic device 102 may include a substrate. The optoelectronic device 102 may also include a first contact electrode over the substrate. The optoelectronic device 102 may further include a second contact electrode over the substrate. The optoelectronic device 102 may additionally include a first two-dimensional van der Waal (vdW) material layer in contact with the first contact electrode. The optoelectronic device 102 may also include a second two-dimensional van der Waal (vdW) material layer in contact with the second contact electrode, the second two-dimensional van der Waal material layer also forming a heterojunction with the first two-dimensional van der Waal material layer. The optoelectronic system may further include a neural network 104 for identifying or determining an object (e.g. a mask with MIR targets) providing or transmitting the first electromagnetic wave. The neural network 104 may be coupled to the optoelectronic device.

In other words, the optoelectronic system may include an optoelectronic device 102 and a neural network 104 connected to the optoelectronic device. The optoelectronic device 102 may include a substrate and two electrodes over the substrate. The optoelectronic device may include a two-dimensional van der Waal (vdW) material layer in physical contact with each of the two electrodes. The two-dimensional van der Waal (vdW) material layer may be made of different materials forming a heterojunction.

For avoidance of doubt, FIG. 1 seeks to illustrate the features of an optoelectronic system according to various embodiments, and is not intended to limit, for instance, the arrangement, orientation, shape, size etc. of the various features.

The optoelectronic device 102 may be a two-terminal device, and may be referred to as a vdW heterostructure or a retinomorphic device. In various embodiments, the first electrode may be referred to as a drain electrode and the second electrode may be referred to as a source electrode. In various other embodiments, the first electrode may be referred to as a source electrode and the second electrode may be referred to as a drain electrode.

Generally speaking, a two-dimensional van der Waal layer or flake may refer to one or more monolayers (e.g. less than 10 or less than 5 monolayers) in which atoms within each monolayer are joined via covalent bonds, while the different monolayers are held by van der Waals forces. In various embodiments, the first two-dimensional van der Waal (vdW) layer may include black phosphorus-arsenic (b-AsP). In various other embodiments, the first two-dimensional van der Waal (vdW) layer may include black phosphorous (BP), palladium selenide (PdSe₂), or tellurium (Te).

In various embodiments, the second two-dimensional van der Waal material layer may include molybdenum (IV) telluride (MoTe₂).

In various embodiments, the first electromagnetic wave may be mid infrared (MIR) radiation, while the second electromagnetic wave may be near infrared (NIR) radiation. Mid infrared (MIR) radiation may refer to any radiation having a wavelength or wavelength range selected from a range from 3 μm to 8 μm, while near infrared (NIR) radiation may refer to any radiation having a wavelength or wavelength range selected from a range from 0.7 μm to 3 μm. However, it may also be envisioned that the first electromagnetic wave and/or the second electromagnetic wave may be other types of electromagnetic waves. For instance, the first electromagnetic wave may be far infrared radiation (FAR), while the second electromagnetic wave may be visible light or ultraviolet (UV) light.

In various embodiments, the optoelectronic device may be configured such that the first electromagnetic wave provided to the optoelectronic device generates a first photoexcited current flowing in a first direction when the first contact electrode and the second electrode are at zero voltage bias, while the optoelectronic device may also be configured such that the second electromagnetic wave provided to the optoelectronic device generates a second photoexcited current flowing in a second direction opposite the first direction when the first contact electrode and the second electrode are at zero voltage bias. The first photoexcited current flowing in the first direction may be generated via a photothermoelectric (PTE) effect, while the second photoexcited current flowing in the second direction may be generated via a photovoltaic (PV) effect.

MIR radiation and NIR radiation may generate photoexcited currents flowing in opposite directions when the first contact electrode and the second electrode are at zero voltage bias. This may be because the photoexcited current due to MIR is generated via PTE, while the photoexcited current due to NIR is generated via PV.

In various embodiments, the optoelectronic device may be configured to generate a spike train based on a portion of a time-domain transduction current (I_{DS}) waveform output above a threshold current (I_{TC}). The time-domain transduction current (I_{DS}) waveform output may be generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

The spike train may be generated based on a part of a time-domain transduction current (I_{DS}) waveform output that is above I_{TC} threshold line. The I_{DS} waveform output may be generated when the second electromagnetic wave, e.g. NIR optical pulses and the first electromagnetic wave, e.g. MIR radiation (above a predetermined spiking threshold P_{MIR-ST} are incident on the optoelectronic device 102.

In various embodiments, a power of the second electromagnetic wave may be selected from a range greater than 0 mW cm⁻² to 255 mW cm⁻². The power of the first electromagnetic wave may be selected from a range from 0 W cm⁻² to 56 W cm⁻².

In various embodiments, the system may further include a first electromagnetic source configured to emit the electromagnetic radiation. The system may also include a second electromagnetic source configured to emit the second electromagnetic radiation. For instance, the first electromagnetic source may be a MIR source such as a quantum cascade laser, a thermal emitter, a heated pig iron or a heated steel strip, while the second electromagnetic source may be a NIR source such as a NIR lamp or laser.

In various embodiments, the neural network 104 may be configured to identify or determine the object providing or transmitting the first electromagnetic wave based on the spike train. For instance, the object may be distinct from the first electromagnetic source, such as a mask with MIR targets transmitting MIR radiation emitted from a MIR source. In various other embodiments, the object may be the first electromagnetic source, e.g. the MIR source.

In various embodiments, the optoelectronic system may include a controller configured to move the object providing or transmitting the first electromagnetic wave such that the first electromagnetic wave from different portions of the object is provided to the optoelectronic device at different periods of time. For instance, the controller may be used to move the object, such as a mask with MIR targets, to “scan” different parts of the mask over time so that the shapes of the MIR targets can be identified.

In various embodiments, the neural network may be a trained spiking neural network (SNN). The neural network may include an input layer, a hidden layer connected to the input layer, and an output layer connected to the hidden layer.

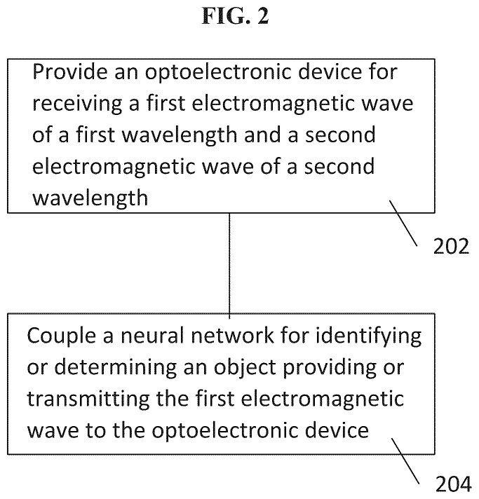

FIG. 2 shows a general illustration of a method of forming an optoelectronic system according to various embodiments. The method may include, in 202, providing an optoelectronic device for receiving a first electromagnetic wave of a first wavelength and a second electromagnetic wave of a second wavelength. The optoelectronic device may include a substrate. The optoelectronic device may also include a first contact electrode over the substrate. The optoelectronic device may further include a second contact electrode over the substrate. The optoelectronic device may additionally include a first two-dimensional van der Waal (vdW) material layer in contact with the first contact electrode. The optoelectronic device may also include a second two-dimensional van der Waal (vdW) material layer in contact with the second contact electrode, the second two-dimensional van der Waal material layer also forming a heterojunction with the first two-dimensional van der Waal material layer. The method may also include, in 204, coupling a neural network for identifying or determining an object providing or transmitting the first electromagnetic wave to the optoelectronic device.

In other words, the method may include coupling an optoelectronic device as described herein with a neural network as described herein to form the optoelectronic system.

In various embodiments, the first two-dimensional van der Waal material layer may include black phosphorus-arsenic (b-AsP). In various other embodiments, the first two-dimensional van der Waal (vdW) layer may include black phosphorous (BP), palladium selenide (PdSe₂), or tellurium (Te).

In various embodiments, the second two-dimensional van der Waal material layer may include molybdenum (IV) telluride (MoTe₂).

In various embodiments, the first electromagnetic wave may be mid infrared (MIR) radiation, while the second electromagnetic wave may be near infrared (NIR) radiation. However, it may also be envisioned that the first electromagnetic wave and/or the second electromagnetic wave may be other types of electromagnetic waves.

In various embodiments, the optoelectronic device may be configured such that the first electromagnetic wave provided to the optoelectronic device generates a first photoexcited current flowing in a first direction when the first contact electrode and the second electrode are at zero voltage bias. The optoelectronic device may also be configured such that the second electromagnetic wave provided to the optoelectronic device generates a second photoexcited current flowing in a second direction opposite the first direction when the first contact electrode and the second electrode are at zero voltage bias.

In various embodiments, the first photoexcited current flowing in the first direction may be generated via a photothermoelectric (PTE) effect, while the second photoexcited current flowing in the second direction may be generated via a photovoltaic (PV) effect.

In various embodiments, the optoelectronic device may be configured to generate a spike train based on a portion of a time-domain transduction current (I_{DS}) waveform output above a threshold current (I_{TC}). The time-domain transduction current (I_{DS}) waveform output may be generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

In various embodiments, a power of the second electromagnetic wave is selected from a range greater than 0 mW cm⁻² to 255 mW cm⁻². The power of the first electromagnetic wave may be selected from a range from 0 W cm⁻² to 56 W cm⁻².

In various embodiments, the neural network may be configured to identify or determine the object providing or transmitting the first electromagnetic wave based on the spike train.

In various embodiments, the method may also include providing a controller configured to move the object providing or transmitting the first electromagnetic wave such that the first electromagnetic wave from different portions of the object is provided to the optoelectronic device at different periods of time.

In various embodiments, the method may additionally include providing a first electromagnetic source configured to emit the first electromagnetic radiation. The method may also include providing a second electromagnetic source configured to emit the second electromagnetic radiation.

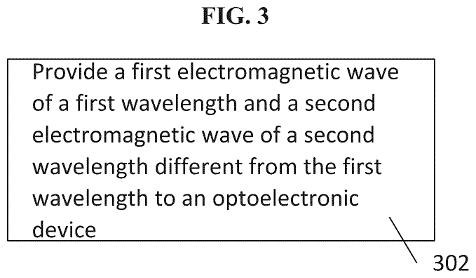

FIG. 3 shows a general illustration of a method of forming an optoelectronic system according to various embodiments. The method may include, in 302, providing a first electromagnetic wave of a first wavelength and a second electromagnetic wave of a second wavelength different from the first wavelength to an optoelectronic device. The optoelectronic device may include a substrate. The optoelectronic device may also include a first contact electrode over the substrate. The optoelectronic device may further include a second contact electrode over the substrate. The optoelectronic device may additionally include a first two-dimensional van der Waal (vdW) material layer in contact with the first contact electrode. The optoelectronic device may also include a second two-dimensional van der Waal (vdW) material layer in contact with the second contact electrode, the second two-dimensional van der Waal material layer also forming a heterojunction with the first two-dimensional van der Waal material layer. The optoelectronic system may also include a neural network for identifying or determining an object providing or transmitting the first electromagnetic wave. The neural network may be coupled to the optoelectronic device.

In other words, the method may include providing electromagnetic waves of two different wavelengths to the optoelectronic device as described herein, such that a neural network coupled to the optoelectronic device is able to identify or determine the object or properties of the object emitting or transmitting the first electromagnetic wave.

In various embodiments, the first electromagnetic wave may be mid infrared (MIR) radiation, while the second electromagnetic wave may be near infrared (NIR) radiation. However, it may also be envisioned that the first electromagnetic wave and/or the second electromagnetic wave may be other types of electromagnetic waves.

In various embodiments, the method may further include biasing the first electrode and the second electrode at zero voltage such that the first electromagnetic wave provided to the optoelectronic device generates a first photoexcited current flowing in a first direction, and the second electromagnetic wave provided to the optoelectronic device generates a second photoexcited current flowing in a second direction opposite the first direction.

In various embodiments, the first photoexcited current flowing in the first direction may be generated via a photothermoelectric (PTE) effect, while the second photoexcited current flowing in the second direction may be generated via a photovoltaic (PV) effect.

In various embodiments, the optoelectronic device may be configured to generate a spike train based on a portion of a time-domain transduction current (I_{DS}) waveform output above a threshold current (I_{TC}). The time-domain transduction current (I_{DS}) waveform output may be generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

In various embodiments, the method may also include moving the object providing or transmitting the first electromagnetic wave such that the first electromagnetic wave from different portions of the object is provided to the optoelectronic device at different periods of time.

### Example 1

Various embodiments may relate to a two-dimensional (2D) MIR retinomorphic device integrating perception and encoding functionalities simultaneously based on a b-AsP/MoTe₂ van der Waals heterostructure. The retinomorphic single device may be designed such that it can perceive external light in the MIR spectral range (at ~4.6 μm) while simultaneously encode the received MIR information into spike trains by harnessing a stochastic NIR sampling terminal (at ~730 nm excitation). With high detectivity (3.1×10¹⁰ cm Hz^{0.5}/W) and rapid response rate (~20 μs) under MIR illumination without inducing electrical bias, the device successfully demonstrates a typical neural encoding algorithm of rate-based encoding with wide dynamic working range and high encoding precision. The device may feature the adaption ability to intensity variation of MIR signal, which is analogue to the human eye's visual adaption to the change in ambient light intensity in the visible range. Furthermore, a trained SNN achieves an inference accuracy of more than 94% to the MIR Modified National Institute of Standards and Technology (MNIST) data set which is encoded into spikes by the device. The retinomorphic device integrating perception and encoding functionalities may have the potential to perform MIR machine vision in a highly compact and efficient way.

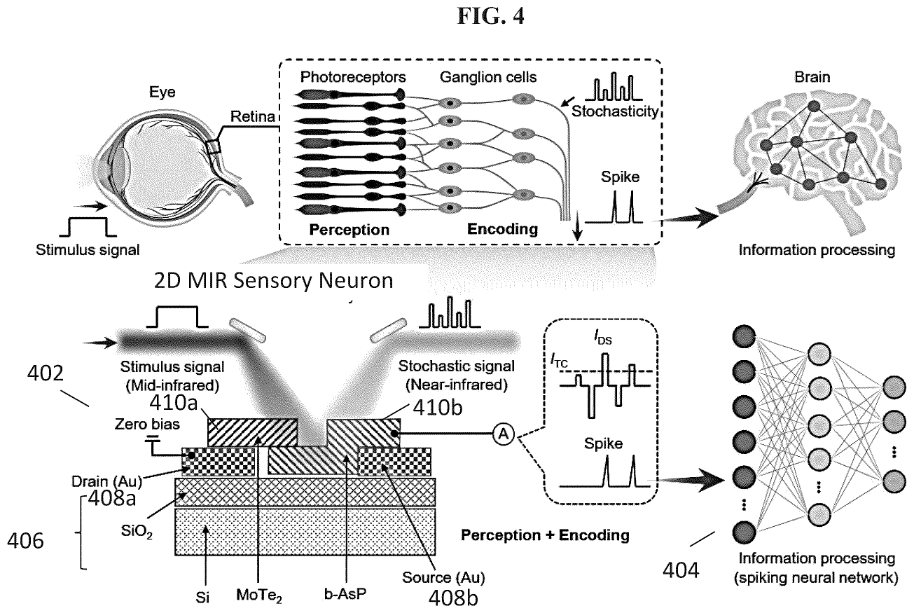

The visual system is one of the important sensory organs for humans to perceive the external world as more than 80% of the environment information is captured in human eyes. FIG. 4 shows (above) the implementation of perception, encoding and processing of stimulus signals from external objects in the human visual system; and (below) illustrates the optoelectronic system that can mimic the key functionalities according to various embodiments. For the human visual system, the external stimulation signals are perceived by photoreceptors and converted into electrical impulses (spikes) by ganglion cells following neural encoding algorithms, and eventually transmitted to the visual cortex in the brain for processing. Notably, the encoding process exhibits the inherent stochasticity which is involved in the spike generation and enhances the noise tolerance of spikes. Inspired by the human retina, a 2D retinomorphic device 402 capable of simultaneously perceiving and encoding MIR optical stimuli is proposed and demonstrated by using a 2D b-AsP/MoTe₂ van der Waals heterostructure.

The 2D retinomorphic device 402 may include a substrate 406 (e.g. a silicon oxide (SiO₂)/silicon (Si) substrate) as well as a drain electrode 408a and a source electrode 408b over the substrate 406. The 2D retinomorphic device 402 may also include a MoTe₂ layer 410a in contact with the drain electrode 408a and a b-AsP layer 410b in contact with the source electrode 408b.

Upon the stimulation of MIR signals, the photo-excited current (I_{DS}) of the 2D retinomorphic device 402 is measured from source/drain electrodes at zero bias, which mimics the optical signal collection and conversion of the photoreceptors in the human retina. Meanwhile, programmable NIR optical pulses with stochastic intensity cause corresponding fluctuation of I_{DS}, where a spike is generated when the I_{DS} exceeds the threshold line (I_{TC}), emulating the encoding scheme of ganglion cells. The as-generated spike trains with coded MIR information are finally processed by a trained SNN 404 for intelligent tasks, such as classification and decision.

In the retinomorphic device, the b-AsP is used as the MIR photosensitive layer owing to its narrow bandgap of ~0.2 eV and high MIR optical absorption efficiency of ~10%, and MoTe₂ with an appropriate bandgap of ~1.0 eV serves as the NIR sensitizer. In addition, both b-AsP and MoTe₂ exhibit high hole mobility of ~117 and ~10 cm² V⁻¹ s⁻¹, respectively, allowing for high photosensitivity of the device.

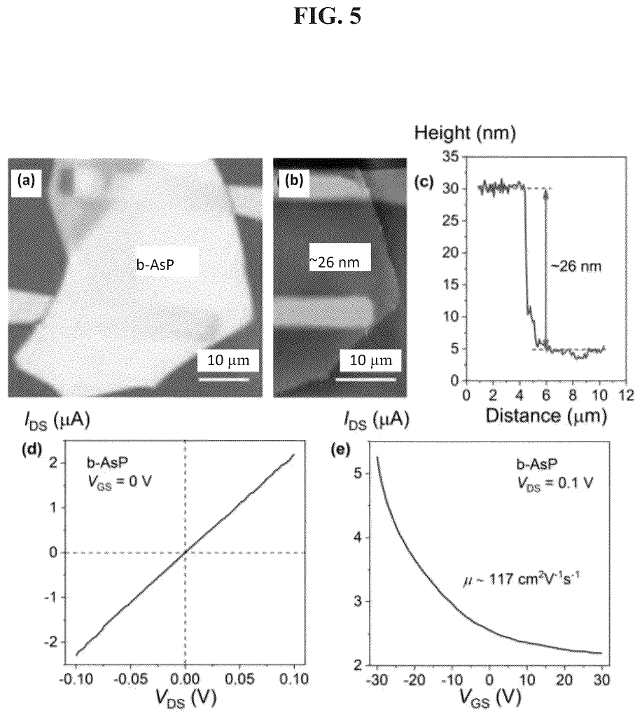

FIG. 5 shows morphology characterization and electrical properties of black phosphorus-arsenic (b-AsP): (a) a microscopic image of b-AsP according to various embodiments; (b) an atomic force microscopic (AFM) image of a two-dimensional (2D) b-AsP-based back-gate field-effect transistor according to various embodiments; (c) a plot of height (in nanometers or nm) as a function of distance (in micrometers or μm) illustrating the height profile of the 2D b-AsP flake according to various embodiments (thickness of ~26 nm); (d) a plot of the transduction current I_{DS} (in micro-Amperes or μA) as a function of source-drain voltage V_{DS} (in volts or V) illustrating the output characteristic curve of the 2D b-AsP-based transistor according to various embodiments (linear I_{DS}−V_{DS} indicates that Ohmic contact was formed between the 2D b-AsP flake and gold (Au) electrodes); and (e) a plot of the transduction current I_{DS} (in micro-Amperes or μA) as a function of gate voltage V_{GS} (in volts or V) illustrating the transfer characteristic curve of the 2D b-AsP-based transistor at V_{DS}=0.1 V according to various embodiments. It can be observed that the b-AsP exhibits heavily-doped p-type conduction behavior with a very weak gate modulation of channel carrier.

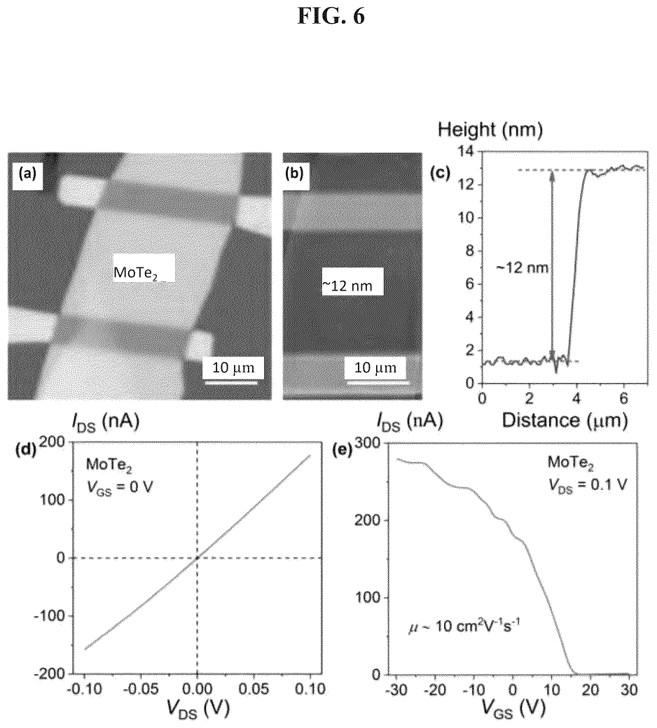

FIG. 6 shows morphology characterization and electrical properties of molybdenum (IV) telluride (MoTe₂): (a) a microscopic image of MoTe₂ according to various embodiments; (b) an atomic force microscopic (AFM) image of a two-dimensional (2D) MoTe₂-based back-gate field-effect transistor according to various embodiments; (c) a plot of height (in nanometers or nm) as a function of distance (in micrometers or μm) illustrating the height profile of the 2D MoTe₂ flake according to various embodiments (thickness of ~12 nm); (d) a plot of the transduction current I_{DS} (in nano-Amperes or nA) as a function of source-drain voltage V_{DS} (in volts or V) illustrating the output characteristic curve of the 2D MoTe₂-based transistor according to various embodiments (near linear I_{DS}−V_{DS} indicates that negligible Schottky barriers at the interface between 2D MoTe₂ flake and gold (Au) electrodes); and (e) a plot of the transduction current I_{DS} (in nano-Amperes or nA) as a function of gate voltage V_{GS} (in volts or V) illustrating the transfer characteristic curve of the 2D MoTe₂-based transistor at V_{DS}=0.1 V according to various embodiments. The MoTe₂ featured a p-type switching with a mobility of ~10 cm² V⁻¹ s⁻¹.

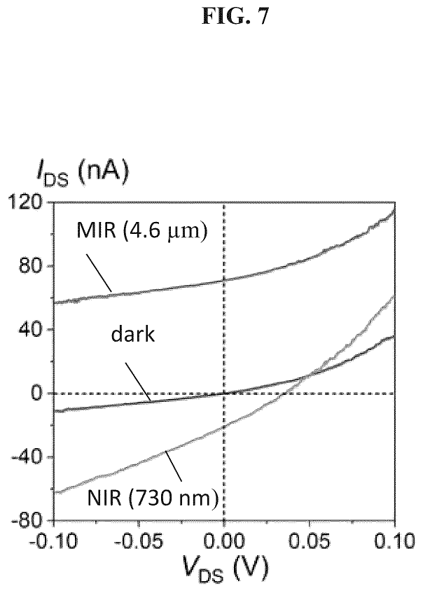

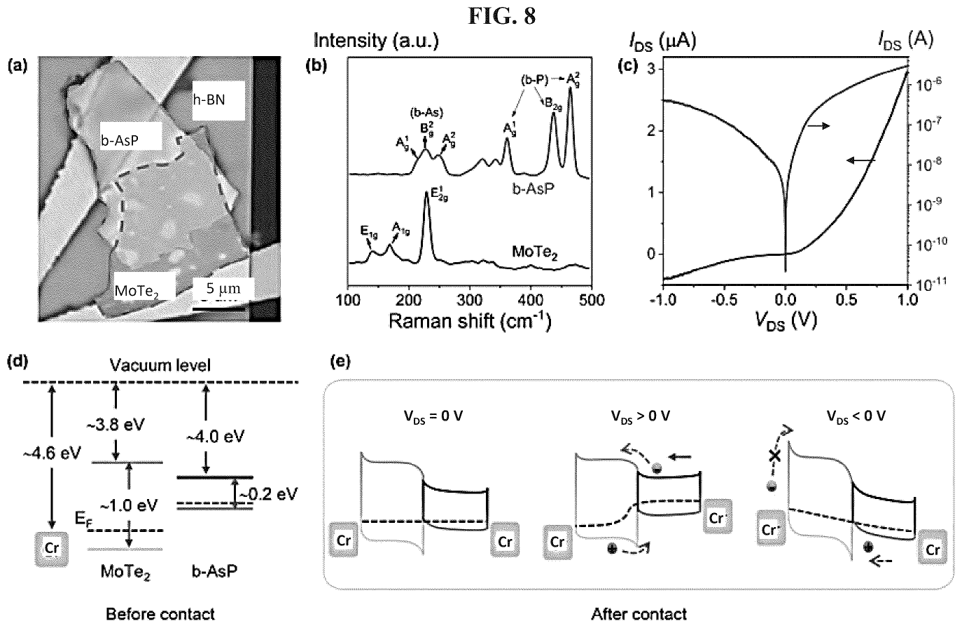

FIG. 7 shows a plot of the transduction current I_{DS} (in nano-Amperes or nA) as a function of source-drain voltage V_{DS} (in volts or V) illustrating of the black phosphorus-arsenic/molybdenum (IV) telluride (b-AsP/MoTe₂) optoelectronic device according to various embodiments in dark, under mid-infrared (MIR) (4.6 μm) and under near-infrared (NIR) (730 nm). FIG. 7 confirms the sensitive photodetection capability of the optoelectronic device. The photoresponse characteristics are discussed in FIGS. 8-10, where the photothermoelectric (PTE) and photovoltaic (PV) effects are identified as the dominant mechanisms for perceiving MIR and NIR illumination, respectively,

FIG. 8 shows the characterizations and band alignments of the black phosphorus-arsenic/molybdenum (IV) telluride (b-AsP/MoTe₂) optoelectronic device according to various embodiments: (a) microscopic image of the b-AsP and MoTe₂ flakes placed on a silicon dioxide/silicon (SiO₂/Si) substrate according to various embodiments; (b) a plot of intensity (in arbitrary units or a.u.) as a function of Raman shift (per centimeter or cm⁻¹) illustrating the Raman spectra of MoTe₂ and b-AsP according to various embodiments; (c) a plot of transduction current I_{DS} (in micro-Amperes or μA/Amperes or A) as a function of source-drain voltage V_{DS} (in volts or V) illustrating the output characteristic curve of the b-AsP/MoTe₂ heterostructure according to various embodiments; (d) the band profiles of chromium (Cr), MoTe₂ and b-AsP before contact; and (e) band alignment of the b-AsP/MoTe₂ heterostructure according to various embodiments at different biasing voltages according to various embodiments.

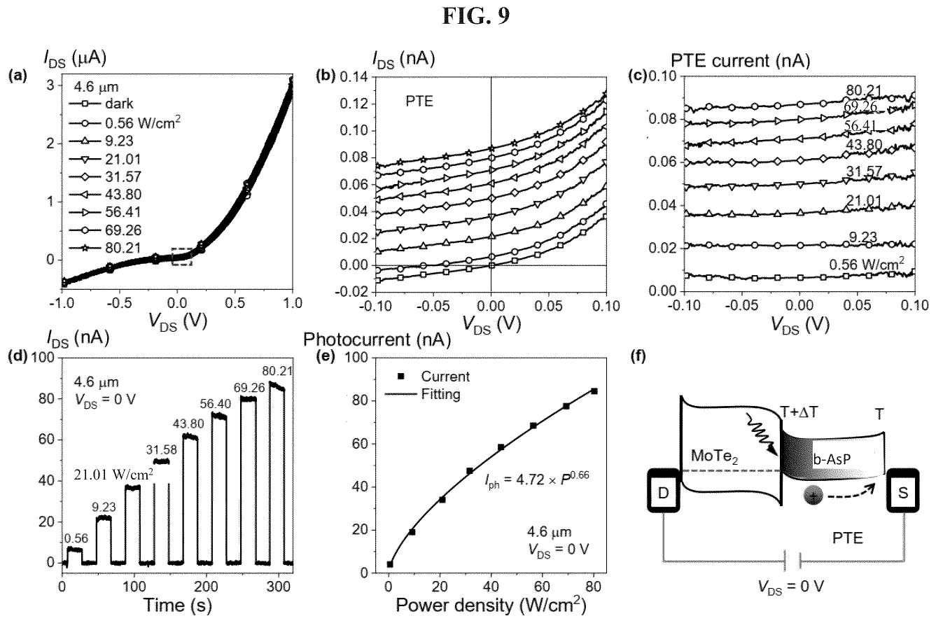

FIG. 9 shows the photothermoelectric (PTE) response characteristics of the black phosphorus-arsenic/molybdenum (IV) telluride (b-AsP/MoTe₂) optoelectronic device according to various embodiments under 4.6 μm laser illumination: (a) a plot of transduction current I_{DS} (in micro-Amperes or μA) as a function of source-drain voltage V_{DS} (in volts or V) illustrating the output characteristics of the optoelectronic device according to various embodiments in dark and under illumination with power densities ranging from 0.56 to 80.21 W cm⁻²; (b) a plot of transduction current I_{DS} (in nano-Amperes or nA) as a function of source-drain voltage V_{DS} (in volts or V) showing a magnified view of the area enclosed by dotted lines in (a); (c) a plot of photocurrent (in nano-amperes or nA) as a function of source-drain voltage V_{DS} (in volts or V) illustrating the output characteristics of the optoelectronic device according to various embodiments at different power densities ((c) shows an independence of photocurrent on bias voltage, which is an important feature of photo thermoelectric effect); (d) a plot of photocurrent (in nano-amperes or nA) as a function of time (in seconds or s) illustrating the photoswitching response of the optoelectronic device according to various embodiments at V_{DS}=0V; (e) a plot of photocurrent Iₚₕ (in nano-Amperes or nA) as a function of power density (in Watts per square centimeter or W/cm²) illustrating a relationship of Iₚₕ=4.72×P^{0.66} according to various embodiments; and (f) the band diagram of the optoelectronic device according to various embodiments under mid-infrared (MIR) laser illumination at V_{DS}=0V.

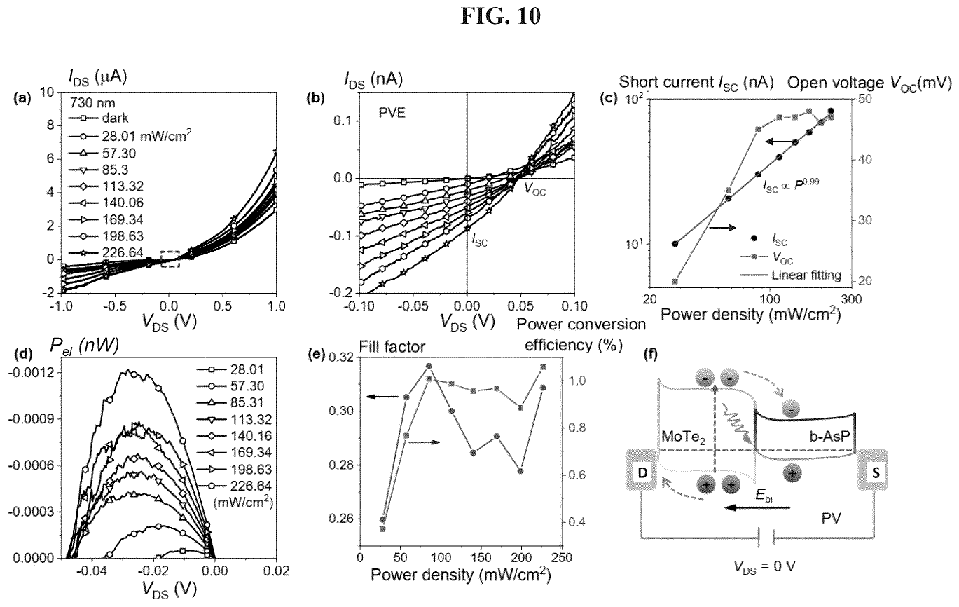

FIG. 10 shows the photovoltaic (PV) response characteristics of the b-AsP/MoTe₂ optoelectronic device according to various embodiments under 730 nm laser illumination: (a) a plot of transduction current I_{DS} (in micro-Amperes or μA) as a function of source-drain voltage V_{DS} (in volts or V) illustrating the output characteristics of the optoelectronic device according to various embodiments in dark and under illumination with power densities ranging from 28.01 mW cm⁻² to 226.64 mW cm⁻²; (b) a plot of transduction current I_{DS} (in nano-Amperes or nA) as a function of source-drain voltage V_{DS} (in volts or V) showing a magnified view of the area enclosed by dotted lines in (a); (c) a plot of short current I_{SC} (in nano-Amperes or nA) as a function of power density (in milli-Watts per square centimeter or mW/cm²) illustrating the dependence of short-circuit current (I_{SC}) and open-circuit voltage (V_{OC}) on the power density according to various embodiments; (d) a plot of output electrical power Pet (in nano-Watts or nW) as a function of source-drain voltage V_{DS} (in volts or V) illustrating the variation of Pe as a function of the applied bias V_{DS} at different power densities according to various embodiments; (e) a plot of fill factor FF/power conversion efficiency PCE (in percent or %) illustrating the variation of FF and PCE with power density according to various embodiments; and (f) band diagrams of the optoelectronic device according to various embodiments under 730 nm laser illumination at V_{DS}=0V.

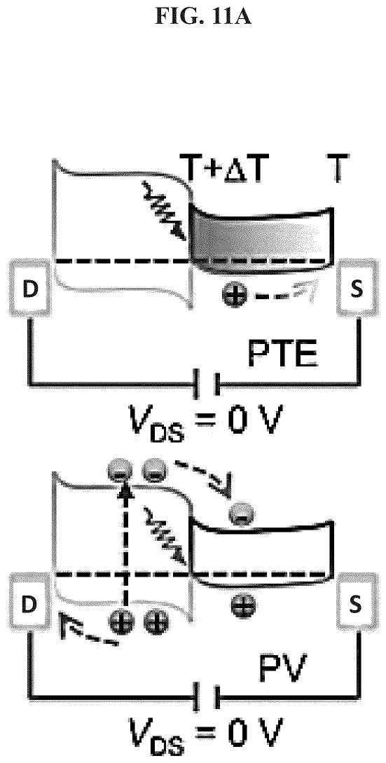

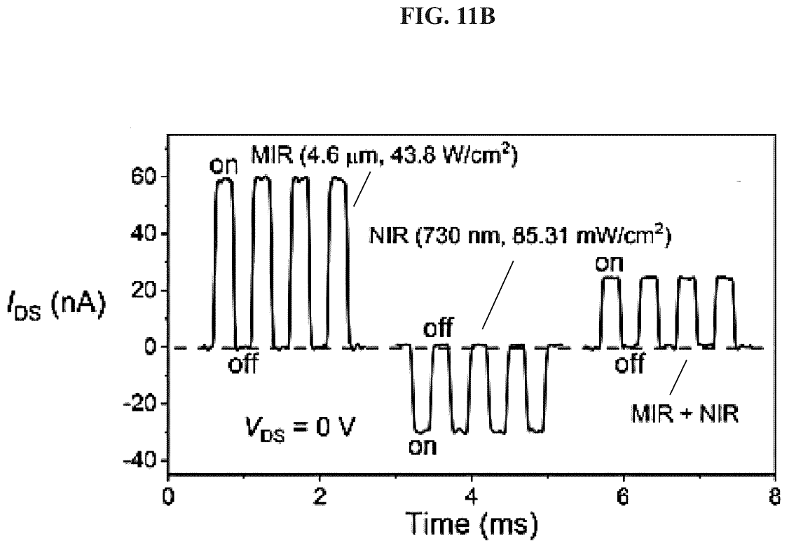

FIG. 11A shows the band schematic of the photothermoelectric (PTE) mode and the photovoltaic (PV) mode for perceiving mid-infrared (MIR) and near-infrared (NIR) respectively according to various embodiments. As shown in FIG. 11A, an unbalanced lattice temperature distribution is generated in b-AsP layer under MIR laser irradiation due to the asymmetric contacts of b-AsP with MoTe₂ and chromium/gold (Cr/Au) electrodes. The lattice temperature of b-AsP at the MoTe₂ conduct side is higher than that at Cr/Au electrode contact side because the thermal conductivity of MoTe₂ (~40 W m⁻¹ K⁻¹) is lower than that of Cr/Au (~200 W ml K⁻¹). Such lattice temperature distribution promotes the diffusion of holes in the b-AsP from the MoTe₂ contact side to Cr/Au electrode contact side, thus forming a positive PTE photocurrent under zero bias with b-AsP as the ground terminal. Under NIR laser excitation, the MoTe₂ layer generates electron-hole pairs which are separated by the built-in electrical field with direction pointing from b-AsP to MoTe₂ side at the junction. The photo-generated electrons and holes move toward b-AsP and MoTe₂, respectively, which contributes to the negative PV photocurrent.

FIG. 11B shows a plot of transduction current I_{DS} (in nano-Amperes or nA) as a function of time (in milliseconds or ms) illustrating time resolved I_{DS} of the optoelectronic device according to various embodiments under illumination with mid-infrared (MIR) and near-infrared (NIR) as well as simultaneous illumination of both MIR and NIR. The I_{DS} exhibits rapid changes with a response rate of ~20 μs when the illumination is switched on and off.

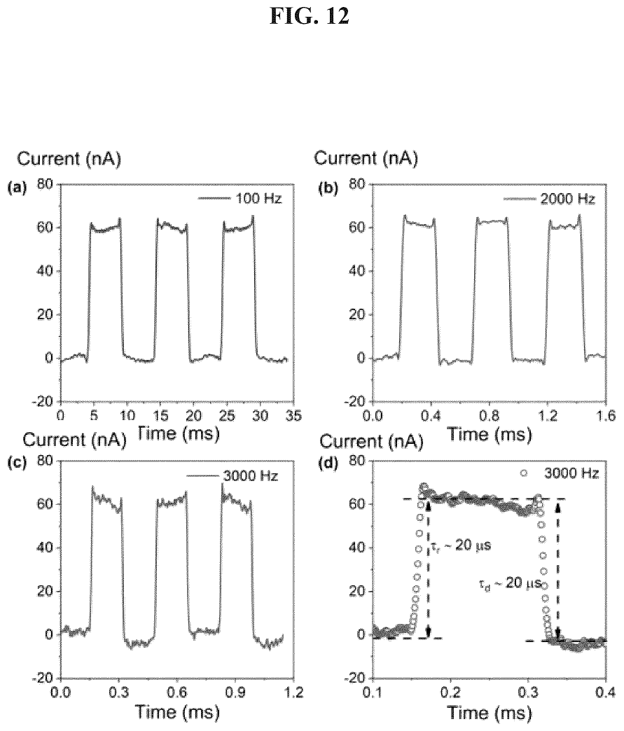

FIG. 12 shows transient behaviors and speed characteristics of the b-AsP/MoTe₂ optoelectronic device according to various embodiments under 4.6 μm laser illumination: (a) a plot of current (in nano-Amperes or nA) as a function of time (in milliseconds or ms) illustrating the transient photoresponse of the optoelectronic device according to various embodiments under pulsed 4.6 μm laser illumination with the frequency of 100 Hz; (b) a plot of current (in nano-Amperes or nA) as a function of time (in milliseconds or ms) illustrating the transient photoresponse of the optoelectronic device according to various embodiments under pulsed 4.6 μm laser illumination with the frequency of 2000 Hz; (c) a plot of current (in nano-Amperes or nA) as a function of time (in milliseconds or ms) illustrating the transient photoresponse of the optoelectronic device according to various embodiments under pulsed 4.6 μm laser illumination with the frequency of 3000 Hz; and (d) a plot of current (in nano-Amperes or nA) as a function of time (in milliseconds or ms) illustrating the response rate of the optoelectronic device according to various embodiments with a rising time of τᵣ=20 μs and a decay of τ_{d}=20 μs.

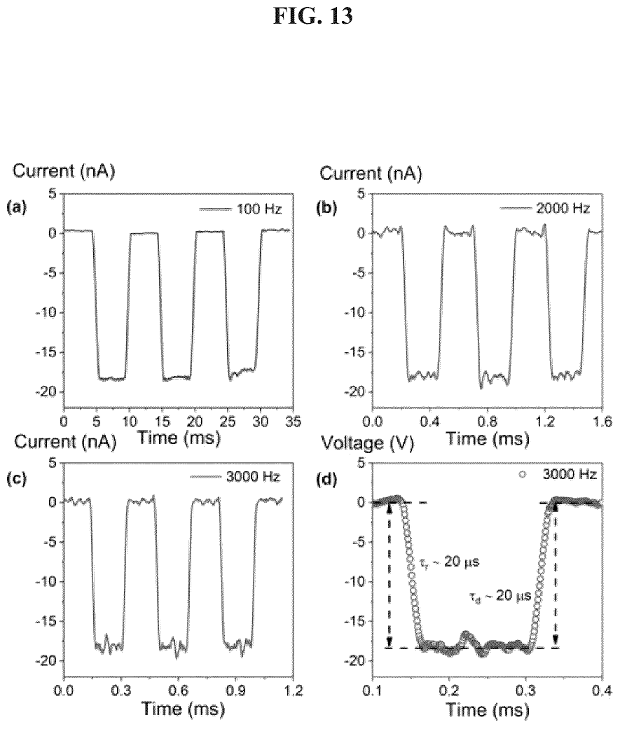

FIG. 13 shows transient behaviors and speed characteristics of the b-AsP/MoTe₂ optoelectronic device according to various embodiments under 730 nm laser illumination: (a) a plot of current (in nano-Amperes or nA) as a function of time (in milliseconds or ms) illustrating the transient photoresponse of the optoelectronic device according to various embodiments under pulsed 730 nm laser illumination with the frequency of 100 Hz; (b) a plot of current (in nano-Amperes or nA) as a function of time (in milliseconds or ms) illustrating the transient photoresponse of the optoelectronic device according to various embodiments under pulsed 730 nm laser illumination with the frequency of 2000 Hz; (c) a plot of current (in nano-Amperes or nA) as a function of time (in milliseconds or ms) illustrating the transient photoresponse of the optoelectronic device according to various embodiments under pulsed 730 nm laser illumination with the frequency of 3000 Hz; and (d) a plot of voltage (in volts or V) as a function of time (in milliseconds or ms) illustrating the response rate of the optoelectronic device according to various embodiments with a rising time of τᵣ=20 μs and a decay of τ_{d}=20 μs.

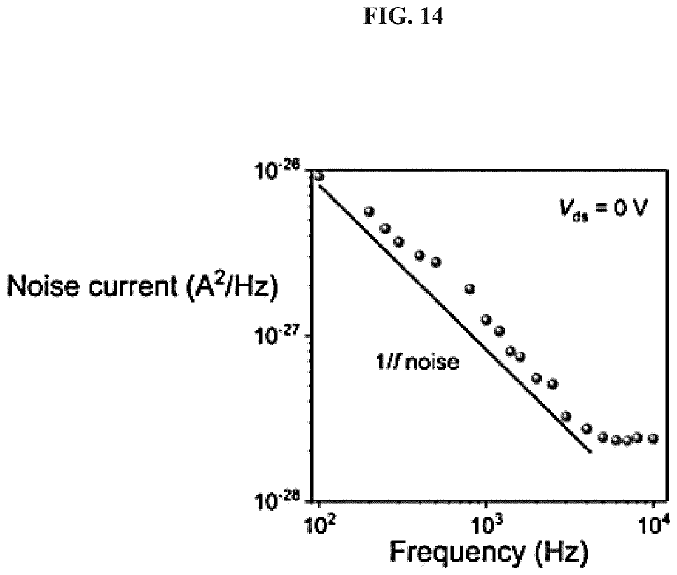

Moreover, the detectivity of the device to MIR illumination can reach up to ~3.1×10¹⁰ cm Hz^{0.5}/W. More details on the photoresponse performance under MIR and NIR illumination are provided in FIGS. 14-17.

FIG. 14 shows a plot of noise current (in square Amperes per Hertz or A²/Hz) as a function of frequency (in Hertz or Hz) illustrating to noise characteristics of the b-AsP/MoTe₂ optoelectronic device according to various embodiments at a source-drain voltage V_{DS}=0V. It is observed that the noise of the heterostructure is dominated by flicker (1/f) noise, which is attributed to the trapping and detrapping of charge carriers.

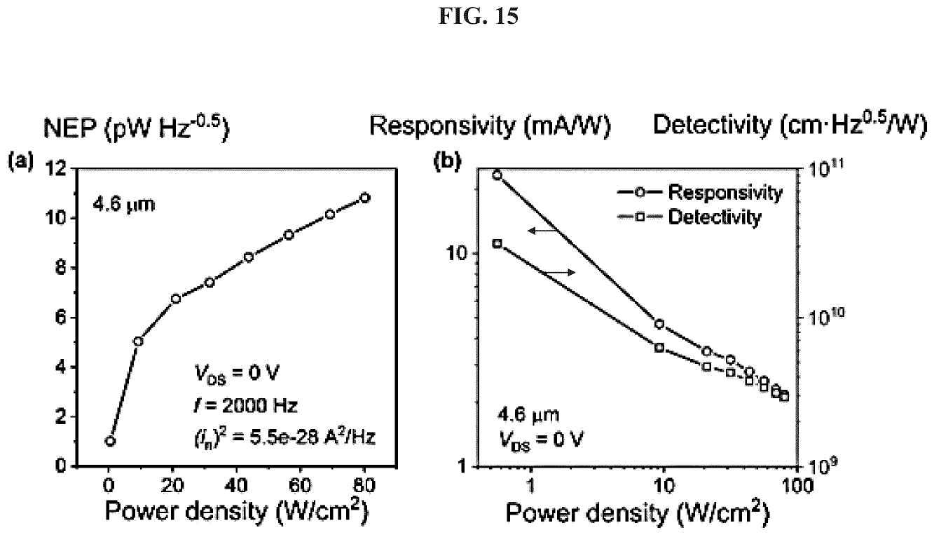

FIG. 15 shows photodetection performance of the optoelectronic device according to various embodiments under 4.6 μm laser illumination: (a) a plot of noise equivalent power NEP (in pico Watts per square root Hertz or pW Hz^{-0.5}) as a function of power density (in Watts per square centimeter or W/cm²) of the optoelectronic device according to various embodiments at source-drain voltage V_{DS}=0V and frequency f=2000 Hz; and (b) a plot of responsivity (in milli-Amperes per Watt or mA/W)/detectivity (in centimeter square root Hertz per Watt or cm·Hz^{0.5}/W) as a function of power density (in Watts per square centimeter or W/cm²) illustrating the power density-dependent responsivity and detectivity of the optoelectronic device according to various embodiments at source-drain voltage V_{DS}=0V.

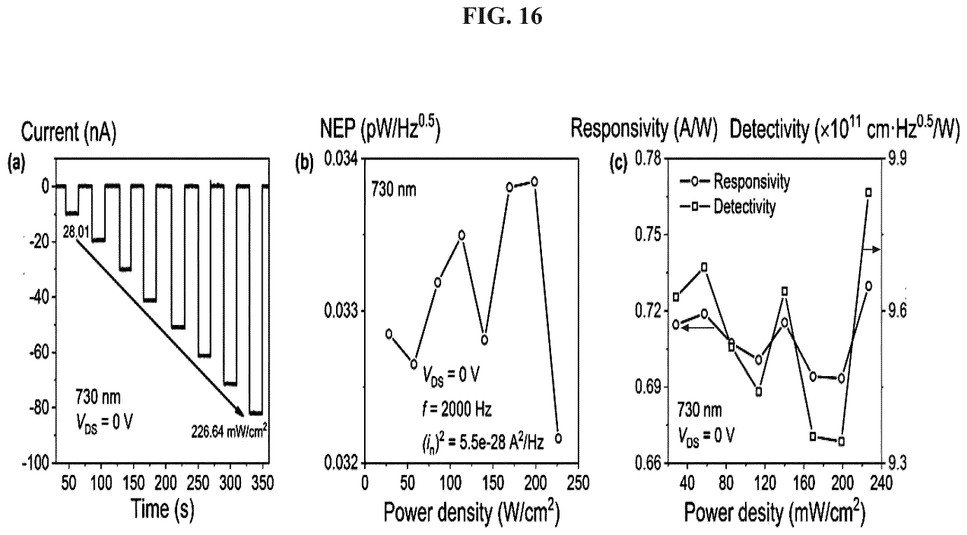

FIG. 16 shows photodetection performance of the optoelectronic device according to various embodiments under 730 nm laser illumination: (a) a plot of current (in nano-Amperes or nA) as a function of time (in seconds or s) illustrating the photoresponse switching behavior of the optoelectronic device according to various embodiments under illumination with various power densities; (b) a plot of noise equivalent power NEP (in pico Watts per square root Hertz or pW Hz^{-0.5}) as a function of power density (in watts per square centimeter or W/cm²) of the optoelectronic device according to various embodiments at source-drain voltage V_{DS}=0V and frequency f=2000 Hz; and (c) a plot of responsivity (in Amperes per Watt or A/W)/detectivity (×10¹¹, in centimeter square root Hertz per Watt or cm. Hz^{0.5}/W) as a function of power density (in milli-Watts per square centimeter or mW/cm²) illustrating the power density-dependent responsivity and detectivity of the optoelectronic device according to various embodiments for 730 nm illumination.

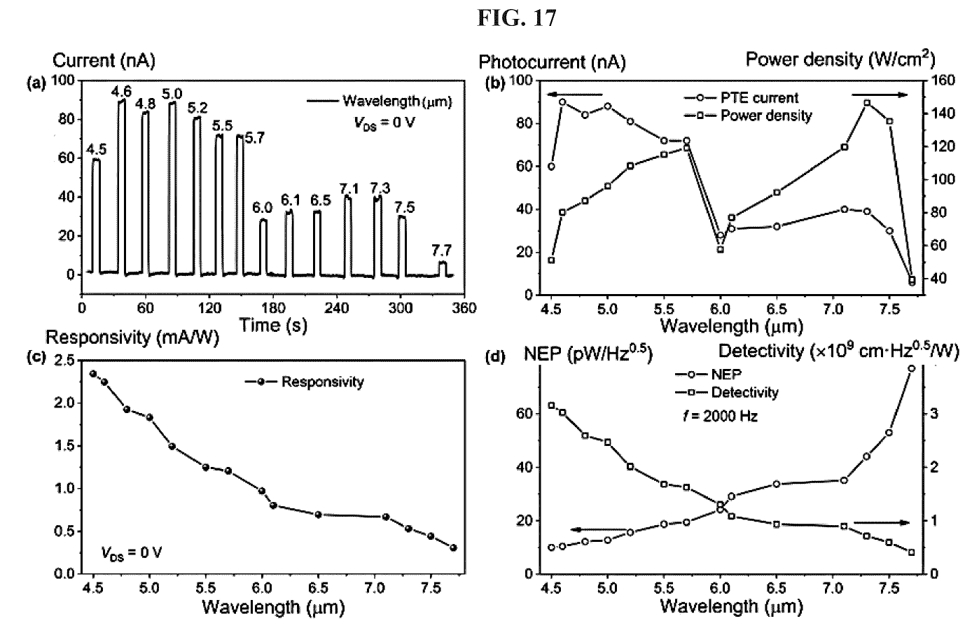

FIG. 17 shows the broadband mid-infrared (MIR) photoresponse characteristics of the optoelectronic device according to various embodiments at source-drain voltage V_{DS}=0V: (a) a plot of current (in nano-Amperes or nA) as a function of time (in seconds or s) illustrating the time-resolved photoresponse of the optoelectronic device according to various embodiments under illumination with various wavelengths from 4.5 to 7.7 μm; (b) a plot of photocurrent (in Nano-amperes or nA)/power density (in Watts per square centimeter or W/cm²) as a function of wavelength (in micrometers or μm) illustrating the photocurrent and laser power density of the optoelectronic device according to various embodiments corresponding to each wavelength; (c) a plot of responsivity (in milli-Amperes per Watt or mA/W) as a function of wavelength (in micrometers or μm) illustrating the wavelength-dependent responsivity of the optoelectronic device according to various embodiments; and (d) a plot of noise equivalent power NEP (in picoWatts per square root Hertz or pW Hz^{-0.3})/detectivity (×10⁹, in centimeter square root Hertz per Watt or cm·Hz^{0.5}/W) as a function of wavelength (in micrometers or μm) illustrating variation of NEP and detectivity of the optoelectronic device according to various embodiments with wavelength.

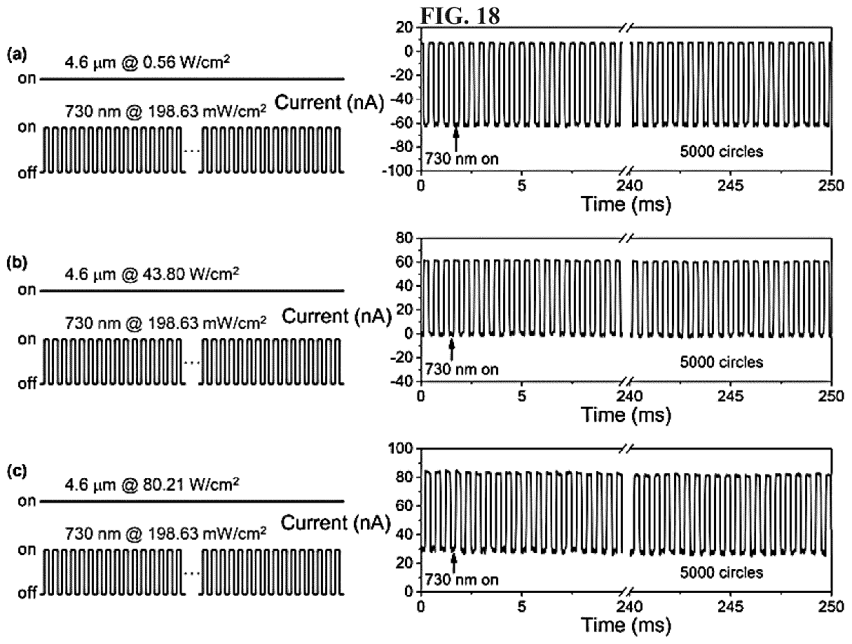

It can be clearly observed in FIG. 11B that the photocurrent generated by MIR and NIR excitations exhibit opposite polarity at V_{DS}=0 V, while under the simultaneous illumination, the I_{DS} (−24 nA) is close to the sum of the photocurrent generated by the individual illumination (60 nA at MIR, −30 nA at NIR). The photoresponse under the simultaneous illumination shows high repeatability and stability, evidenced by multiple and reproducible switching (FIG. 18).

FIG. 18 shows the reliability of the b-AsP/MoTe₂ optoelectronic device according to various embodiments under simultaneous illumination of both 4.6 μm and 730 nm: (a) illumination conditions (left) and corresponding current (in nano-Amperes or nA)-time (in milliseconds or ms) curves (right) when the 4.6 μm illumination is at 0.56 W/cm²; (b) illumination conditions (left) and corresponding current (in nano-Amperes or nA)-time (in milliseconds or ms) curves (right) when the 4.6 μm illumination is at 43.80 W/cm²; and (c) illumination conditions (left) and corresponding current (in nano-Amperes or nA)-time (in milliseconds or ms) curves (right) when the 4.6 μm illumination is at 80.21 W/cm². The good reliability was demonstrated with multiple and reproducible switching (5000 cycles). The 730 nm illumination is irradiated to the optoelectronic device in the form of pulses at a frequency of 2000 Hz.

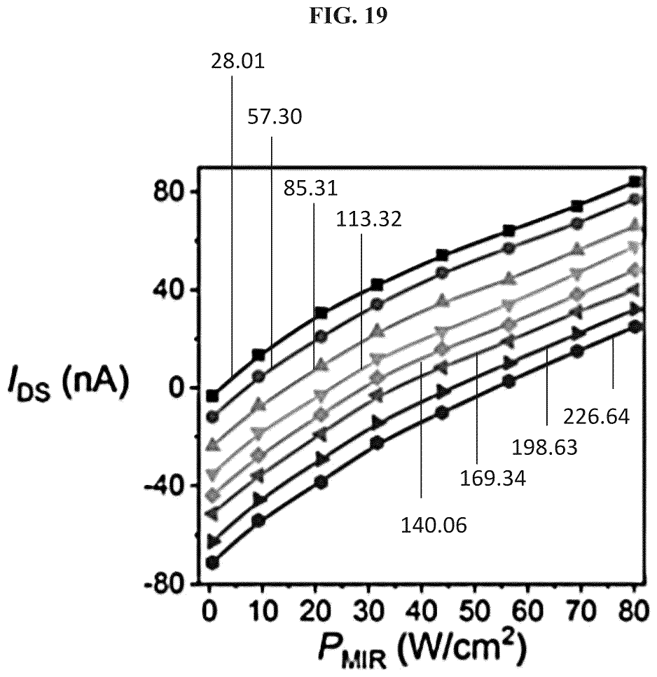

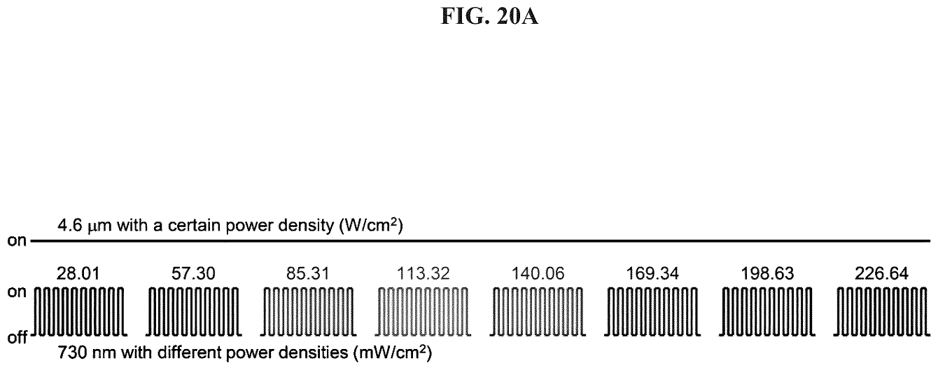

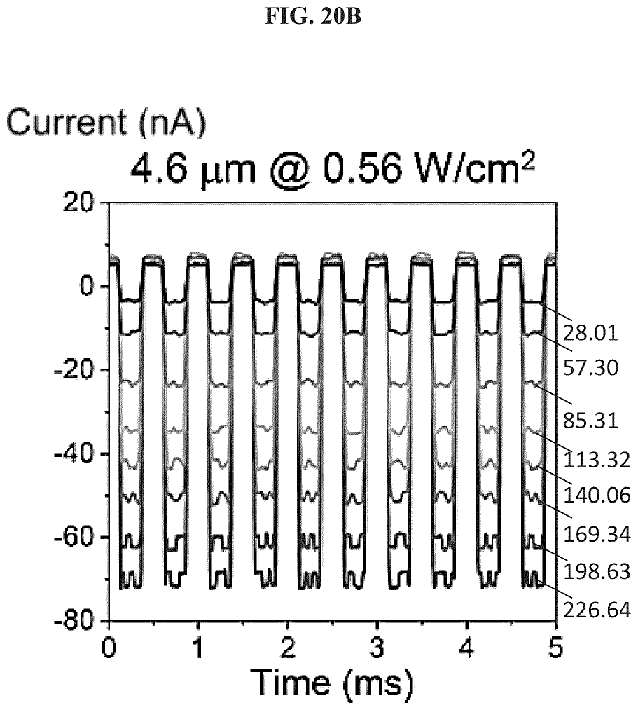

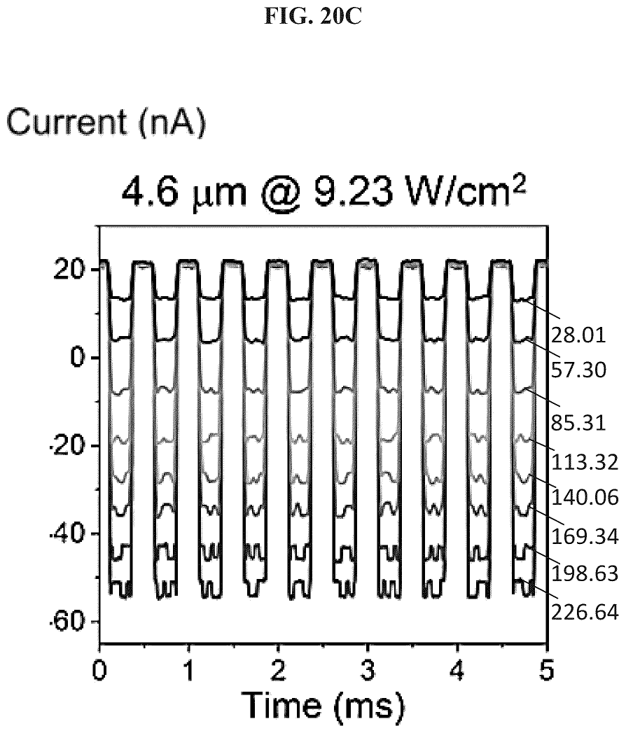

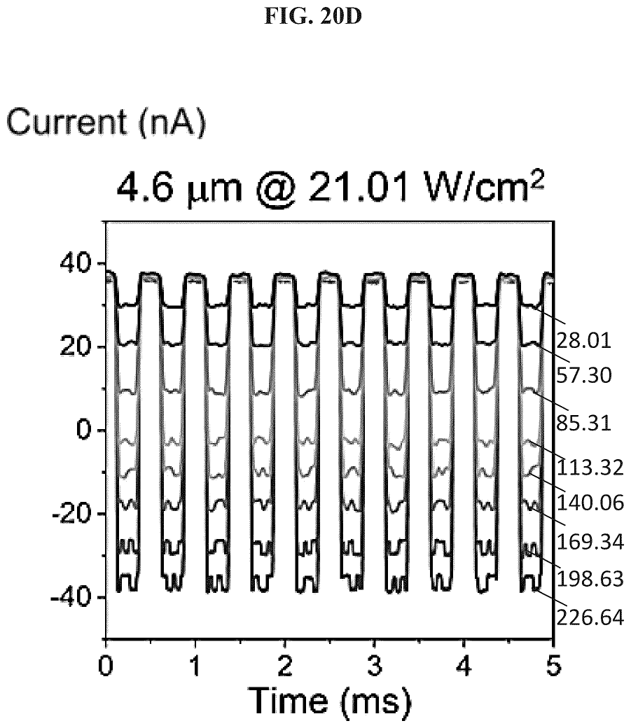

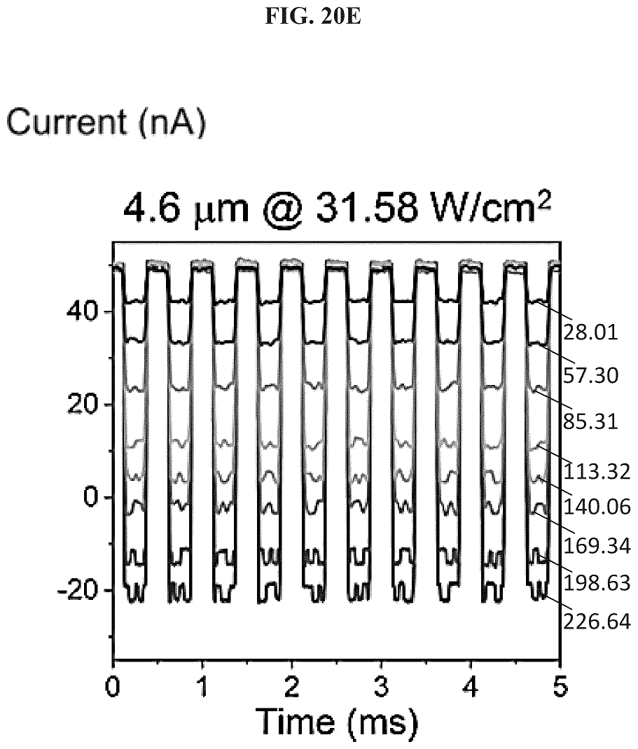

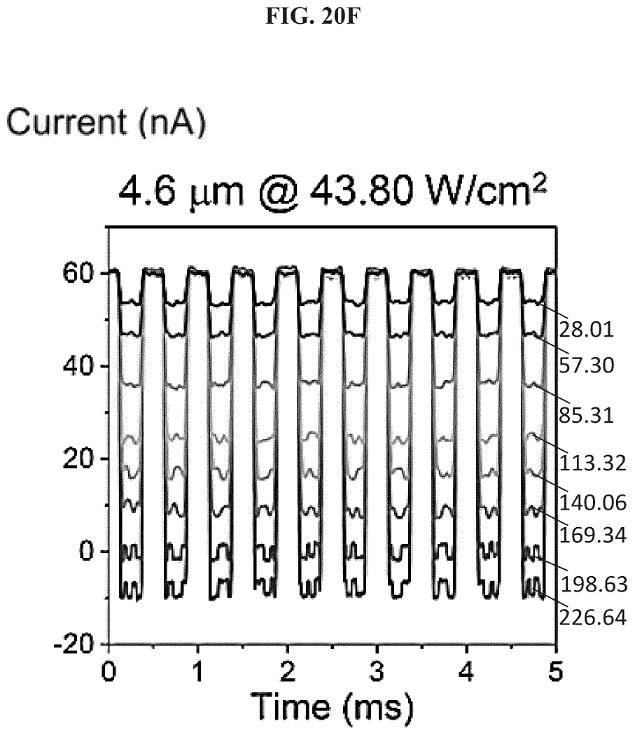

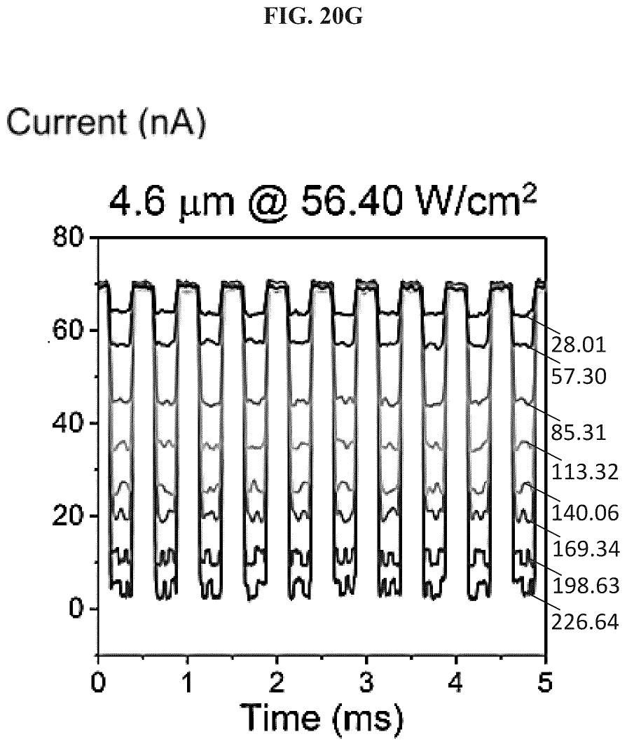

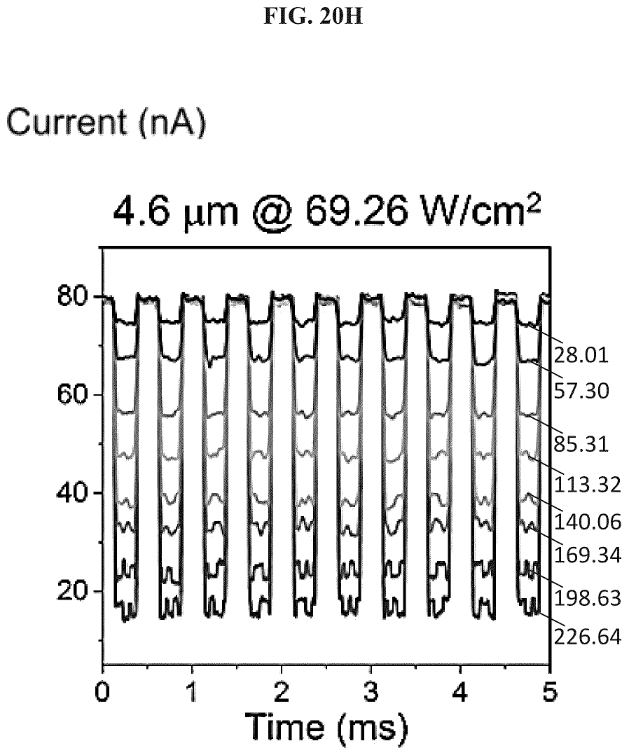

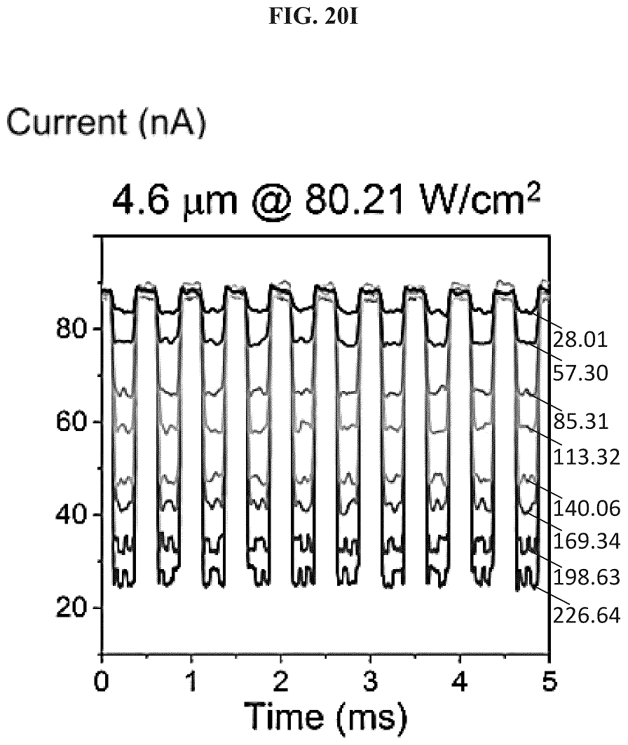

FIG. 19 shows a plot of transduction current I_{DS} (in nano-Amperes or nA) as a function of mid-infrared power density P_{MIR} (in Watts per square centimeter or W/cm²) illustrating the dependence of output current of the optoelectronic device according to various embodiments on the MIR power density under the modulation of near-infrared (NIR light) with various power densities (P_{NIR}, in milli-Watts per square centimeter or mW/cm²). FIG. 19 depicts the dependence of I_{DS} on the MIR illumination intensity at different NIR power densities (see FIG. 20A for more details), which is an important reference to obtain dynamic encoding range for MIR power density (P_{MIR}) once the I_{TC} and NIR power density (P_{NIR}) distribution are given.

FIG. 20A shows the measurement conditions of the optoelectronic device according to various embodiments, i.e. under simultaneous illumination of 4.6 μm illumination and various power densities of 730 nm illumination. FIG. 20B shows a plot of current (in nano-Amperes or nA) as a function of time (in milliseconds or ms) illustrating the photoresponse of the optoelectronic device according to various embodiments under 0.56 W/cm² of 4.6 μm illumination and various power densities of 730 nm illumination. FIG. 20C shows a plot of current (in nano-Amperes or nA) as a function of time (in milliseconds or ms) illustrating the photoresponse of the optoelectronic device according to various embodiments under 9.23 W/cm² of 4.6 μm illumination and various power densities of 730 nm illumination. FIG. 20D shows a plot of current (in nano-Amperes or nA) as a function of time (in milliseconds or ms) illustrating the photoresponse of the optoelectronic device according to various embodiments under 21.01 W/cm² of 4.6 μm illumination and various power densities of 730 nm illumination. FIG. 20E shows a plot of current (in nano-Amperes or nA) as a function of time (in milliseconds or ms) illustrating the photoresponse of the optoelectronic device according to various embodiments under 31.58 W/cm² of 4.6 μm illumination and various power densities of 730 nm illumination. FIG. 20F shows a plot of current (in nano-Amperes or nA) as a function of time (in milliseconds or ms) illustrating the photoresponse of the optoelectronic device according to various embodiments under 43.80 W/cm² of 4.6 μm illumination and various power densities of 730 nm illumination. FIG. 20G shows a plot of current (in nano-Amperes or nA) as a function of time (in milliseconds or ms) illustrating the photoresponse of the optoelectronic device according to various embodiments under 56.40 W/cm² of 4.6 μm illumination and various power densities of 730 nm illumination. FIG. 20H shows a plot of current (in nano-Amperes or nA) as a function of time (in milliseconds or ms) illustrating the photoresponse of the optoelectronic device according to various embodiments under 69.26 W/cm² of 4.6 μm illumination and various power densities of 730 nm illumination. FIG. 20I shows a plot of current (in nano-Amperes or nA) as a function of time (in milliseconds or ms) illustrating the photoresponse of the optoelectronic device according to various embodiments under 80.21 W/cm² of 4.6 μm illumination and various power densities of 730 nm illumination.

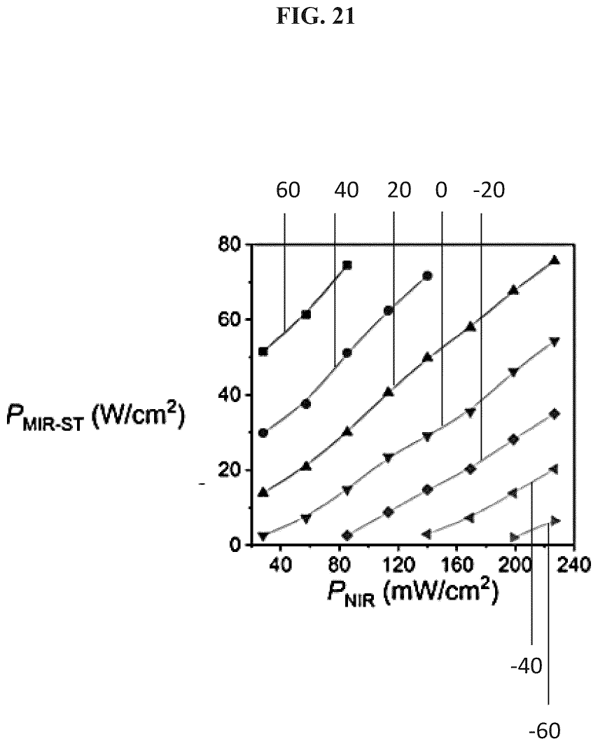

FIG. 21 is a plot of spiking threshold P_{MIR-ST} (in Watts per square centimeters or W/cm²) and a function of mid-infrared power density P_{MIR} (in milli-Watts per square centimeter or mW/cm²) illustrating the different P_{MIR-ST}−P_{MIR} at different threshold currents (I_{TC}, in nano-Amperes or nA) according to various embodiments. P_{MIR-ST} may be defined as the MIR power density require to initiate a current spike, i.e. I_{DS}>I_{TC}. FIG. 21 presents the spiking threshold P_{MIR-ST} of the optoelectronic device, i.e. the P_{MIR} required to initiate a spike under a fixed I_{Tc} and P_{NIR}. Only the P_{MIR} higher than P_{MIR-ST} can be encoded dynamically.

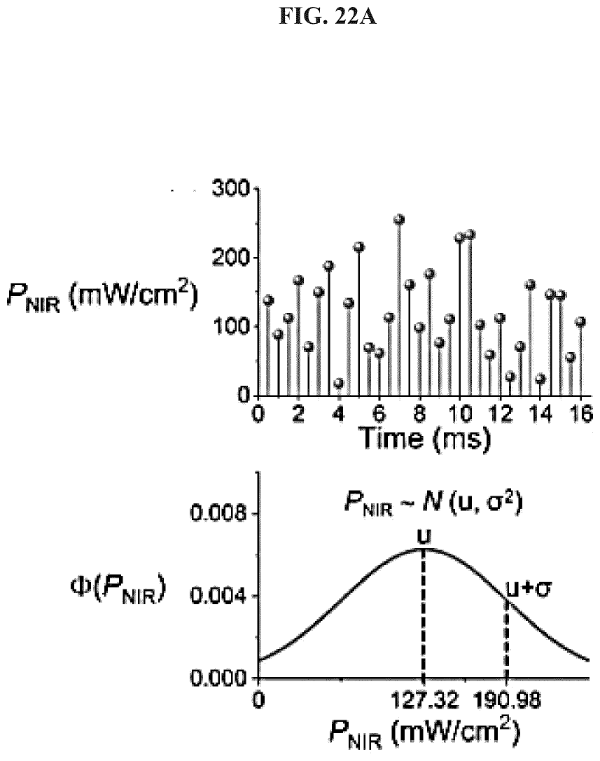

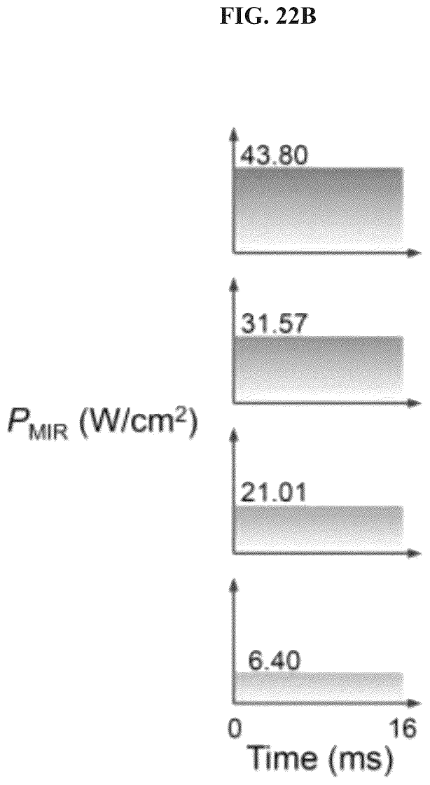

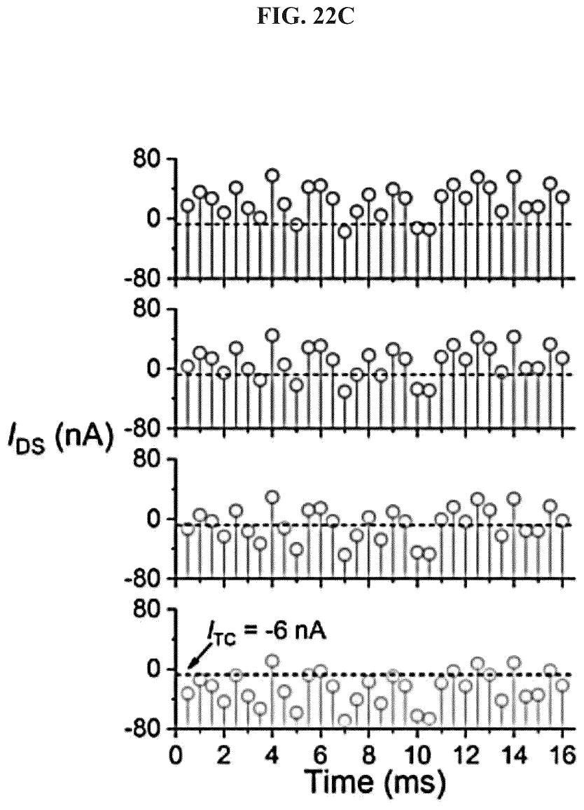

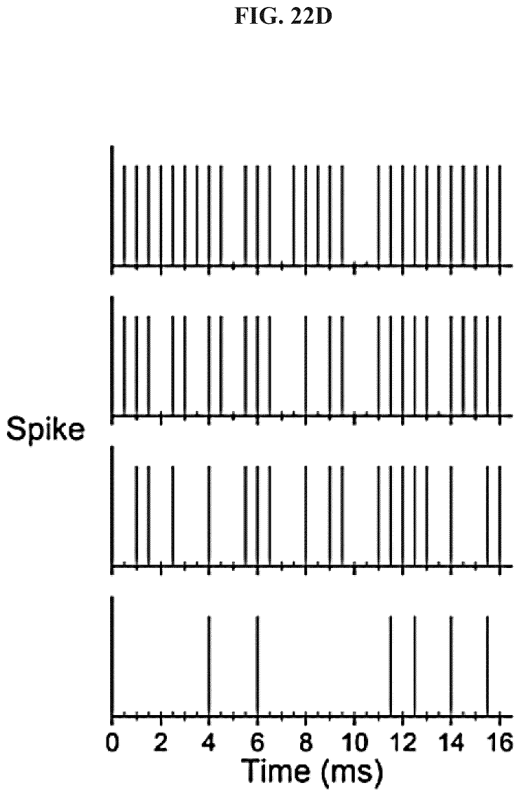

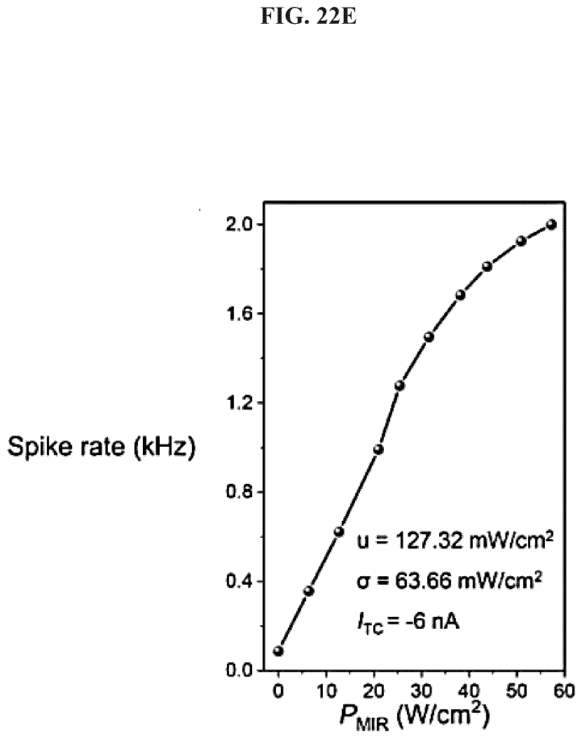

Next, the function of simultaneous perception and spike rate-based encoding for P_{MIR} is experimentally demonstrated. The NIR laser is applied as sampling pulses with amplitude following a Gaussian distribution with a pulse duration of 0.5 ms, which is analogous to inherent stochasticity. FIG. 22A shows (above) one trail of near infrared (NIR) optical pulses (32 pulses for one trail) that is randomly sampled from a Gaussian distribution according to various embodiments for spike rate encoding; and (below) the Gaussian distribution of NIR power densities with mean of u=127.32 mW cm⁻² and a standard deviation of σ=63.66 mW cm⁻² according to various embodiments.

When the NIR sampling pulse and MIR light with a specific intensity are simultaneously illuminated on the device, the response corresponding to each P_{MIR} (FIG. 22B) is recorded by I_{DS}. FIG. 22B shows plots of mid-infrared power density P_{MIR} (in Watts per square centimeter or mW/cm²) as a function of time (in milliseconds or ms) illustrating the analog values of various intensities of mid-infrared (MIR) illumination according to various embodiments. The P_{MIR} is encoded by 16 trails of NIR optical pulses train (32 spikes for one trail) and therefore results in a sequence of I_{DS} with 512 sampling points. More sampling points for one MIR intensity can guarantee higher encoding quantization accuracy. One trail of as-recorded I_{DS} trails with I_{TC}=−6 nA and corresponding spike trains are shown in FIG. 22C and FIG. 22D, respectively. FIG. 22C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 22B according to various embodiments. The sampling rate for NIR light is 2 kHz. FIG. 22D shows a plot of spike as a function of time (in milliseconds or ms) illustrating the corresponding spike train for each transduction current (I_{DS}) waveform in FIG. 22C when the spike threshold current (I_{TC}) is set to −6 nA according to various embodiments. The I_{DS} higher than I_{TC} could stimulate one spike, which can be realized by a sample operation circuit. Average spike rate for each P_{MIR} is calculated according to the generated spike train, as shown in FIG. 22E. FIG. 22E shows a plot of mean spike rate (in kilo-Hertz or kHz) as a function of mid-infrared power density P_{MIR} (in Watts per square centimeter or W/cm²) of the optoelectronic device according to various embodiments when mean (u)=127.32 mW cm⁻², standard deviation (σ)=63.66 mW and threshold current (I_{TC})=~6 nA. It can be clearly observed that the device is capable of simultaneously perceiving and encoding the P_{MIR} within ~56 W cm⁻². For high-power regions (P_{MIR}>56 W cm⁻²), the encoding operation requires an NIR sampling pulse with a higher u and σ. However, the I_{DS} shows non-negligible fluctuation under higher P_{NIR}, which is not conducive to high-precision coding. In this work, the optimized P_{NIR} range of 0 to 255 mW cm⁻² may be employed, which allows the maximum achievable P_{MIR} for encoding to be ~56 W cm⁻¹.

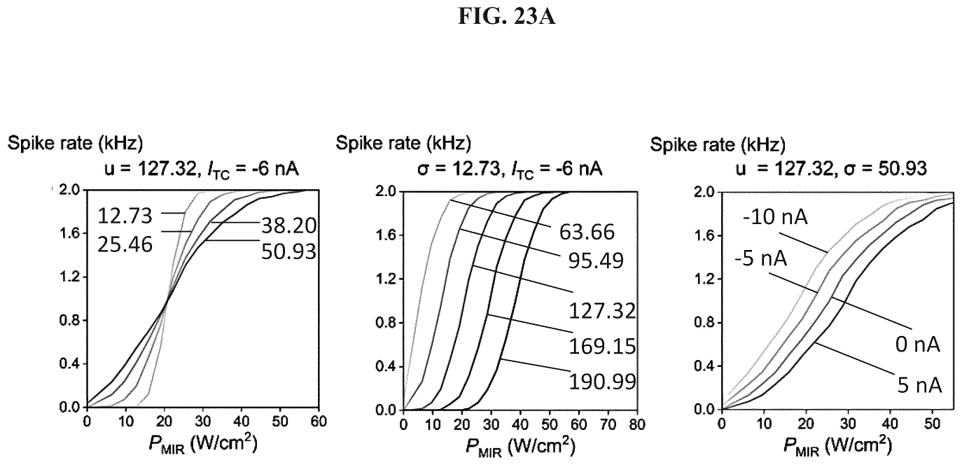

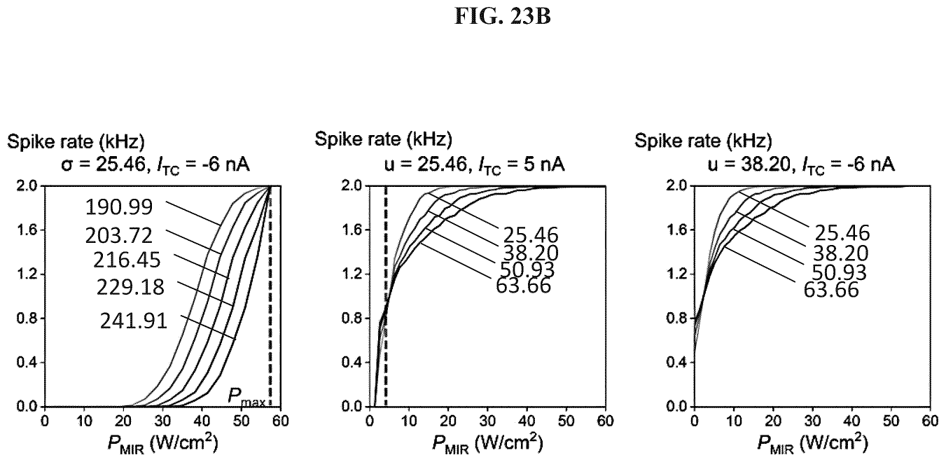

FIG. 23A shows plots of spike rate (in kilo-Hertz or kHz) as a function of mid-infrared power density P_{MIR} (in Watts per square centimeter or W/cm²) illustrating the simulation of spike rate with P_{MIR} for different mean (u), standard deviation (σ) and threshold current (I_{TC}) of the Gaussian distribution of sampling 730 nm light according to various embodiments. Clipping operation on the power density of 730 nm laser is essential to avoid excessive heat effect on the device. FIG. 23B shows plots of spike rate (in kilo-Hertz or kHz) as a function of mid-infrared power density P_{MIR} (in Watts per square centimeter or W/cm²) illustrating the clipping operation on dynamic working range according to various embodiments.

Adaption occurs in all sensory systems to help them efficiently encode external stimuli as the stimuli distribution changes. For example, the human eyes can identify objects both in starlight and in sunlight by changing neural encoding strategy during the adaption process. For intelligent MIR version tasks, a high-performance MIR retinomorphic device should also have such visual adaption ability to satisfy various application scenarios. Two related aspects of the visual adaption ability, namely, dynamic working range and encoding precision are discussed here. A high dynamic working range allows the device to respond to more extreme MIR signal stimuli. Therefore, two targets with distinct P_{MIR} difference can be identified at the same time. For example, the temperature of pig iron and steel strips in industrial process is 427 K and 1457.85 K, respectively. Their P_{MIR} differs over a dynamic range of ~24 dB if they are regarded as two ideal blackbodies according to Plank's radiation law. However, the wide dynamic working range sacrifices the encoding precision which represents the similarity between original targets and encoded results. The dynamic working range is hence required of compression to attain high encoding precision for some cases that the details of P_{MIR} distribution inside targets need to be accurately identified, such as MIR imaging of human body for medical diagnosis.

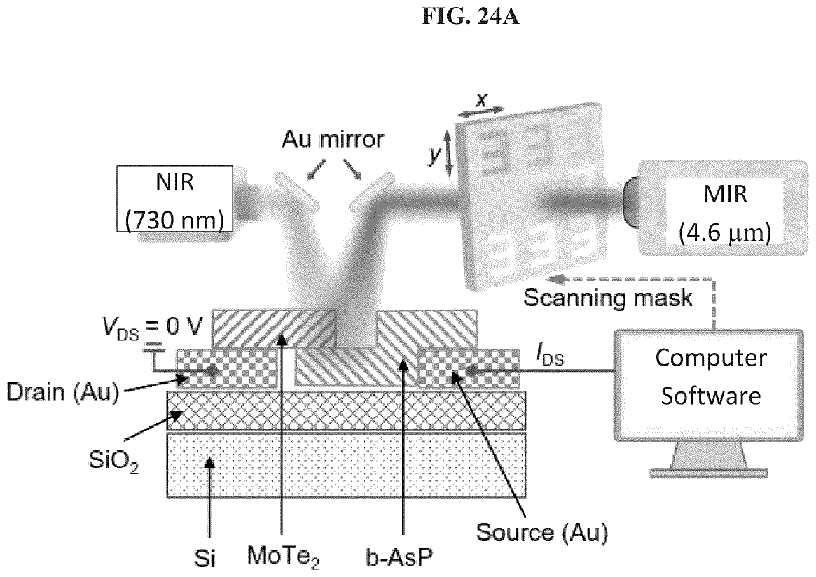

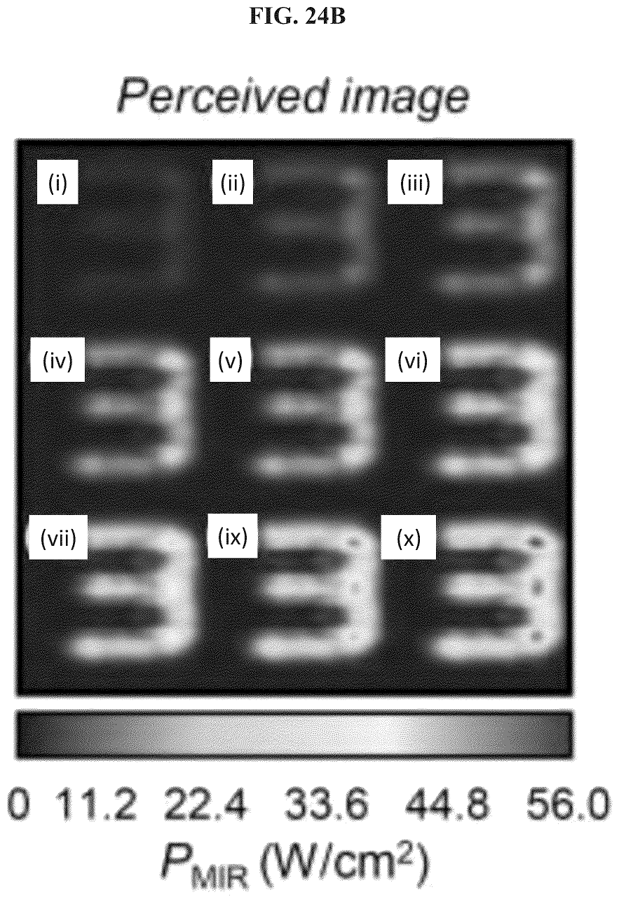

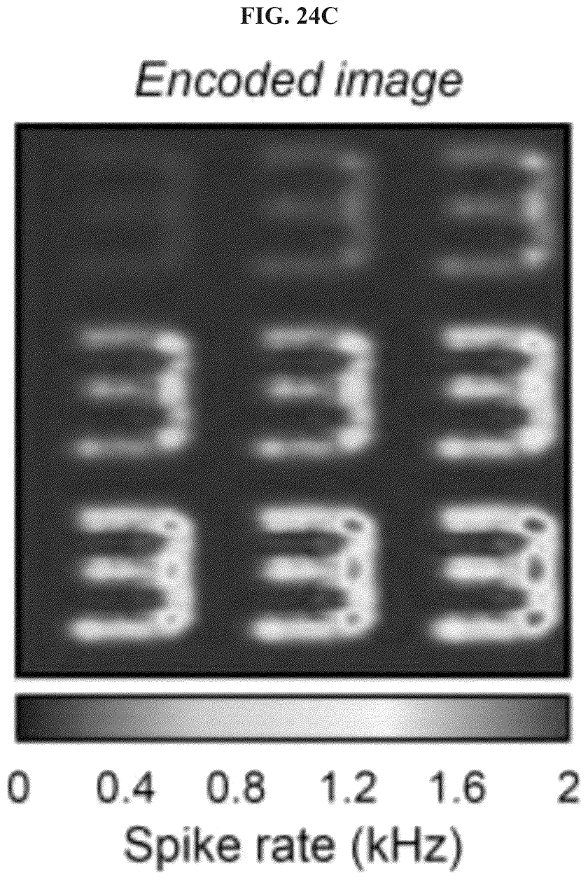

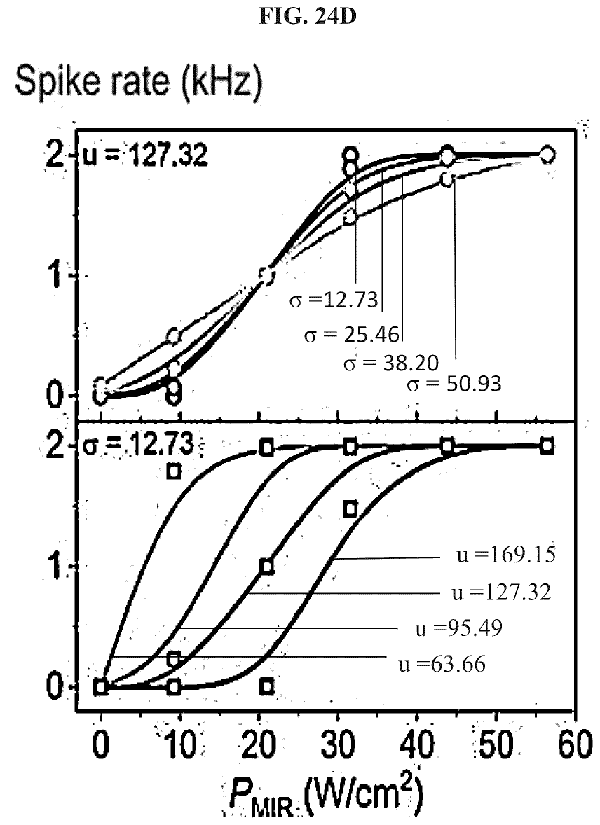

To demonstrate the adaption ability of the MIR retinomorphic device, a testing setup is established as shown in FIG. 24A. FIG. 24A is a schematic showing a testing setup to evaluate perception and encoding ability of the optoelectronic device according to various embodiments. A two-dimensional (2D) metal mask with nine hollow figures ‘3’ illuminated by a power adjustable 4.6 μm MIR laser is used to imitate the real MIR targets. The mask can move along the x and y axis to allow MIR light to pass each target in order. A controller may be used to move the mask. By adjusting the output optical power of MIR laser, the P_{MIR} distribution of each target ‘3’ is different (i.e. linearly distributed within 0 to 56 mW cm⁻²). The real P_{MIR} distribution of nine targets ‘3’ is measured by photocurrent mapping method and presented in FIG. 24B. FIG. 24B shows a photocurrent map illustrating the mid-infrared power densities (PM) of the nine targets according to various embodiments. For convenience, nine targets ‘3’ are named as (i) to (vii), (ix) and (x) in incremental order of P_{MIR}. To encode the P_{MIR} distribution of targets into corresponding spike trains, another NIR light, whose P_{NIR} is sampled from a Gaussian distribution with mean (u) of 127.32 mW cm⁻² and standard deviation (σ) of 63.66 mW cm⁻², is also incident into the optoelectronic device at the same time. The recognized image after rate encoding by the optoelectronic device is shown in FIG. 24C. FIG. 24C shows an encoded image after encoding the mid-infrared power densities (P_{MIR}) of the nine targets in FIG. 24B into corresponding spike rates ranging from 0 kHz to 2 kHz according to various embodiments. The correlation coefficient (CC), which refers to the similarity of an encoded targets and a corresponding original one, exceeds 98% for each of the targets, validating that the optoelectronic device has an excellent encoding precision. This may be attributed to the fast response reaching 2 kHz that provides sufficient rate encoding resources for high P_{MIR} resolution.

The adjustment of u and σ for sampling the P_{NIR} can be used for tuning the dynamic working range. The increase of σ extends the dynamic working range, while the increase of u shifts the dynamic working range to a high P_{MIR} range, as presented in FIG. 24D and FIGS. 23A-B.

FIG. 24D shows plots of spike rate (in kilo-Hertzs or kHz) as a function of mid-infrared power density P_{MIR} (in Watts per square centimeters or W/cm²) illustrating experimental results of spike rate P_{MIR} with different means u and standard deviations σ according to various embodiments.

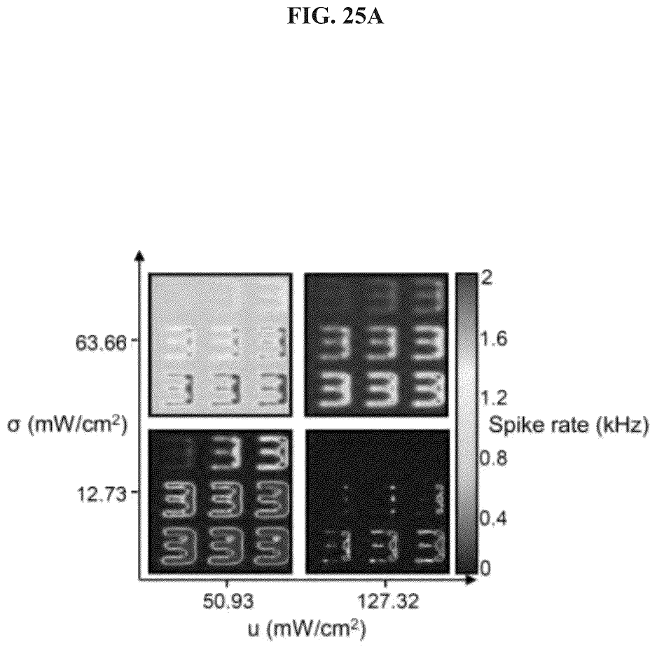

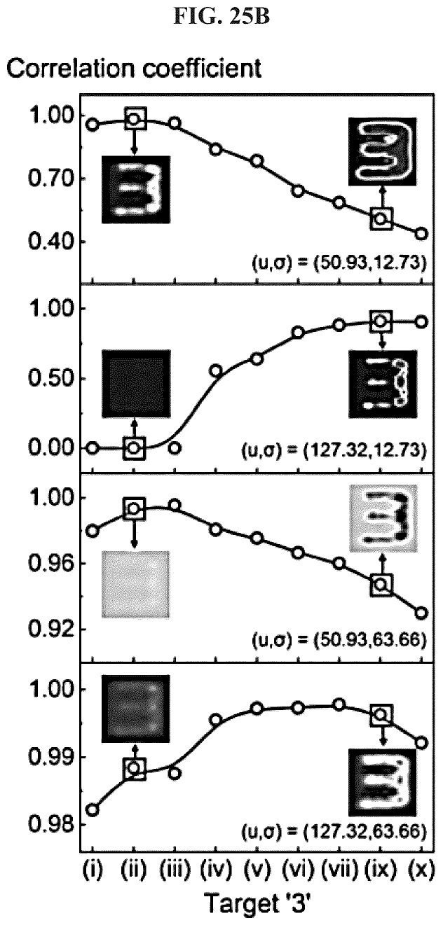

Such dependence can also be observed from the encoded images in FIG. 25A and correlation coefficients (CCs) in FIG. 25B in different cases of u and σ. FIG. 25A shows plots of standard deviation σ (in milli-Watts per square centimeters or mW/cm²) as a function of mean u (in milli-Watts per square centimeters or mW/cm²) illustrating results of encoding images under different sets of u and σ according to various embodiments. Such parameter adjustment may allow the system to adjust dynamic working range and encoding precision to adapt different MIR targets with varied P_{MIR}. FIG. 25B illustrates the correlation coefficients (CC) between the results in FIG. 25A and the corresponding results in FIG. 24B for different cases of mean u and standard deviation σ according to various embodiments, with the insets being the images of targets (ii) and (ix). The threshold current (I_{TC}) used is-6 nA.

For example, when the (u, σ) changes from (50.93, 12.73) to (127.32, 12.73), the dynamic working range shifts to the high P_{MIR} range, which results in the correct encoding of target (ix) with CC improving from 51% to 91% and failed encoding of target (ii) with CC falling to 0%. When the σ is increased from 12.73 to 63.66 at u=50.93, the CCs of targets (ii) and (ix) are both improved to above 92%, indicating the extension of dynamic working range. On the other hand, the background noise of the encoded image is magnified at (u, σ)=(50.93, 63.66) due to the no-zero spike rate at P_{MIR}=0, causing an extra interference for identifying targets. A larger u=127.32 can suppress the background noise, improving the CCs of all targets to more than 98% as shown in the bottom curve of FIG. 25B. To magnify the details of P_{MIR} distribution inside one certain target, a high encoding precision may be required and may be achieved by decreasing σ under a suitable u. For example, the target (ii) at (u, σ)=(50.93, 12.73) has a higher contrast than the case at (u, σ)=(50.93, 63.66). Therefore, optimizing the u and σ values may be critical in achieving a suitable dynamic working range and encoding precision for the realization of visual adaption to different MIR targets.

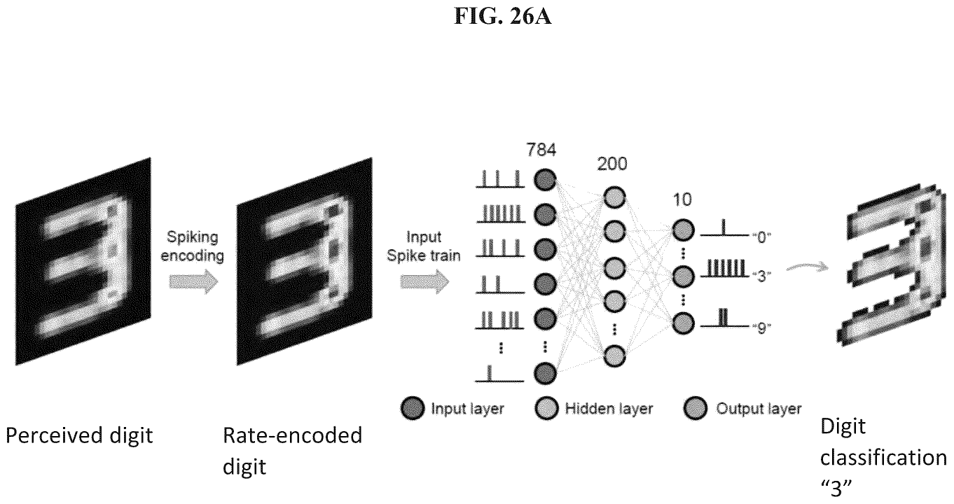

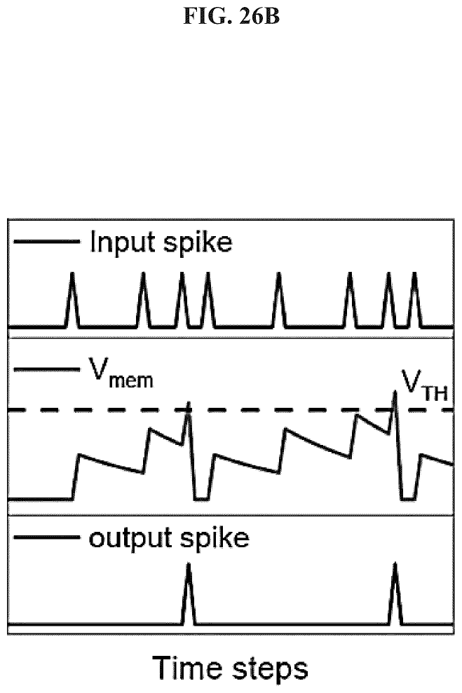

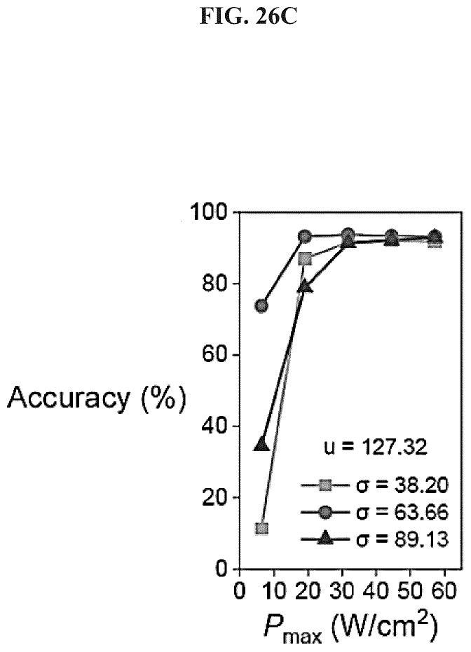

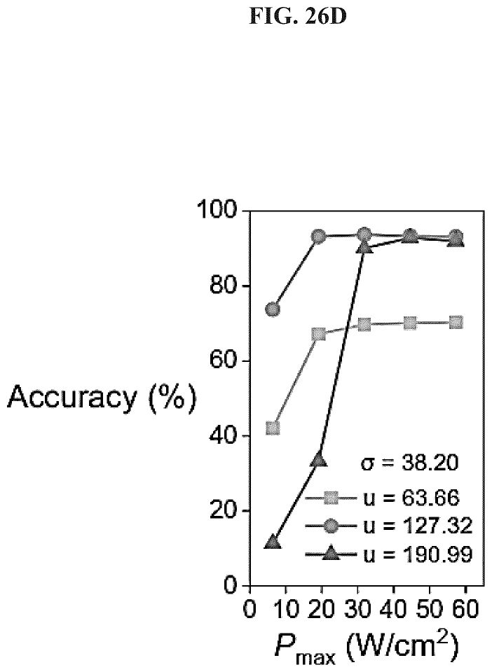

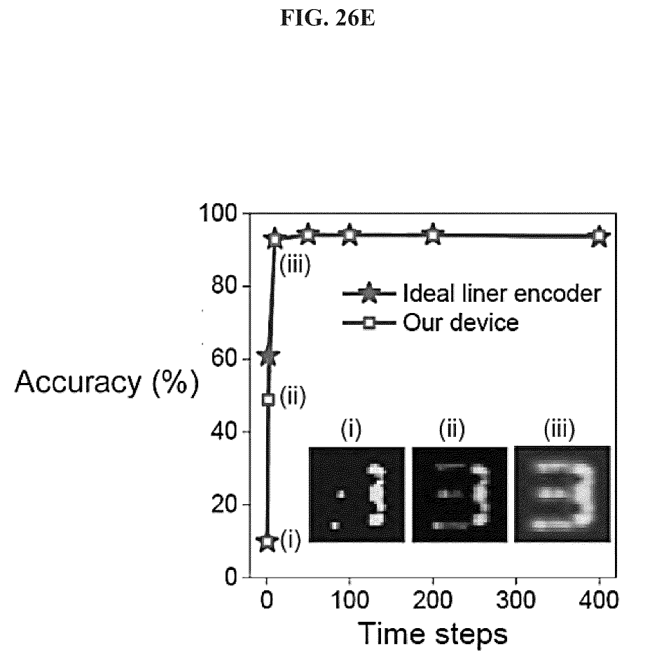

Lastly, the optoelectronic device may be used to encode the MIR MNIST data set into spike trains, which enables the successful realization of SNN-based digit-classification tasks with inference accuracy of more than 94%. Compared to traditional artificial neural network (ANN), SNN is believed to be a more efficient neural network that rarely requires high-precise multiplication. Also, the density of binary spikes required for SNN is much sparser than that for ANN, mitigating the storage memory and energy requirements. The sunTorch platform introduced by Jason K. Eshraghian may be used to establish a fully-connected three-layers SNN that consists of the input layer, hidden layer and output layer with 784, 200 and 10 neurons, respectively, as shown in FIG. 26A.

FIG. 26A shows the mid-infrared (MIR) image being perceived and rate-based encoded into spike trains which enter a trained fully-connected spiking neural network (SNN) to realize digit classification task according to various embodiments. The corresponding digit of the output neuron having the highest spike rate is the predicted result. Each image in the MIR MNIST data set with a size of 28×28 pixels is perceived and encoded by the optoelectronic device into 784 spike trains that concurrently enter into the input layer of a trained SNN. The training and parameters optimization methods for SNN are described below. The 10 neurons in the output layer shown in FIG. 26A represent digits from 0 to 9. The neuron producing the spike train with the highest spike rate corresponds to the digit that SNN predicts. The neuron connection between the two layers is described by a leaky integrated-and-fire (LIF) neuron model as shown in FIG. 26B.

FIG. 26B illustrates the leaky integrate-and-fire (LIF) neuron model used in the spiking neural network (SNN) according to various embodiments. The membrane voltage (Vₘₑₘ) increases with the input spike until it reaches a constant threshold (V_{TH}) at which an output spike appears and the Vₘₑₘ is reset to zero. During the period without input spike, the Vₘₑₘ decays with the membrane potential decay rate (β) of 0.95. The input pre-neuronal spikes Xᵢ(t) are modulated by synaptic weights Wᵢ to produce a resultant current

$${\sum }_{i = 1}^{k} {W}_{i}^{T} {X}_{i} ( t ) ,$$

which affects the membrane potential Vₘₑₘ of the post-neuron in the next neuron layer, given as:

$${V}_{mem} ( t + 1 ) = {βV}_{mem} ( t ) + {\sum }_{i = 1}^{k} {W}_{i}^{T} {X}_{i} ( t ) - R [ {βV}_{mem} ( t ) + {\sum }_{i = 1}^{k} {W}_{i}^{T} {X}_{i} ( t ) ] \\ R = \{ \begin{matrix}1 , if {V}_{mem} > {V}_{TH} \\ 0 , otherwise\end{matrix}$$

where β, i and k are membrane potential decay rate, neuron index and the number of neurons in this layer, respectively. The Tis the transposition operation. The Vₘₑₘ of the post-neuron will integrate incoming spikes until it reaches membrane threshold V_{TH} where the Vₘₑₘ is reset to zero. Meanwhile, the post-neuron generates an output spike which acts as the input spike of next neuron layer.

The classification performance of SNN significantly depends on the dynamic working range and encoding precision of the device. As mentioned above, the u and σ values of Gaussian distribution for sampling NIR light control the dynamic working range and encoding precision. If the dynamic working range mismatches the P_{MIR} range of the target within [0, Pₘₐₓ] or the encoding precision is insufficient, the inaccurate translation of the target by encoded spikes will increase the inference error of SNN.

The classification accuracy of SNN versus different maximum power density Pₘₐₓ of MIR MNIST images at different σ and u for the sampling of NIR light is described in FIG. 26C and FIG. 26D, respectively. FIG. 26C is a plot of accuracy (in percent or %) as a function of maximum power density Pₘₐₓ (in Watts per square centimeter or W/cm²) illustrating variation of accuracy with Pₘₐₓ at various standard deviations σ according to various embodiments. FIG. 26D is a plot of accuracy (in percent or %) as a function of maximum power density Pₘₐₓ (in Watts per square centimeter or W/cm²) illustrating variation of accuracy with Pₘₐₓ at various means u according to various embodiments. The u, I_{TC} and time steps in FIG. 26C are 127.32 mW cm⁻², −6 nA and 200, respectively. The σ, I_{TC} and time steps in FIG. 26D are 38.20 mW cm⁻², −6 nA and 200, respectively.

FIGS. 26C-D show the classification accuracy of SNN when the Pₘₐₓ of MIR MNIST test set varies from 0 to 56 W cm⁻² at different values of u and σ. A relatively low σ of 38.20 makes the dynamic working range too narrow to encode the digits with Pₘₐₓ lower than 10 W cm⁻², resulting in 11.2% classification accuracy. When σ increases to 63.66 mW cm⁻², the enlarged dynamic working range can cover both low and high Pₘₐₓ and may allow the classification accuracy to become higher than 92%. However, the further increase of σ to 89.13 mW cm⁻² decreases the encoding precision because the spike rate difference is not sufficient enough to support accurate classification for the low-Pₘₐₓ case. Additionally, the background noise is magnified, hampering the successful classification of SNN. Similarly, the u value controls the position of the dynamic working range. For example, a relatively low u=63.66 mW cm⁻² will also magnify the background noise and greatly decrease the classification accuracy. A relatively high u=190.99 mW cm²² results in low classification accuracy for digits with low P_{MIR}. The time steps for sampling NIR light (representing the number of required time points when sampling NIR light for encoding one MIR intensity) also influences the classification accuracy of SNN. If the device works at the optimal (u, σ)=(127.32, 38.20) for targets with Pₘₐₓ of 31.83 W cm⁻², a very high classification accuracy of up to 94% can be achieved only with 10 time steps as shown in inset (iii) of FIG. 26E. FIG. 26E shows a plot of accuracy (in percent or %) as a function of time steps illustrating the classification accuracy of the spiking neural network (SNN) according to various embodiments versus the time steps of one spike train when Pₘₐₓ is 31.83 W cm⁻², with insets (i)-(iii) showing the encoded images of “3” when the time steps are 1, 2 and 10, respectively.

The time steps lower than 10 will result in an inadequate representation of digits as shown in the insets (i)-(ii). It is noteworthy that for the low encoding precision cases, the increase in the sampling points can enhance the classification accuracy by improving the quantitative accuracy of the spike rate. For example, for the case with (u, σ)=(63.66, 38.20) whose spike rate ranges from 0.25 to 2 kHz, 70% accuracy can be achieved with 200 sampling points, while 50 sampling points can only lead to 49% accuracy.

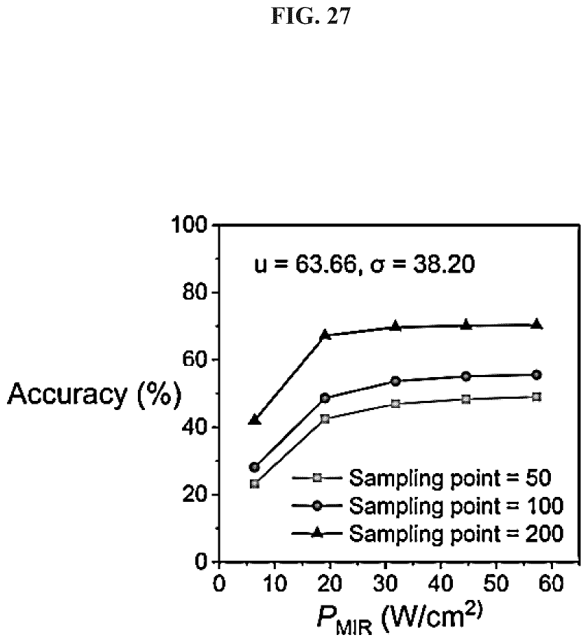

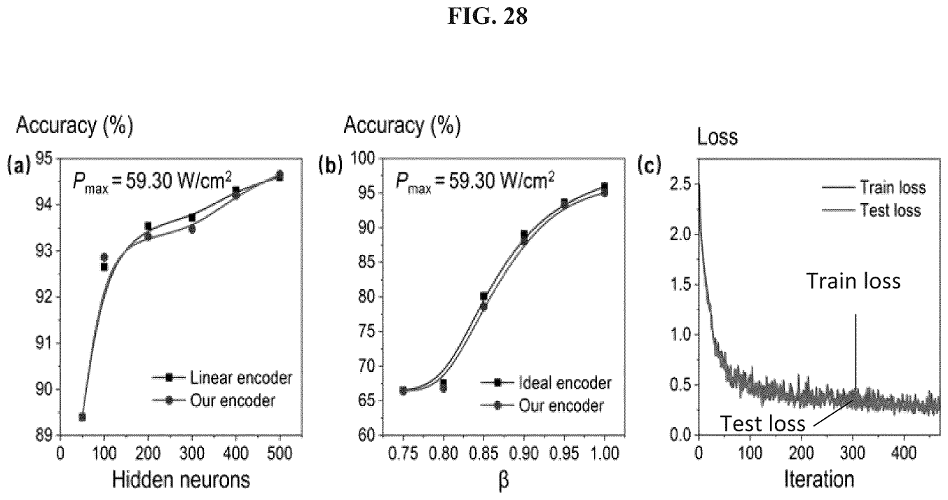

FIG. 27 shows a plot of accuracy (in percent or %) as a function of mid-infrared power density P_{MIR} (in Watts per square centimeters or W/cm²) illustrating the classification accuracy distribution at different number of sampling points for low encoding precision cases according to various embodiments. The I_{TC} is set to −6 nA. FIG. 28 shows (a) a plot of accuracy (in percent or %) as a function of hidden neurons illustrating dependence of accuracy on hidden neurons in an ideal linear encoder and the spiking neural network (labelled as “our encoder”) according to various embodiments for data set with maximum power density Pₘₐₓ of 59.30 W cm⁻²; (b) a plot of accuracy (in percent or %) as a function of membrane potential decay rate (β) illustrating dependence of accuracy on β in an ideal conventional linear encoder and the spiking neural network (labelled as “our encoder”) according to various embodiments for data set with maximum power density Pₘₐₓ of 59.30 W cm⁻²; and (c) a plot of loss as a function of iteration illustrating cross-entropy loss of the spiking neural network according to various embodiments versus iteration of the train and test sets.

It is motivating that the performance of the device as demonstrated above is already comparable to an ideal linear encoder. By optimizing the encoding parameters and sampling points of the device, it may be possible for various embodiments to ensure effective classification with the inference accuracy of up to 94% for MIR targets.

Inspired by the human vision system with the function of perceiving, transmitting and processing the external environment information, a compact MIR retinomorphic device using a 2D b-AsP/MoTe₂ van der Waals heterostructure has been demonstrated. The device may not only perceive the MIR illumination stimuli (~4.6 μm) with a fast response rate of 20 us and a high detectivity of 3.1×10¹⁰ cm Hz^{0.5}/W, but may also encode it into rate-based spike trains with the assistance of a stochastic NIR sampling terminal (~730 nm). Moreover, the device's encoding range and precision can be flexibly adjusted for different MIR illumination intensities. The device may encode the MIR MNIST data set into spike trains which enables the connected SNN to achieve digit classification with an accuracy higher than 94%. Various embodiments may provide a promising routine for constructing compact and efficient MIR neuromorphic devices for night machine vision, military, defense, and medical diagnosis. It may be anticipated that the optical approaches of realizing neuromorphic functions based on 2D van der Waals heterostructures have the potential of wide bandwidth up to tens of gigahertz when combined with integrated guided-wave nano photonics, bringing in the advantages of low data latency and high energy efficiency.

### Methods

### Device Fabrication and Characterization

As 2D b-AsP and MoTe₂ flakes are sensitive to the water and oxygen in the surrounding environment, dry transfer was applied to fabricate the 2D b-AsP/MoTe₂ van der Waals heterostructure. The contact electrodes (5/50/10 nm Cr/Au/Cr) were first patterned on a SiO₂/Si substrate by standard photolithography and electron beam evaporation. The exfoliated 2D b-AsP and MoTe₂ flakes from bulk crystals were then dry transferred onto the electrodes. Finally, h-BN encapsulation was used to protect the device from degradation. The morphology and quality of as-fabricated device was characterized by optical microscope (Nikon), atomic force microscope (Bruker Dimension Icon) and confocal micro-Raman spectroscopy (WITec alpha300).

### Detection And Encoding Measurements

The measurements of electrical and photoelectric properties were performed at room temperature and under ambient air conditions. A digital source meter (Keysight, B2912A) was used to apply voltage to the device and record the generated current. A MIR quantum cascade laser (QCL) (Daylight Solution, MIRCat) with tunable wavelength from 4 to 8 μm was employed to the external stimuli. The laser spot is about 100 μm. The power of MIR laser was recorded by a thermal power meter (OPHIR, Nova display-ROHS). A power adjustable 730 nm laser was applied as the stochastic terminal and its power density was measured using a power meter (Thorlabs, PM100D). For the encoding measurements, the device is simultaneously illuminated by 4.6 μm MIR laser with a fixed power density and pulsed 730 nm laser with Gaussian-distribution power density. The pulse duration of 730 nm laser is set to 0.5 ms and its amplitude is determined by the desired encoding algorithm. The fast current sampling was collected by means of an oscilloscope (Keysight, DSOX3054T).

### Photocurrent Mapping Method to Recognize P_{MIR} Distribution Image of FIG. ‘3’

To recognize the P_{MIR} distribution image of figure ‘3’ targets in mask, the responding photocurrent of the device to every pixel of mask is collected by oscilloscope. The mask has 300× 300 pixels in which each ‘3’ target occupies 100×10⁰ pixels. The P_{MIR} of 4.6 μm laser from QCL on every ‘3’ region (100×100 pixels) is different. When the mask is scanned by pixels, the responding photocurrent of each pixel depends on the optical flux of 4.6 μm laser passing through this pixel region. According to the mapping relation of photocurrent and P_{MIR} given in FIG. 9(e), the corresponding P_{MIR} for every pixel can be estimated from the photocurrent obtained by experiment, and finally constitutes the P_{MIR} distribution image shown in FIG. 24B.

### Preparation of MIR MNIST Data Set

The MIR MNIST data set is obtained by mapping pixel values of traditional MNIST data set ranging in [0, 255] to optical power density of 4.6 μm laser ranging in [0, Pₘₐₓ]. Once the Pₘₐₓ is set, every image in the prepared MIR MINST data set with a size of 28×28 pixels is first flattened to obtain 784 analog optical power density of MIR laser. The MIR laser with a certain optical power density can be detected and encoded by the retinomorphic optoelectronic device into spike trains as the input of SNN.

### Training and Parameter Optimization of SNN

For training of SNN, a surrogate gradient descent algorithm is used to update synaptic weights in order to avoid dead neuron problem. The loss function and optimizer used here are cross-entropy loss and Adam optimizer. There are 60000 and 10000 MIR MNIST images used for training and test, respectively. The number of hidden neurons and membrane potential decay rate are two super-parameters affecting classification ability of SNN. More hidden neurons and higher β can enhance the classification accuracy (seen in FIG. 28(a)-(b)). The β of real synaptic devices hardly reaches 100%, and therefore the β in this work may be set to 0.95. The number of hidden neurons is set to 200 considering the trade-off between performance and complexity. After training around 450 iterations in one epoch with the batch size of 128, the loss of train and test sets all converge to a steady level, verifying SNN is well trained without under-fitting and over-fitting problems (seen in FIG. 28(c)).

Supplementary Note 1: Electrical Characterizations of the b-AsP/MoTe₂ Heterostructure

The thickness of as-used 2D b-AsP flake and 2D MoTe₂ flake is ~26 nm and ~12 nm, respectively, as shown in FIGS. 5(a)-(c) and FIGS. 6(a)-(c). FIG. 5(d) and FIG. 6(d) display the electric transport properties of individual b-AsP and MoTe₂, respectively, where the nearly linear output characteristic curves suggest that good contacts are formed between the b-AsP (MoTe₂) and electrodes. According to the transfer characteristic curves (FIG. 5(e) and FIG. 6(e)), both b-AsP and MoTe₂ exhibit p-type conduction behaviour, where the b-AsP shows a very weak gate modulation. The field-effect mobility (u) could be calculated using the relation:

$$μ = \frac{{dI}_{DS}}{{dV}_{GS}} \frac{L}{{WV}_{DS} {C}_{ox}}$$

where Z and W are the length and width of the channel, respectively, I_{DS}, V_{DS} and V_{GS} refer to the source-drain current, bias voltage and gate voltage, respectively, and Cₒₓ is the dielectric oxide capacitance (13.4 nF cm⁻² for used SiO₂). The as-calculated mobility of the b-AsP and MoTe₂ are reach up to ~117 and ~10 cm² V⁻¹ s⁻¹, which is consistent with previous reports. The good contacts and high carrier mobility enable the b-AsP/MoTe₂ heterostructure to have excellent photoresponse performance. The optical image of an as-fabricated b-AsP/MoTe₂ heterostructure is shown in FIG. 8(a). The entire device is finally encapsulated by insulating h-BN flake to prevent it from being corroded by water and oxygen in the air. Raman measurements on the b-AsP and MoTe₂ were taken, as presented in FIG. 8(b). The Raman spectrum of MoTe₂ shows three peaks at 145, 170, and 230 cm⁻¹, which is corresponding to the E_{1g}, A_{1g} and E_{2g}¹ mode of 2H-MoTe₂. In the b-AsP side, high-frequency region contains three obvious peaks at 360, 435 and 462 cm⁻¹, which can be assigned to the A_{g}¹, B_{2g}² and A_{g}² mode of black phosphorus (b-P), respectively, whereas low-frequency region (200-260 cm⁻¹) contains three peaks from the A_{g}¹, B_{g}² and A_{g}² mode of black arsenic (b-As). These distinct Raman peaks indicate the high crystal quality of as-exfoliated 2D b-AsP and MoTe₂ flakes. The I_{DS}−V_{DS} curve (FIG. 8(c)) of the b-AsP/MoTe₂ heterostructure shows diode-like rectification characteristics, indicating the existence of built-in electric field in the overlap region. FIGS. 8(d)-(e) depict the band alignments of the b-AsP/MoTe₂ heterostructure before and after contact, in which the energy level positions are obtained from the references. Based on the band alignments, the diode-like rectification characteristics can be easily understood. In equilibrium state (V_{DS}=0 V), the minority electrons in b-AsP would move into MoTe₂, thereby causing a wider depletion layer at MoTe₂ side and creating more holes at b-AsP side. In other words, a built-in electric field with direction pointing to MoTe₂ side is formed at the interface of the b-AsP/MoTe₂ heterostructure. At positive bias (V_{DS}>0 V), the majority holes in MoTe₂ and minority electrons in b-AsP easily cross over the interface barrier, forming a large current. At negative bias (V_{DS}<0 V), the electrons can hardly be injected into MoTe₂ due to the high Schottky barrier for electrons, while the holes in b-AsP could cross the interface barrier due to the small valance band offset (~0.2 eV). Even so, the current at negative bias is lower than that at positive bias.
Supplementary Note 2: Photoresponse Characteristics of the b-AsP/MoTe₂ Heterostructure

Under the MIR (4.6 μm laser) illumination with various power densities ranging from 0.56 to 80.21 W cm⁻², the I_{DS}−V_{DS} curves (FIGS. 9(a)-(b)) of the b-AsP/MoTe₂ heterostructure gradually shift upward with the increase of power density, and the photocurrent at different power densities shows an independence on bias voltage (FIG. 9(c)). Such MIR photoresponse behavior can be attributed to the photothermoelectric (PTE) mechanism. In the heterostructure, the MIR absorption of MoTe₂ can be ignored due to its large bandgap of ~1.0 eV. Therefore, the PTE-generated photocurrent is mainly contributed from b-AsP. In addition, the thermal conductivity of b-AsP (~110.26 μW m⁻¹ K⁻¹) and MoTe₂ (~40 W m⁻¹ K⁻¹) is less than that of Cr/Au electrode (~200 W m⁻¹ K⁻¹), and the Seebeck coefficient of b-AsP (~803 pV K⁻¹) is higher than that of MoTe₂ (~230 μV K⁻¹). As a result, a temperature gradient would form in the b-AsP and thus cause the diffusion of hot holes from the MoTe₂ contact side to Cr/Au electrode contact side, thereby generating a positive PTE photocurrent under zero bias with b-AsP as the ground terminal, as schematically shown in FIG. 9(f). FIG. 9(d) shows the time-resolved photoresponse under illumination with different power densities, suggesting fast response switching and power-dependent PTE photocurrent increase. The mapping between PTE photocurrent and power density can be well fitted by a relationship of Iₚₕ=4.72×P^{0.66}, which is an important link for encoding the MIR illumination intensity.

Under 730 nm laser illumination, the I_{DS} of the b-AsP/MoTe₂ heterostructure increases significantly at both positive and negative bias with increasing power density from 28.01 to 226.64 mW cm⁻², as shown in FIG. 10(a), and the magnified view of the I_{DS}−V_{DS} curves in FIG. 10(b) shows obvious short-circuit current (I_{SC}) and open-circuit voltage (V_{OC}). Such photoresponse behaviour indicates a distinct photovoltaic (PV) response in the b-AsP/MoTe₂ heterostructure. As presented in FIG. 10(c), the I_{SC} and V_{OC} increase with increasing the power density, and the I_{SC} shows a near linear dependence on the power density (I_{SC} □P^{0.99}). The maximum output electrical power (Pet=I_{SC}×V_{OC}) is calculated to be 1.2 nW under the power density of 226.64 mW cm⁻² (FIG. 10(d)). The fill factor (FF) and power conversion efficiency (PCE) are calculated following the relations:

$$FF = \frac{{P}_{el , m ax}}{{I}_{sc} \times {V}_{oc}} \\ PCE = \frac{{P}_{el , ma x}}{{P}_{i n}}$$

where P_{el,max} is the maximum output electrical power and Pᵢₙ refer to the incident power. As shown in FIG. 10(e), a FF of 0.3 and a PCE of 1% are obtained in the heterostructure, which are competitive with reported PV devices based on 2D van der Waals heterostructures. The PV mechanism of the b-AsP/MoTe₂ heterostructure is shown in FIG. 10(f). Under 730 nm laser illumination, a large number of electron-hole pairs are generated in MoTe₂, which are separated by the built-in electrical field with direction pointing to MoTe₂ side at the interface. As a result, the photo-generated electrons and holes can move into b-AsP and MoTe₂, respectively, thus forming a negative I_{SC} and positive V_{OC}.
Supplementary Note 3: Photodetection Performance of the b-AsP/MoTe₂ Heterostructure

Photoresponse rate is a key figure of merit of photodetectors. FIGS. 12-13 present the photoswitching behaviour and response rate of the b-AsP/MoTe₂ heterostructure under 4.6 μm and 730 nm illumination at V_{DS}=0 V, respectively. There is no obvious declination of the photoresponse amplitude as the pulse frequency increases from 100 to 3000 Hz, indicating the potential of high-speed operation. The photoresponse rate with a rise time (τᵣ) of ~20 μs and a decay time (τ_{d}) of ~20 μs are achieved for both 4.6 μm and 730 nm, which is faster than most PTE and PV photodetectors. In addition, two other important figure of merits, namely responsivity (R) and detectivity (D*), are also calculated by the following equations:

$$R = \frac{{I}_{p h}}{P \times A} \\ {D}^{*} = \frac{{( AB )}^{0.5}}{NEP}$$

where Iₚₕ, P, A, B and NEP refer to photocurrent, incident power density, the effective device area, measuring bandwidth and noise equivalent power, respectively. The NEP can be obtained following NEP=iₙ/R, where iₙ is noise current. The noise spectral density of the heterostructure is displayed in FIG. 14, which is measured at V_{DS}=0 V. It is observed that the noise is dominated by flicker (1/f) noise, which is attributed to the trapping and detrapping of local charge carriers. In this work, the sampling frequency of MIR and NIR illumination is 2 kHz, so the noise of the b-AsP/MoTe₂ heterostructure should be 1/f noise. Based on this, the NEP, R and D* of the heterostructure under 4.6 μm and 730 nm illumination with various power densities are accordingly calculated, which are shown in FIGS. 15-16, respectively. Note that the frequency of the noise current is chosen to be 2000 Hz and these figure of merits are obtained at V_{DS}=0 V. For 4.6 μm, a low NEP of 1.0 pW Hz^{-0.5} and a high R of 23.3 mA W⁻¹ with a high D* of 3.1×10¹⁰ cm Hz^{0.5} W⁻¹ are achieved under the power density of 0.56 W cm⁻². In terms of 730 nm, the values of NEP, R and D* are about 0.033 pW Hz^{-0.5}, 0.72 A W⁻¹ and 9.6×10¹¹ cm Hz^{0.5} W⁻¹, respectively. These figure of merits are competitive in both MIR and NIR photodetectors based on 2D van der Waals heterostructures. Furthermore, the b-AsP/MoTe₂ heterostructure demonstrates excellent broadband MIR photodetection capability at V_{DS}=0 V, as shown in FIG. 17. The responsivity and detectivity of the heterostructure monotonously decrease from 2.34 to 0.31 mA W⁻¹ and 3.2×10⁹ to 4.1×10⁸ cm Hz^{0.5} W⁻¹ as the wavelength increases from 4.5 to 7.7 μm, respectively, which is attributed the decreasing MIR absorption of b-AsP.

### Supplementary Note 4; Analytical Results of the Device and Spiking Neural Network

A current response model of the device to P_{MIR} and P_{NIR} can be fitted by measured data. By this model, simulation results of spike rate as a function of P_{MIR} is given in FIG. 23A. It's observed that a higher σ can extend to cover P_{MIR} range from 0 to 56 W cm⁻². The location of dynamic working range moves with u and I_{TC}. It's noted that too high power of 730 nm light (P_{NIR}) will bring exceed heat accumulated inside device which also illuminated by MIR light. The heat effect results in the instability of device and the current response becomes nonlinear and uncontrollable. To avoid this situation, we clip the P_{NIR} range of sampling train of 730 nm light between 0 and 255 mW cm⁻², despite how σ and u increase or decrease. This clipping operation limits the maximum encoding power density of MIR light (Pₘₐₓ) to 56 W cm⁻² shown in FIG. 23B left diagram. If I_{TC} is below 0 nA, similarly, the minimum encoding power density (Pₘᵢₙ) is limited to 2.5 W cm⁻² presented in FIG. 23B middle diagram. Pₘᵢₙ returns to 0 when I_{TC} is higher than 0 nA, because the spike rate for no MIR light illumination has already been a certain value. For example, the spike rate for 0-P_{MIR} in FIG. 23B right diagram is around 0.5 kHz.

When u=63.66 mW cm⁻² and σ=38.20 mW cm⁻², the spike rate range starts from 0.25 kHz to 2 kHz instead of beginning from 0 kHz, therefore, the encoding precision of encoder decreases. In this case, more sampling points can improve the quantitative accuracy of spike rate, i.e., there are more rate levels between 0 to 2 kHz. Therefore, the classification accuracy of SNN is improved accordingly as shown in FIG. 27.

As shown in FIG. 28(a), more hidden neurons improve the classification ability of SNN traded from the structure complexity. Membrane potential decay rate (β) means the ability of the synaptic neuron memorizing the former information. When β reaches 100%, the accuracy exceeds 95% thanks to ideal memory of neurons, but a real synaptic device hardly has β of 100% without any memorized voltage decay, so the β in this work is set to 95%. The u, σ, I_{TC} and sampling points for two figures are 127.32 mW cm⁻², 38.20 mW cm⁻², −6 nA and 50. FIG. 28(c) verifies that training parameters and iteration numbers of SNN is sufficient for loss convergence without underfitting problem. Additionally, the loss convergence of test set proves the SNN has no over-fitting problem.

### Example 2

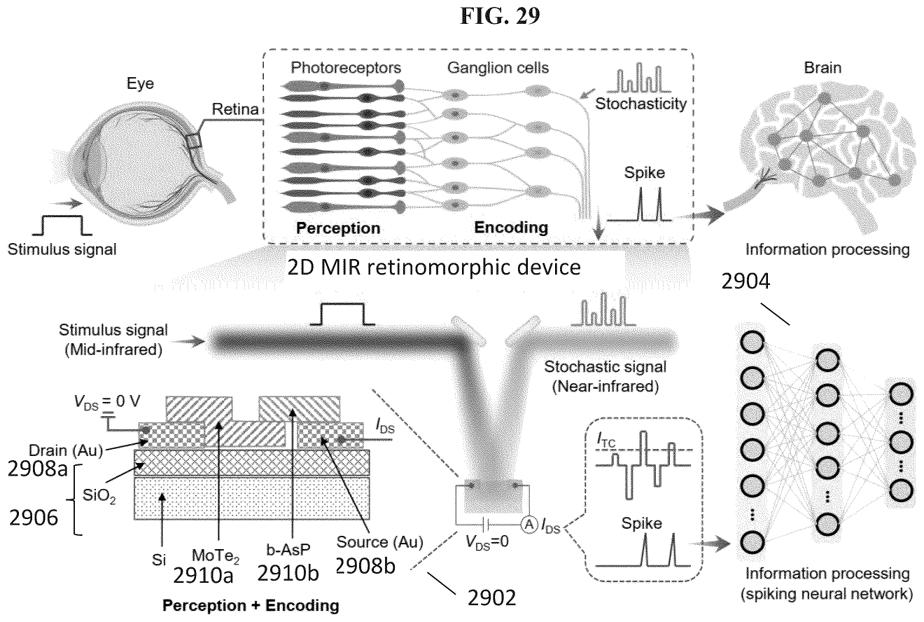

FIG. 29 shows another optoelectronic system that can mimic the key functionalities according to various embodiments. The optoelectronic system may include an optoelectronic device 2902. The optoelectronic device 2902 may include a substrate 2906 (e.g. a silicon oxide (SiO₂)/silicon (Si) substrate) as well as a drain electrode 2908a and a source electrode 2908b over the substrate 2906. The optoelectronic device 2902 may also include a MoTe₂ layer 2910a in contact with the drain electrode 3008a and a b-AsP layer 2910b in contact with the source electrode 2908b. The optoelectronic system may additionally include a neural network 2904 (i.e. trained SNN) coupled to the optoelectronic device 2902.

As shown in FIG. 29, a portion of the b-AsP layer 2910b may be over a portion of the MoTe₂ layer 2910a, while for the device shown in FIG. 4, a portion of the MoTe₂ layer 410a may be over a portion of the b-AsP layer 410b.

The optoelectronic system shown in FIG. 29 is designed such that it can perceive external light in the MIR spectral range (at ~4.6 μm) while simultaneously encode the received MIR information into spike train by harnessing a stochastic NIR sampling terminal (at ~730 nm excitation). The system shown in FIG. 29 has a high MIR detectivity (9.6×10⁸ cm Hz^{0.5}/W) and fast NIR photoresponse rate (~600 ns). The trained SNN 2904 achieves an inference accuracy of more than 96% to the MIR MNIST data set which is encoded into spikes by the device 2902.

Similar to the device 402, in the device 2902, the b-AsP layer 3010b is used as the MIR photosensitive layer owing to its narrow bandgap of ~0.15 eV and high MIR optical absorption efficiency of ~10%. The MoTe₂ layer 2910a with an appropriate bandgap of ~1.0 eV may serve as the NIR sensitizer. Both b-AsP and MoTe₂ exhibit high hole mobility of ~145 and ~15 cm²/Vs, respectively, allowing for fast photoresponse of the b-AsP/MoTe₂ devices.

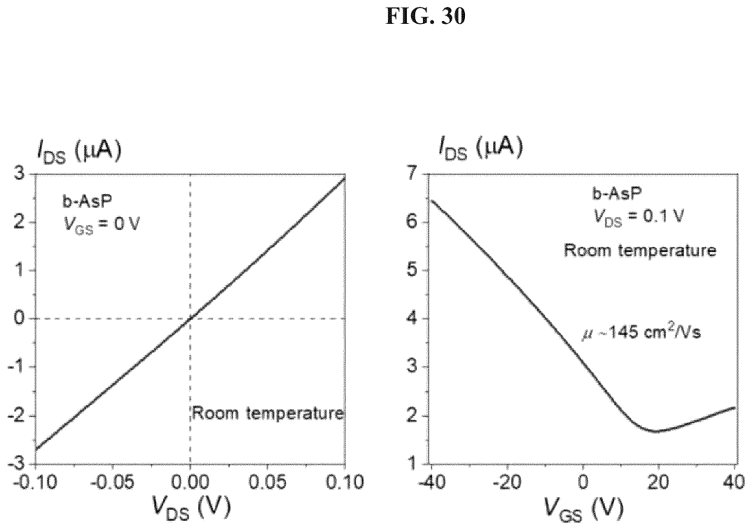

FIG. 30 shows (a) a plot of the transduction current I_{DS} (in micro-Amperes or μA) as a function of source-drain voltage V_{DS} (in volts or V) illustrating the output characteristic curve of a two-dimensional (2D) black phosphorus-arsenic (b-AsP)-based transistor according to various embodiments (linear I_{DS}−V_{DS} indicates that Ohmic contact was formed between the 2D b-AsP flake and gold (Au) electrodes); and (b) a plot of the transduction current I_{DS} (in micro-Amperes or μA) as a function of gate voltage V_{GS} (in volts or V) illustrating the transfer characteristic curve of the 2D b-AsP-based transistor at V_{DS}=0.1 V according to various embodiments. It can be observed that the b-AsP exhibits heavily-doped p-type conduction behavior with a high hole mobility of 145 cm²/Vs at room temperature.

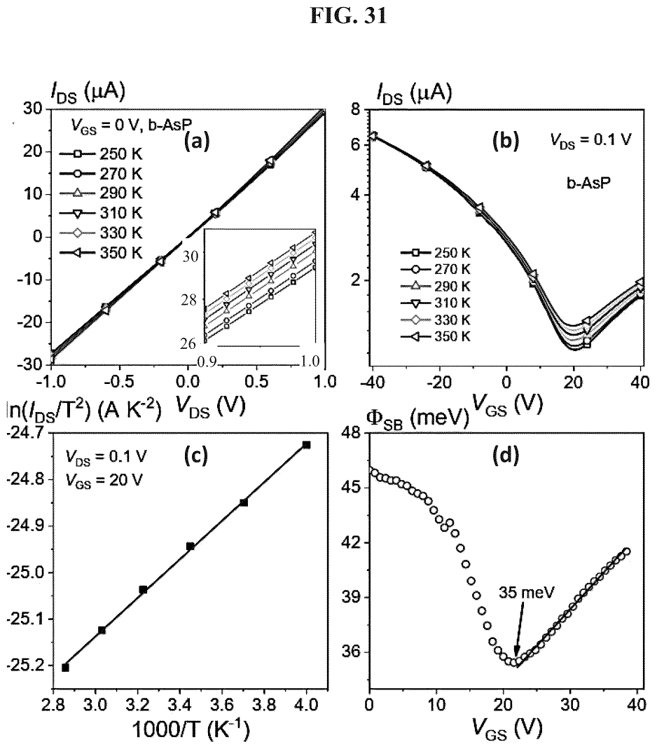

FIG. 31 shows the temperature dependent characteristics of the black phosphorus-arsenic (b-AsP)-based transistor according to various embodiments: (a) a plot of transduction current I_{DS} (in micro-Amperes or μA) as a function of source-drain voltage V_{DS} (in volts or V) illustrating I_{DS}−V_{DS} curves of the transistor according to various embodiments at different temperatures; (b) a plot of the transduction current I_{DS} (in micro-Amperes or μA) as a function of gate voltage V_{GS} (in volts or V) illustrating I_{DS}−V_{GS} curves of the transistor according to various embodiments at different temperatures; (c) an Arrhenius plot of the black phosphorus-arsenic (b-AsP)/gold (Au) contact according to various embodiments; and (d) a plot of the Schottky barrier height Φ_{SB} (in milli-electron-volts or meV) as a function of gate voltage V_{GS} (in volts or V) illustrating the variation of extracted barrier height of the black phosphorus-arsenic (b-AsP)/gold (Au) contact according to various embodiments. Φ_{SB} is about 35 meV at flat-band conditions.

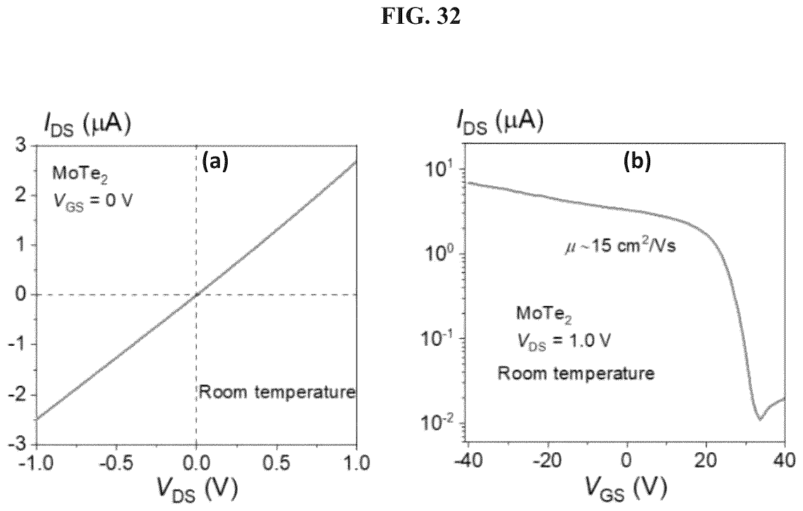

FIG. 32 shows (a) a plot of the transduction current I_{DS} (in micro-Amperes or μA) as a function of source-drain voltage V_{DS} (in volts or V) illustrating the output characteristic curve of a two-dimensional (2D) molybdenum (IV) telluride (MoTe₂)-based transistor according to various embodiments (near linear I_{DS}−V_{DS} indicates that negligible Schottky barriers at the interface between 2D MoTe₂ flake and gold (Au) electrodes); and (b) a plot of the transduction current I_{DS} (in micro-Amperes or μA) as a function of gate voltage V_{DS} (in volts or V) illustrating the transfer characteristic curve of the transistor according to various embodiments which features a p-type behavior with a mobility of ~15 cm² V⁻¹ s⁻¹ at room temperature.

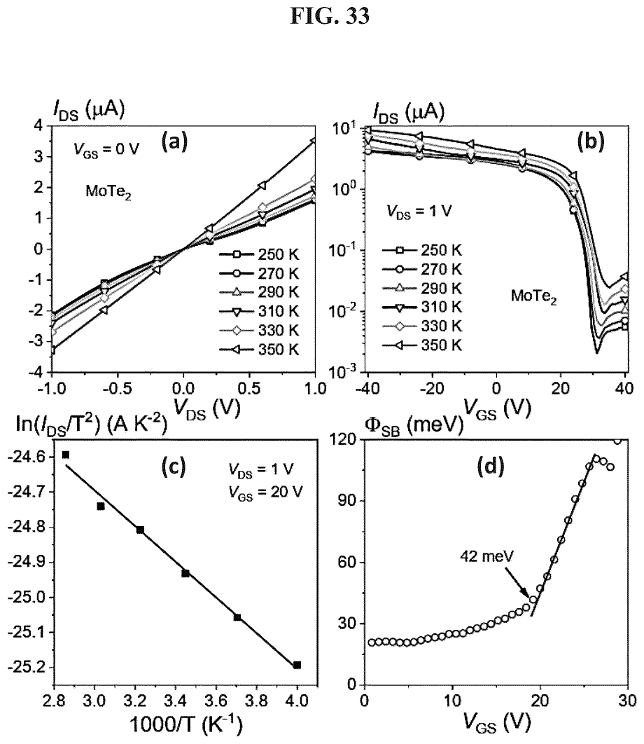

FIG. 33 shows the temperature dependent characteristics of the molybdenum (IV) telluride (MoTe₂)-based transistor according to various embodiments: (a) a plot of transduction current I_{DS} (in micro-Amperes or μA) as a function of source-drain voltage V_{DS} (in volts or V) illustrating I_{DS}−V_{DS} curves of the transistor according to various embodiments at different temperatures; (b) a plot of the transduction current I_{DS} (in micro-Amperes or μA) as a function of gate voltage V_{GS} (in volts or V) illustrating I_{DS}−V_{GS} curves of the transistor according to various embodiments at different temperatures; (c) an Arrhenius plot of the molybdenum (IV) telluride (MoTe₂)/gold (Au) contact according to various embodiments; and (d) a plot of the Schottky barrier height Φ_{SB} (in milli-electron-volts or meV) as a function of gate voltage V_{GS} (in volts or V) illustrating the variation of extracted barrier height of the molybdenum (IV) telluride (MoTe₂)/gold (Au) contact according to various embodiments with V_{GS}. Φ_{SB} is about 42 meV at flat-band conditions.

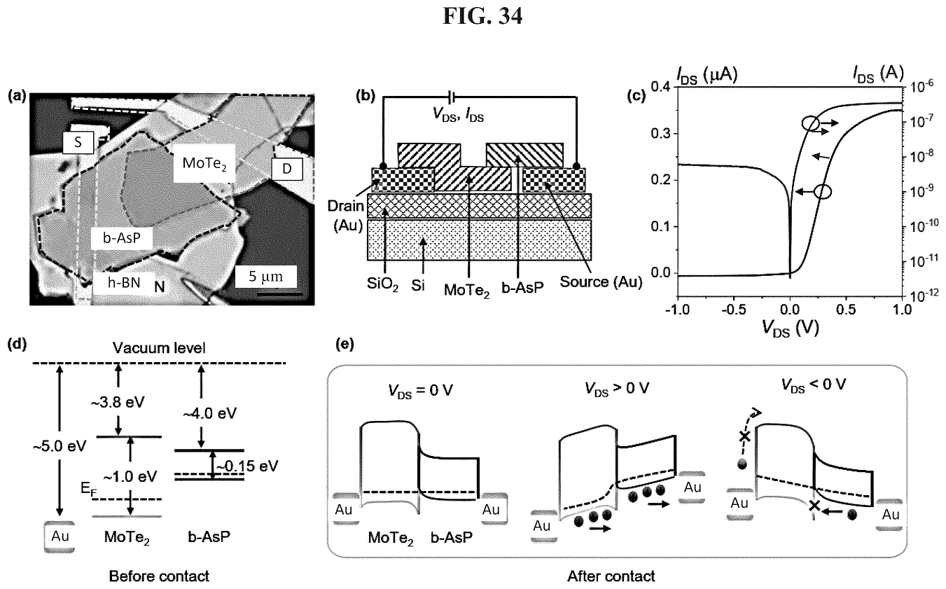

FIG. 34 shows the rectification characterizations and band alignments of the black phosphorus-arsenic/molybdenum (IV) telluride (b-AsP/MoTe₂) optoelectronic device (optoelectronic device 1) according to various embodiments: (a) a microscopic image of the heterostructure encapsulated by a hexagonal-boron nitride (h-BN) flake according to various embodiments; (b) a schematic of the black phosphorus-arsenic/molybdenum (IV) telluride (b-AsP/MoTe₂) optoelectronic device according to various embodiments; (c) a plot of transduction current I_{DS} (in micro-Amperes or μA/nano-Amperes or nA) as a function of source-drain voltage V_{DS} (in volts or V) illustrating the output characteristic curve of the b-AsP/MoTe₂ heterostructure according to various embodiments; (d) the band profiles of gold (Au), MoTe₂ and b-AsP before contact (the curve shows a rectification characteristic); and (e) band alignment of the b-AsP/MoTe₂ heterostructure according to various embodiments at different biasing voltages according to various embodiments.

5 optoelectronic devices (optoelectronic devices 1-5) are fabricated. The 5 optoelectronic devices have different thicknesses and areas of the b-AsP and MoTe₂ layers as further described below. The characteristics as well as experimental results of the 5 optoelectronic devices are discussed below.

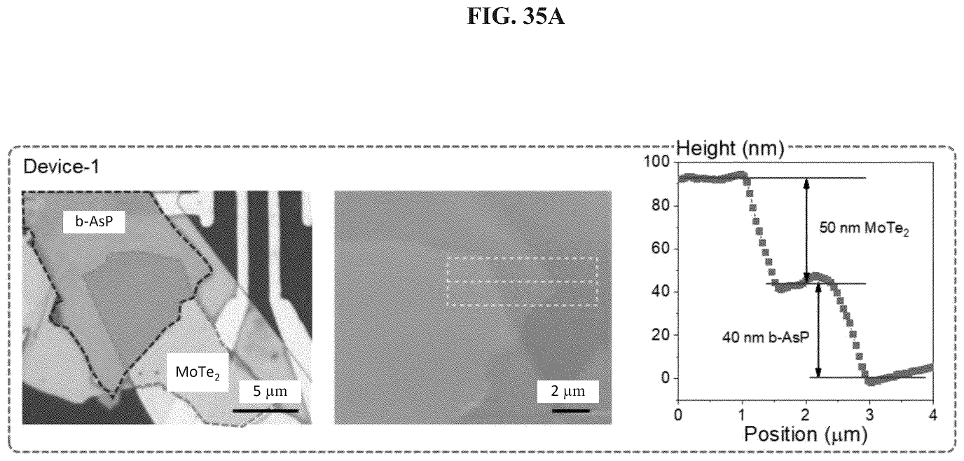

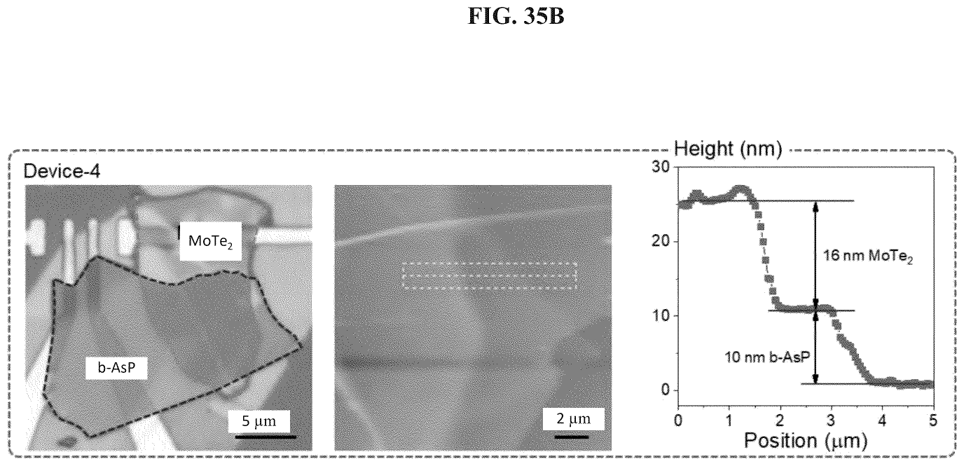

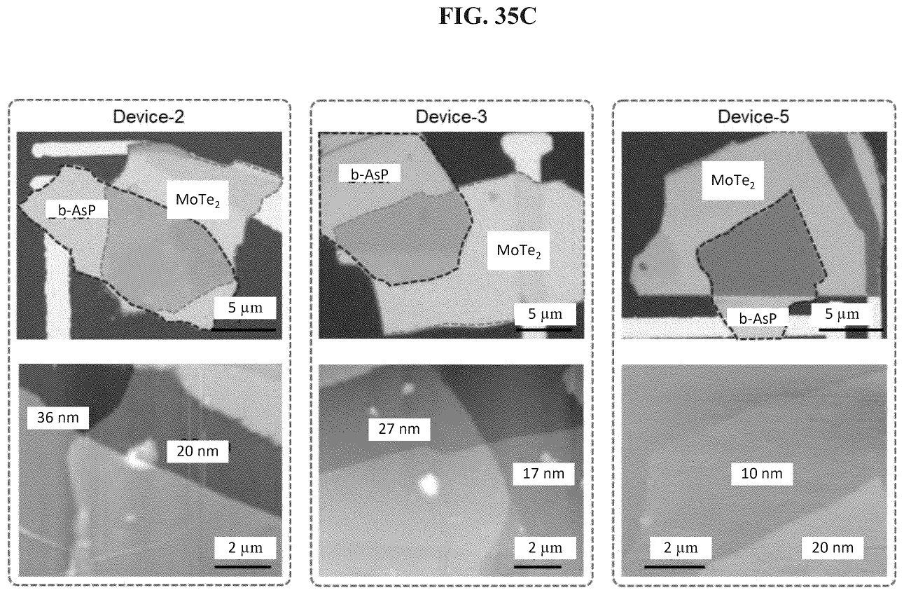

FIG. 35A shows (left) a microscopic image of optoelectronic device 1 according to various embodiments; (middle) a magnified portion including a junction between the black phosphorus-arsenic layer and the molybdenum (IV) telluride (b-AsP/MoTe₂) layer according to various embodiments; and (right) a plot of height (in nanometers or nm) as a function of position (in micrometers or μm) illustrating the height profile of the region indicated by the dashed line in the middle image according to various embodiments. FIG. 35B shows (left) a microscopic image of optoelectronic device 4 according to various embodiments; (middle) a magnified portion including a junction between the black phosphorus-arsenic layer and the molybdenum (IV) telluride (b-AsP/MoTe₂) layer according to various embodiments; and (right) a plot of height (in nanometers or nm) as a function of position (in micrometers or μm) illustrating the height profile of the region indicated by the dashed line in the middle image according to various embodiments. FIG. 35C shows microscopic images of optoelectronic devices 2, 3 and 5 according to various embodiments. All the devices are encapsulated by h-BN flakes for perception and encoding testing.

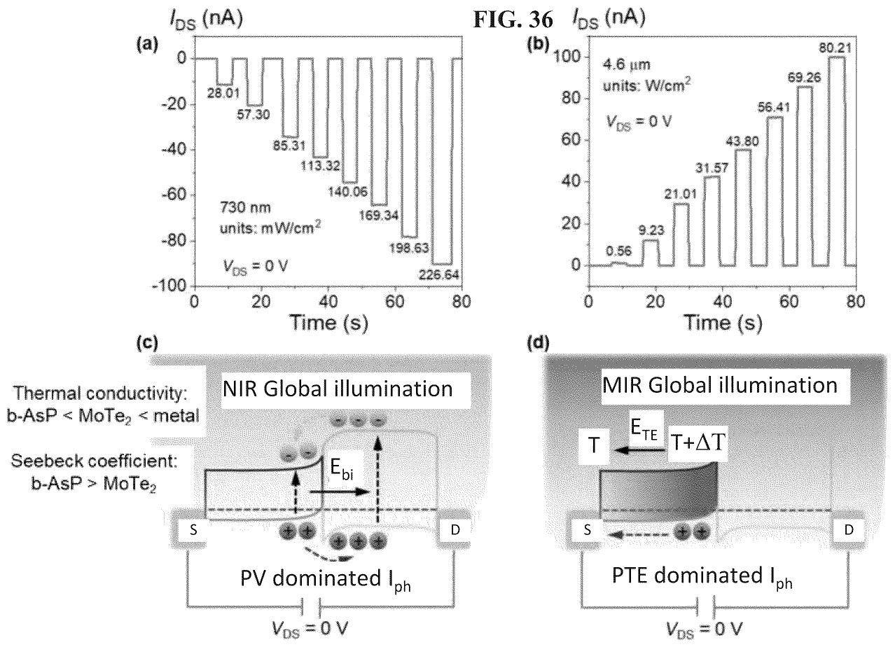

FIG. 36 shows the photoresponse characteristics of the optoelectronic device (optoelectronic device 1) according to various embodiments at drain-source voltage (V_{DS})=0V: (a) a plot of transduction current I_{DS} (in nano-Amperes or nA) as a function of time (in seconds or s) illustrating the near-infrared NIR (730 nm) photoresponse with negative photocurrent at different power densities according to various embodiments; (b) a plot of transduction current I_{DS} (in nano-Amperes or nA) as a function of time (in seconds or s) illustrating the mid-infrared MIR (4.6 μm) photoresponse with positive photocurrent at different power densities according to various embodiments; (c) a schematic illustrating the photoresponse mechanism of the device under NIR global illumination according to various embodiments; and (d) a schematic illustrating the photoresponse mechanism of the device under MIR global illumination according to various embodiments.

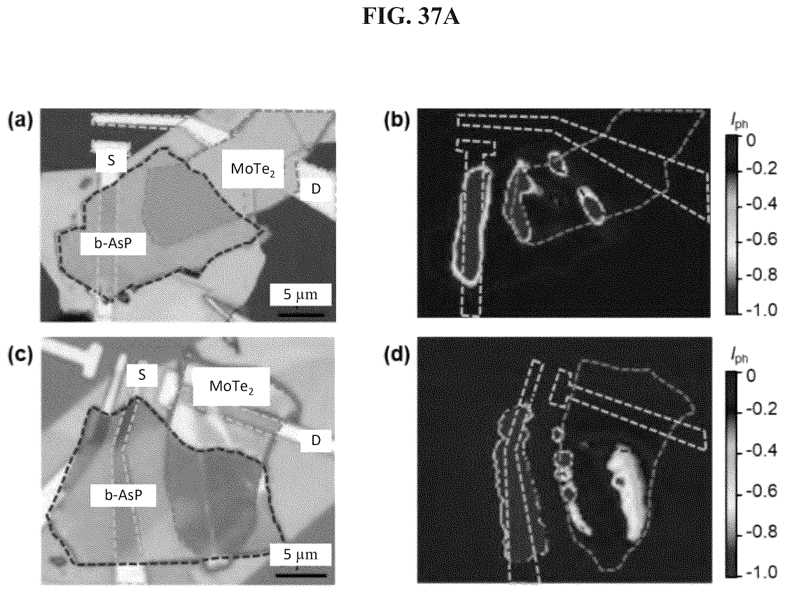

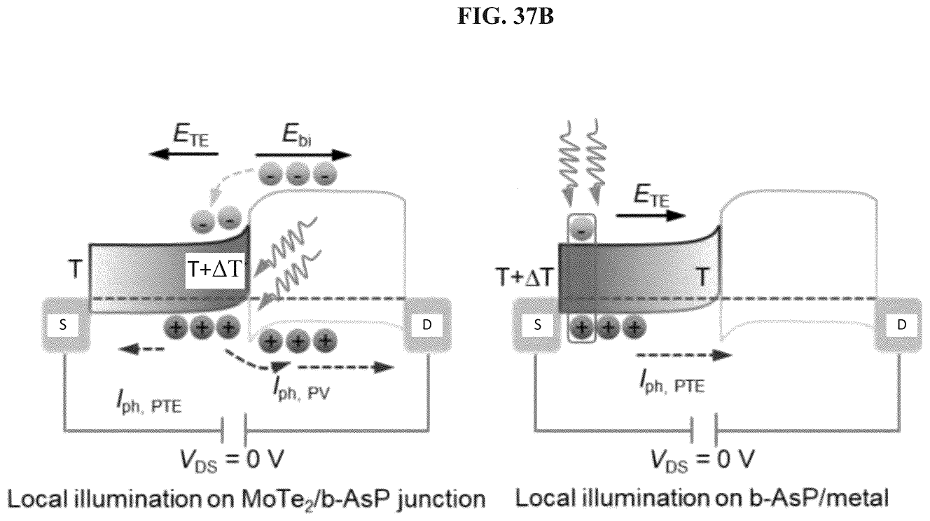

FIG. 37A shows (a) a microscopic image of optoelectronic device 1 according to various embodiments: (b) a corresponding photocurrent mapping of optoelectronic device 1 according to various embodiments; (c) a microscopic image of optoelectronic device 4 according to various embodiments; and (d) a corresponding photocurrent mapping of optoelectronic device 4 according to various embodiments. The photocurrent was normalized. Note that the near-zero photocurrent in the b-AsP/MoTe₂ junction region may be due to the cancellation of the positive and negative photocurrent caused by PTE and PV respectively in the junction. The mapping images were obtained by using a focused 532 nm laser with spot of ~1 μm. FIG. 37B shows (left) a schematic for band alignment and photo-induced carriers flow direction of the black phosphorus-arsenic/molybdenum (IV) telluride (b-AsP/MoTe₂) optoelectronic device when laser is locally illuminated on the b-AsP/MoTe₂ junction according to various embodiments; and (right) a schematic for band alignment and photo-induced carriers flow direction of the black phosphorus-arsenic/molybdenum (IV) telluride (b-AsP/MoTe₂) optoelectronic device when laser is locally illuminated on the b-AsP/metal junction according to various embodiments.

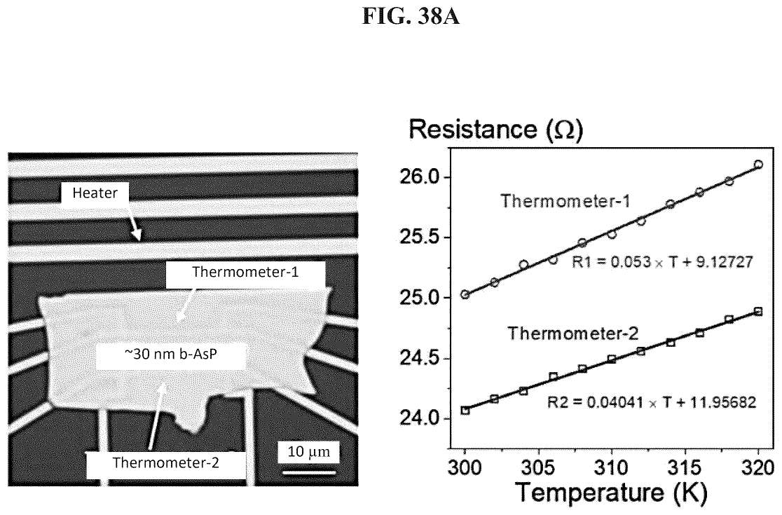

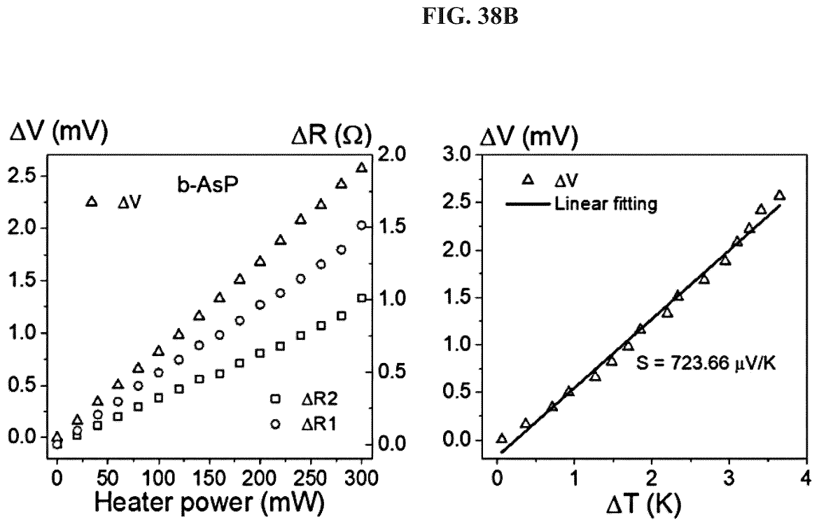

FIGS. 38A-B relate to the Seebeck coefficient measurement of black phosphorus-arsenic (b-AsP). FIG. 38A shows (left) the black phosphorus-arsenic (b-AsP) device structure for thermoelectric measurement according to various embodiments; and (right) a plot of resistance (in Ohms or (2) as a function of temperature (in Kelvins or K) illustrating the temperature-dependent resistance of thermometer-1 and thermometer-2 according to various embodiments. FIG. 38B shows (left) a plot of voltage drop ΔV (in milli-Volts or mV) as a function of heater power (in milli-Watts or mW) illustrating ΔV across black phosphorus-arsenic (b-AsP) and the resistance change (ΔR) of the two thermometers at different heater powers according to various embodiments; and (right) a plot of voltage drop ΔV (in milli-Volts or mV) as a function of temperature difference ΔT (in Kelvins or K) between the two thermometers according to various embodiments. The Seebeck coefficient(S) of b-AsP was extracted and calculated to be S=ΔV/ΔT=723.66 μV/K.

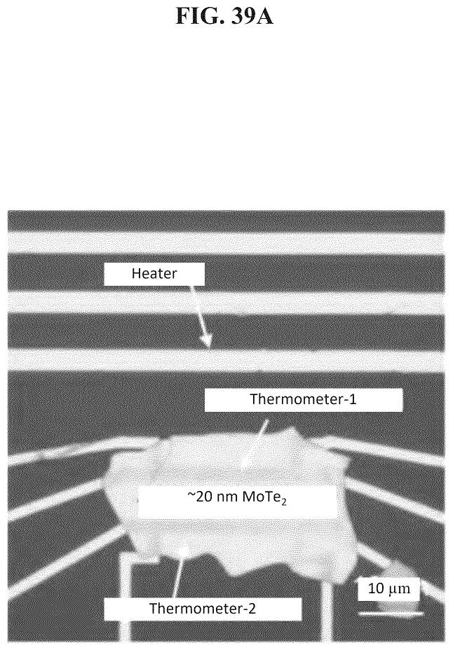

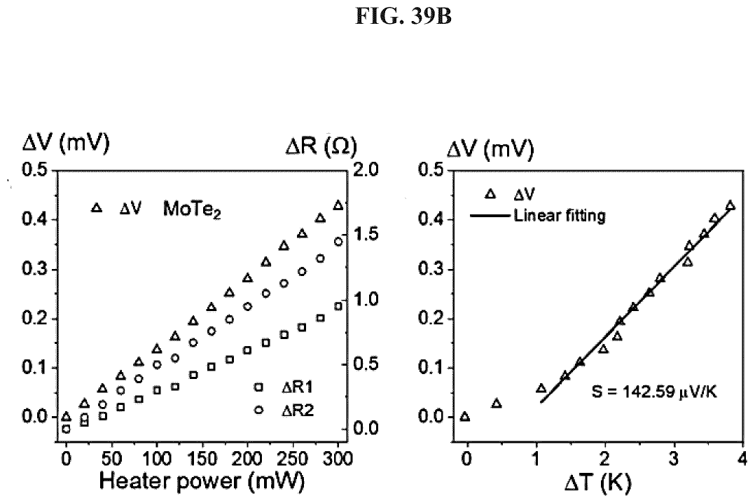

FIGS. 39A-B relate to the Seebeck coefficient measurement of molybdenum (IV) telluride (MoTe₂). FIG. 39A shows the molybdenum (IV) telluride (MoTe₂) device structure for thermoelectric measurement according to various embodiments. FIG. 39B shows (left) a plot of voltage drop ΔV (in milli-Volts or mV) as a function of heater power (in milli-Watts or mW) illustrating ΔV across molybdenum (IV) telluride (MoTe₂) and the resistance change (ΔR) of the two thermometers at different heater powers according to various embodiments; and (right) a plot of voltage drop ΔV (in milli-Volts or mV) as a function of temperature difference ΔT (in Kelvins or K) between the two thermometers according to various embodiments. The Seebeck coefficient(S) of MoTe₂ was extracted and calculated to be S=ΔV/ΔT=142.59 μV/K.

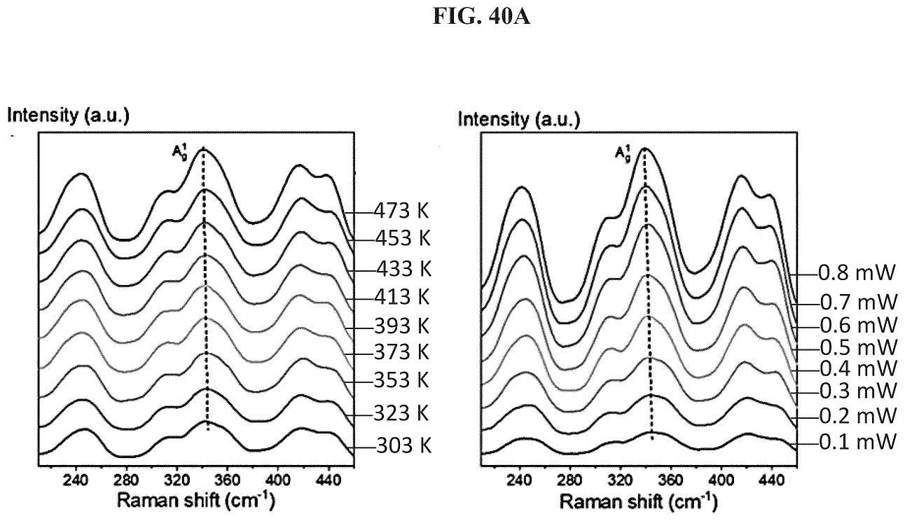

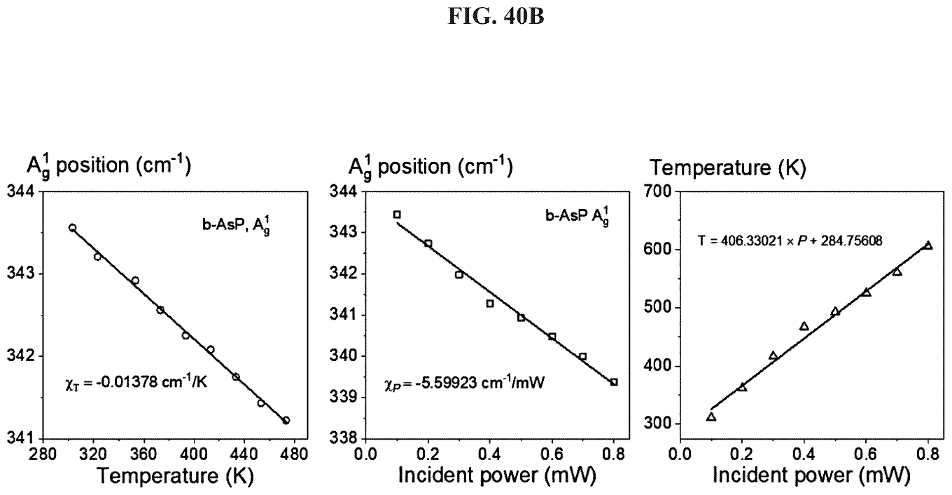

FIGS. 40A-B relate to temperature- and power-dependent Raman spectra of black phosphorus-arsenic (b-AsP). FIG. 40A shows (left) a plot of intensity (in arbitrary units or a.u.) as a function of Raman shift (per centimeter or cm⁻¹) illustrating the Raman spectra of black phosphorus-arsenic (b-AsP) according to various embodiments at different temperatures; and (right) a plot of intensity (in arbitrary units or a.u.) as a function of Raman shift (per centimeter or cm⁻¹) illustrating the Raman spectra of black phosphorus-arsenic (b-AsP) according to various embodiments at different power densities. FIG. 40B shows (left) a plot of A_{g}¹ position (per centimeter or cm⁻¹) as a function of temperature (in Kelvins or K) illustrating variation of the A_{g}¹ peak position with temperature according to various embodiments; (middle) a plot of A_{g}¹ position (per centimeter or cm⁻¹) as a function of incident power (in milli-Watts or mW) illustrating variation of the A_{g}¹ peak position with incident power according to various embodiments; and (right) a plot of temperature (in Kelvins or K) as a function of incident power (in milli-Watts or mW) illustrating the estimated local temperature in black phosphorus-arsenic (b-AsP) according to various embodiments based on the relationship shown in the left and middle plots. There is a linear dependence of the local temperature on incident power.

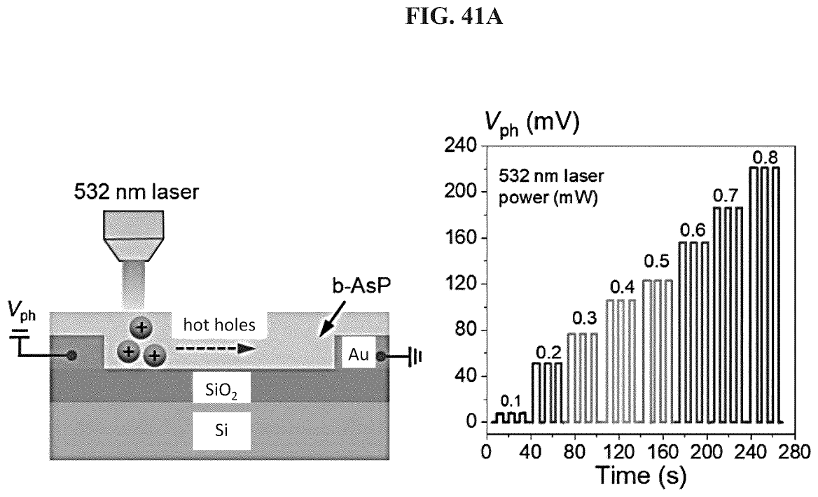

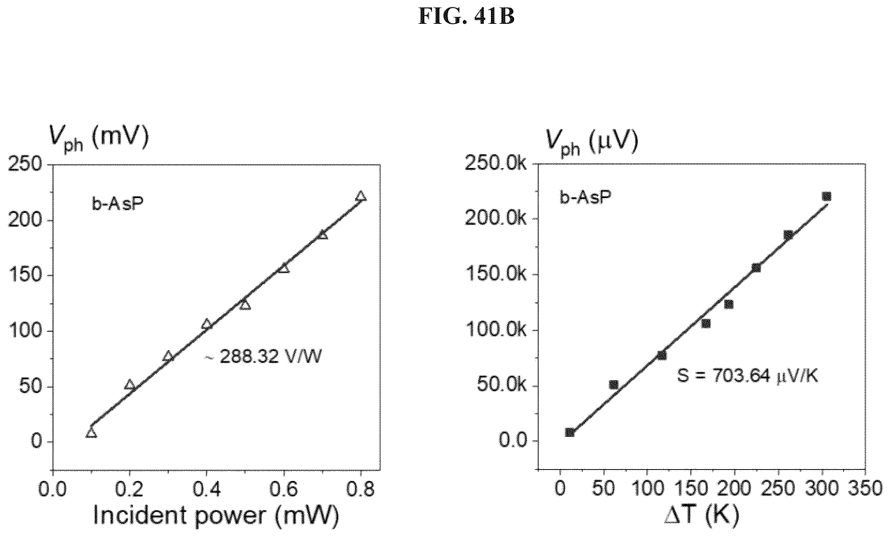

FIGS. 41A-B relate to photo-Seebeck coefficient measurement of black phosphorus-arsenic (b-AsP). FIG. 41A shows (left) a schematic of photo-Seebeck coefficient measurement setup according to various embodiments; and (right) a plot of photo-induced thermal voltage Vₚₕ (in milli-Volts or mV) as a function of time (in seconds or s) illustrating time-resolved Vₚₕ at different incident powers according to various embodiments. In photo-Seebeck coefficient measurement, a temperature gradient and a large of number of hot carriers may be induced in the b-AsP when it is locally illuminated by a focused laser. Thus, a photo-induced thermal voltage (Vₚₕ) may be obtained due to the flow of hot carriers driven by the temperature gradient. FIG. 41B shows (left) a plot of photo-induced thermal voltage (Vₚₕ) (in milli-Volts or mV) as a function of incident power (in milli-Watts or mW) according to various embodiments; and (right) a plot of photo-induced thermal voltage (Vₚₕ) (in micro-Volts or μV) as a function of temperature difference (ΔT) (in Kelvins or K) induced by the focused laser illumination according to various embodiments. The temperature difference (ΔT) was extracted according to FIG. 40B. The photo-Seebeck coefficient of b-AsP is calculated to be S=Vₚₕ/ΔT=703.64 ΔV/K.

As demonstrated above, the photovoltaic (PV) and photothermoelectric (PTE) effects are identified as the dominant mechanisms for perceiving NIR and MIR illumination respectively. The schematic diagram of the photocurrent generation in the b-AsP/MoTe₂ device under NIR and MIR global illumination are depicted in FIG. 36(c), (d) respectively. Under MIR laser global illumination, an unbalanced lattice temperature distribution is generated in b-AsP layer due to the asymmetric contacts of b-AsP with MoTe₂ and Au electrode. The lattice temperature of b-AsP at the MoTe₂ contact side is higher than that at Au electrode contact side because the Seebeck coefficient of b-AsP (723.66 μV/K, see FIGS. 38A-B) is higher than that of MoTe₂ (142.59 μV/K, FIGS. 39A-B) and the thermal conductivity of MoTe₂ (~40 W/mK) is lower than that of Au (~200 W/mK). Such lattice temperature distribution promotes the diffusion of holes in the b-AsP from the MoTe₂ contact side to Au electrode contact side, thus forming a positive PTE photocurrent under zero bias with b-AsP as the source terminal. Under NIR laser global illumination, both b-AsP and MoTe₂ layers generate electron-hole pairs which are separated by the built-in electrical field with direction pointing from b-AsP to MoTe₂ side at the junction. The photo-generated electrons and holes move toward b-AsP and MoTe₂, respectively, which contributes to the negative photovoltaic photocurrent.

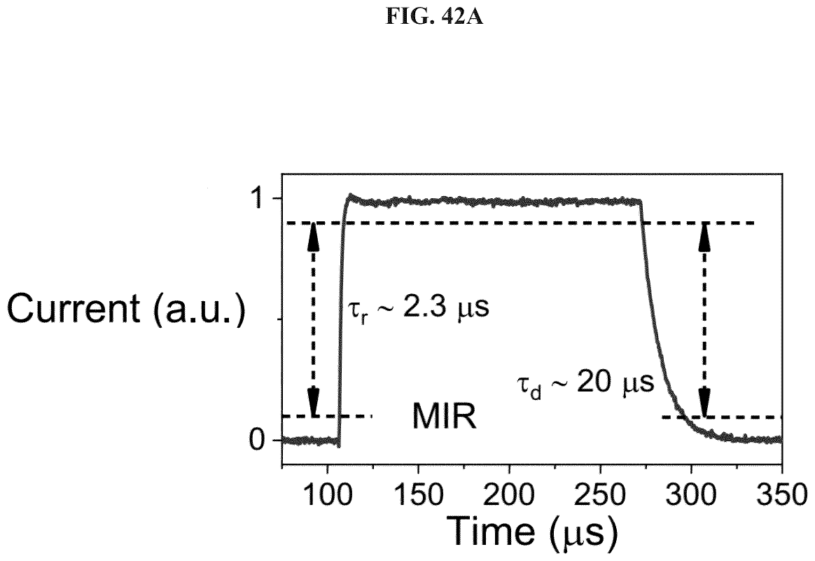

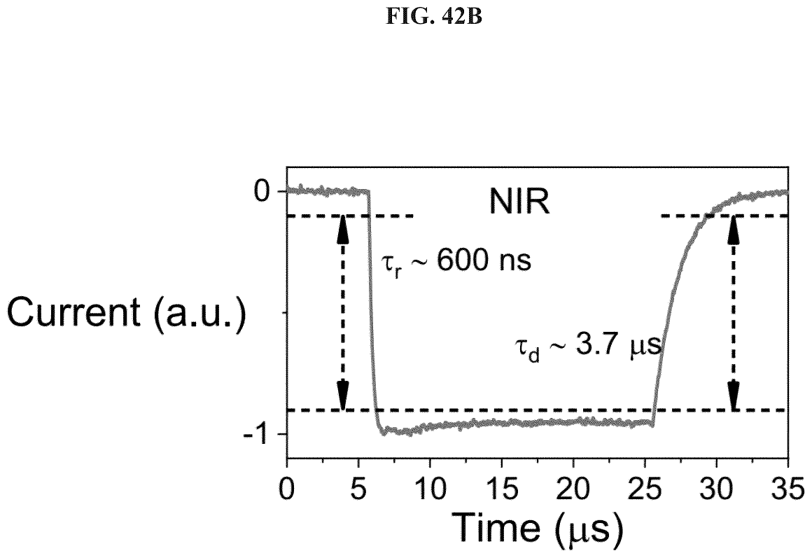

FIG. 42A shows a plot of current (in arbitrary units or a.u.) as a function of time (in micro-seconds or μs) illustrating the photoresponse of the optoelectronic device (optoelectronic device 1) at drain-source voltage V_{DS}=0 V under mid-infrared (MIR) illumination according to various embodiments. FIG. 42B shows a plot of current (in arbitrary units or a.u.) as a function of time (in micro-seconds or μs) illustrating the photoresponse of the optoelectronic device (optoelectronic device 1) at drain-source voltage V_{DS}=0 V under near-infrared (NIR) illumination according to various embodiments.

As shown in FIGS. 42A-B, the NIR and MIR photoresponse rate of the heterostructure are as fast as 600 ns/3.7 μs and 2.3 μs/20 μs, respectively. The asymmetric response time may be due to the trapping of photo-excited charge carriers by the defect state in the junction interface or by phosphorus oxide on the b-AsP surface. Moreover, the detectivity of the device to MIR illumination can reach up to ~9.6×10⁸ cm Hz^{0.5}/W.

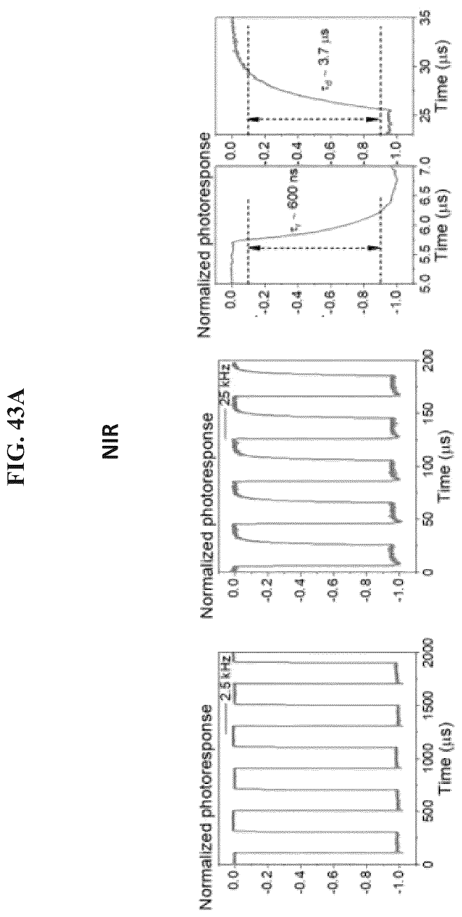

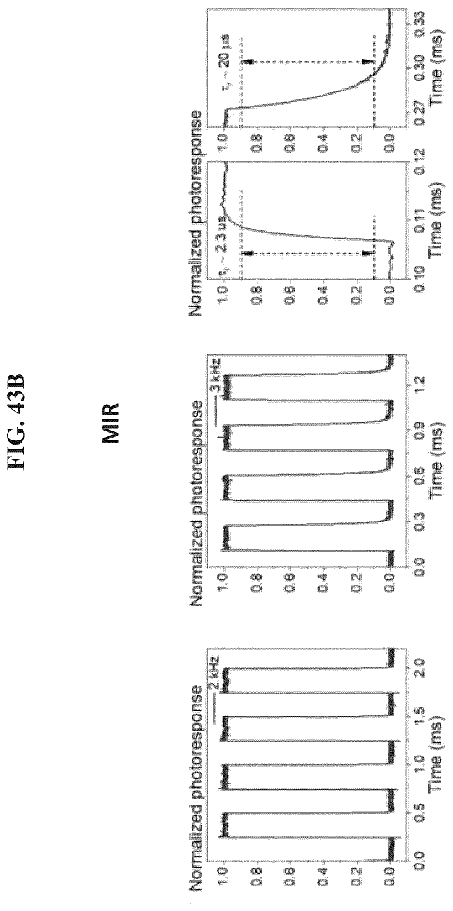

FIG. 43A-B illustrate the photoresponse of the optoelectronic device (optoelectronic device 1) at drain-source voltage V_{DS}=0 V. FIG. 43A shows (left) a plot of normalized photoresponse as a function of time (in microseconds or μs) showing the transient behaviors and speed characteristics of the optoelectronic device (optoelectronic device 1) according to various embodiments under 730 nm laser illumination at 2.5 kHz; (middle) a plot of normalized photoresponse as a function of time (in microseconds or μs) showing the transient behaviors and speed characteristics of the optoelectronic device (optoelectronic device 1) according to various embodiments under 730 nm laser illumination at 25 kHz; and (right) a plot of normalized photoresponse as a function of time (in microseconds or μs) showing a rising time of 600 ns and a decay time of 3.7 μs of the optoelectronic device (optoelectronic device 1) under 730 nm laser illumination according to various embodiments. FIG. 43B shows (left) a plot of normalized photoresponse as a function of time (in milliseconds or ms) showing the transient behaviors and speed characteristics of the optoelectronic device (optoelectronic device 1) according to various embodiments under 4.6 μm illumination at 2 kHz; (middle) a plot of normalized photoresponse as a function of time (in milliseconds or ms) showing the transient behaviors and speed characteristics of the optoelectronic device (optoelectronic device 1) according to various embodiments under 4.6 μm illumination at 3 kHz; and (right) a plot of normalized photoresponse as a function of time (in milliseconds or ms) showing a rising time of 2.3 μs and a decay time of 20 μs of the optoelectronic device (optoelectronic device 1) under 4.6 μm illumination according to various embodiments.

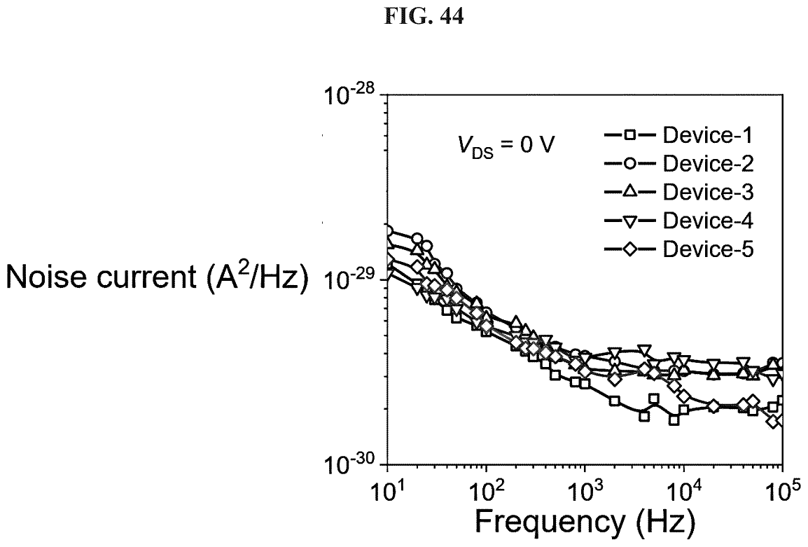

FIG. 44 shows a plot of noise current (in square Amperes per Hertz or A²/Hz) as a function of frequency (in Hertz or Hz) illustrating the noise characteristics of the optoelectronic devices (optoelectronic devices 1-5) according to various embodiments at drain-source voltage V_{DS}=0 V.

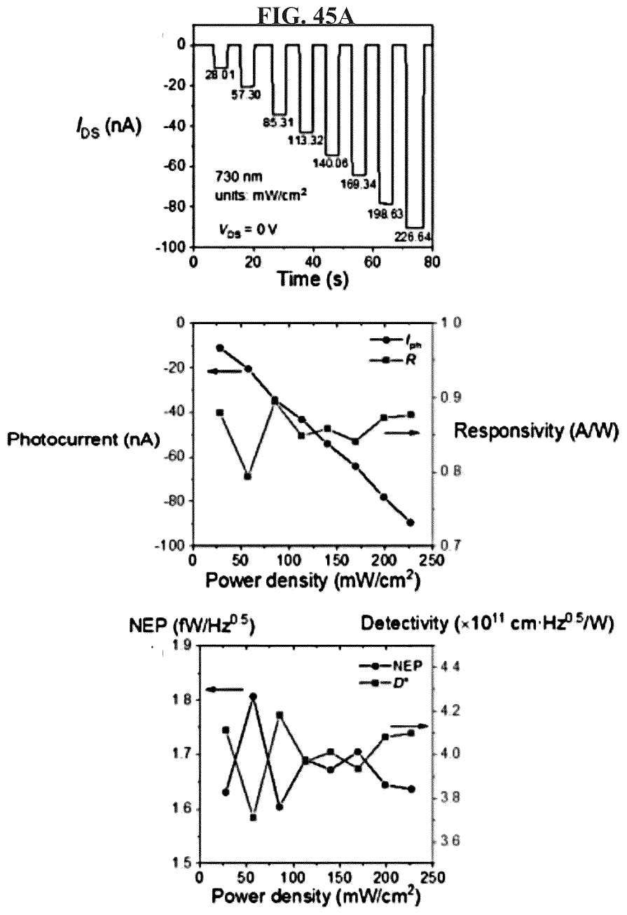

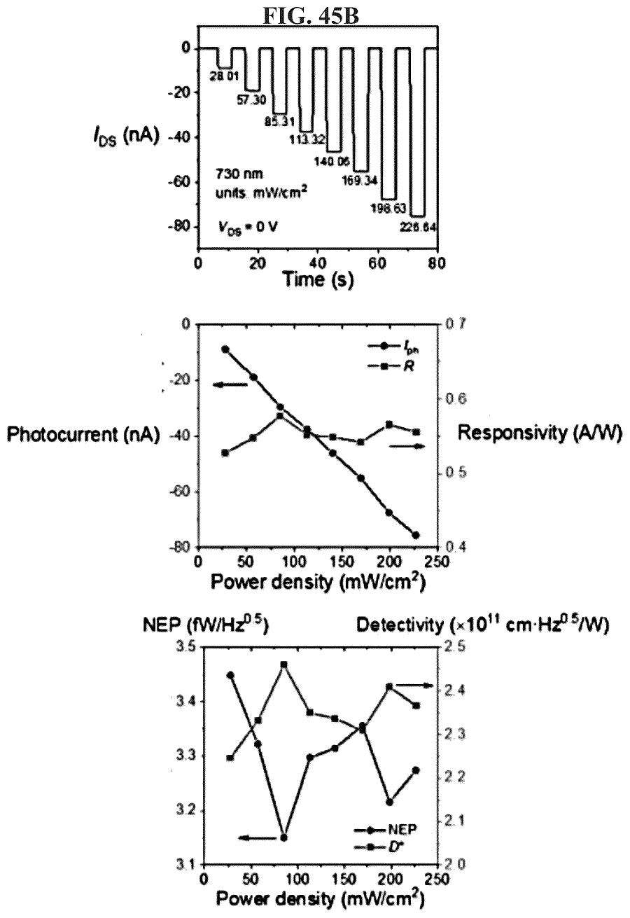

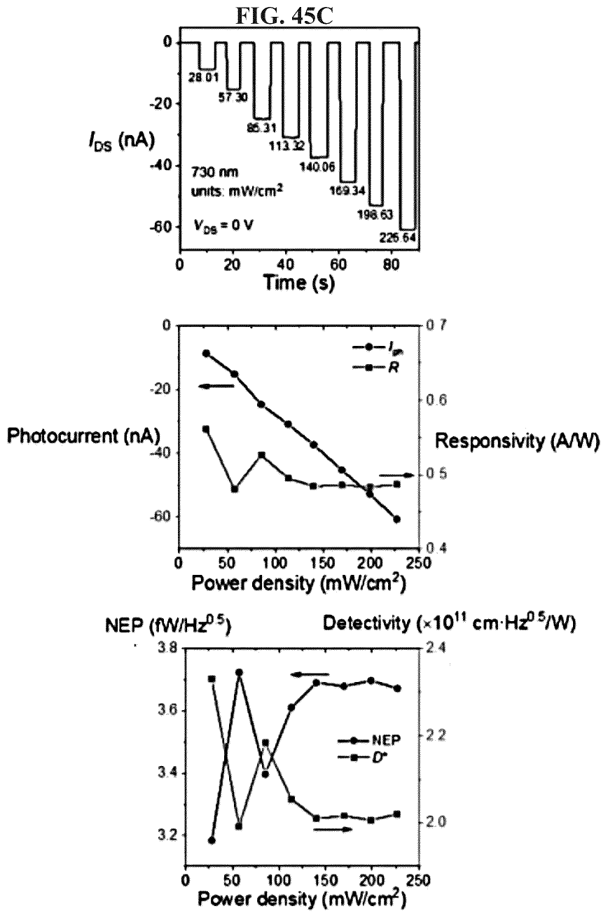

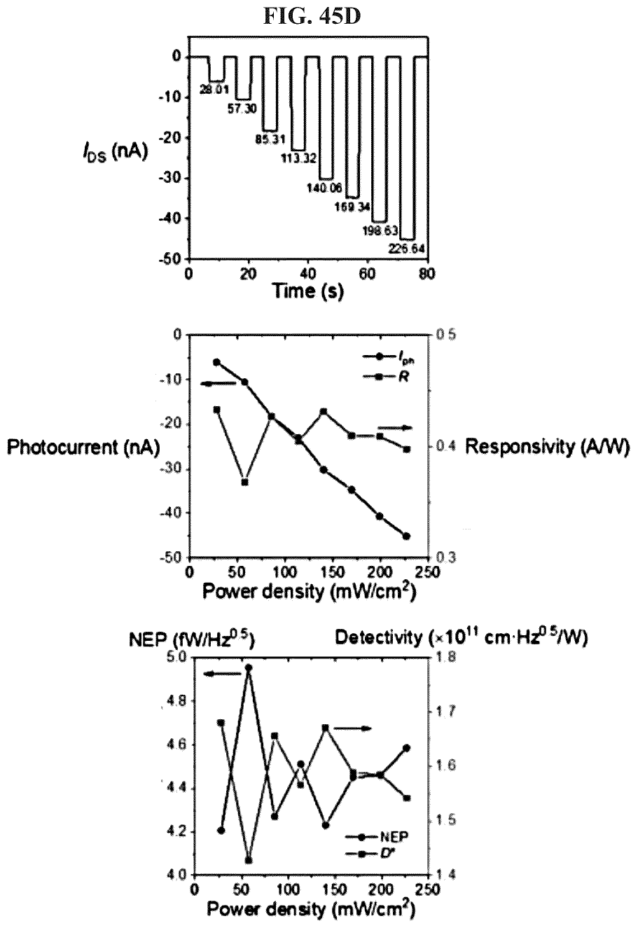

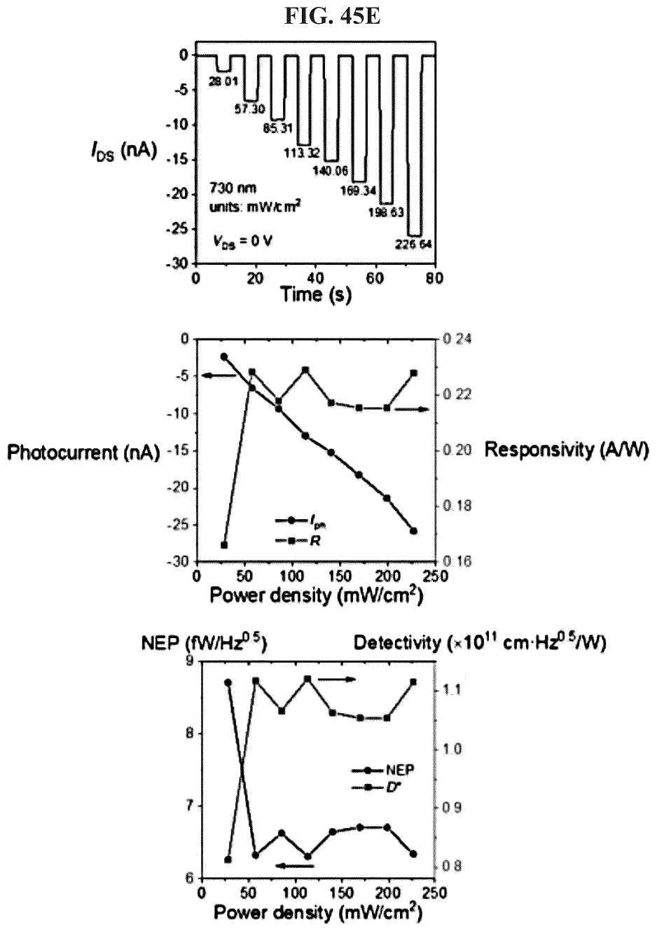

FIGS. 45A-B relate to the NIR (730 nm) photoresponse characteristics of the optoelectronic devices with various thicknesses at drain-source voltage V_{DS}=0 V. FIG. 45A shows (top) a plot of transduction current I_{DS} (in nano-Amperes or nA) as a function of time (in seconds or s) illustrating the time-resolved photoresponse of optoelectronic device 1 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 1 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 1 according to various embodiments under 730 nm illumination with power density. FIG. 45B shows (top) a plot of transduction current I_{DS} (in nano-Amperes or nA) as a function of time (in seconds or s) illustrating the time-resolved photoresponse of optoelectronic device 2 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 2 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 2 according to various embodiments under 730 nm illumination with power density. FIG. 45C shows (top) a plot of transduction current I_{DS} (in nano-Amperes or nA) as a function of time (in seconds or s) illustrating the time-resolved photoresponse of optoelectronic device 3 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 3 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 3 according to various embodiments under 730 nm illumination with power density. FIG. 45D shows (top) a plot of transduction current I_{DS} (in nano-Amperes or nA) as a function of time (in seconds or s) illustrating the time-resolved photoresponse of optoelectronic device 4 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 4 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 4 according to various embodiments under 730 nm illumination with power density. FIG. 45E shows (top) a plot of transduction current I_{DS} (in nano-Amperes or nA) as a function of time (in seconds or s) illustrating the time-resolved photoresponse of optoelectronic device 5 according to various embodiments under 730 nm illumination with various power densities; (middle) a plot of photocurrent (in nano-Amperes or nA)/responsivity (in Amperes per Watt or A/W) as a function of power density (in milli-Watts per square centimeter or mW/cm²) illustrating power density-dependent photocurrent and responsivity of optoelectronic device 5 according to various embodiments under 730 nm illumination; and (bottom) a plot of noise equivalent power NEP (in femto-Watts per square root Hertz or fW Hz^{-0.5})/detectivity (×10¹¹, in centimeter square root Hertz per Watt or cm·Hz^{0.5}/W) as a function of power density (in milli-Watts per square centimeter or mW/cm²) illustrating variation of NEP and detectivity of optoelectronic device 5 according to various embodiments under 730 nm illumination with power density.

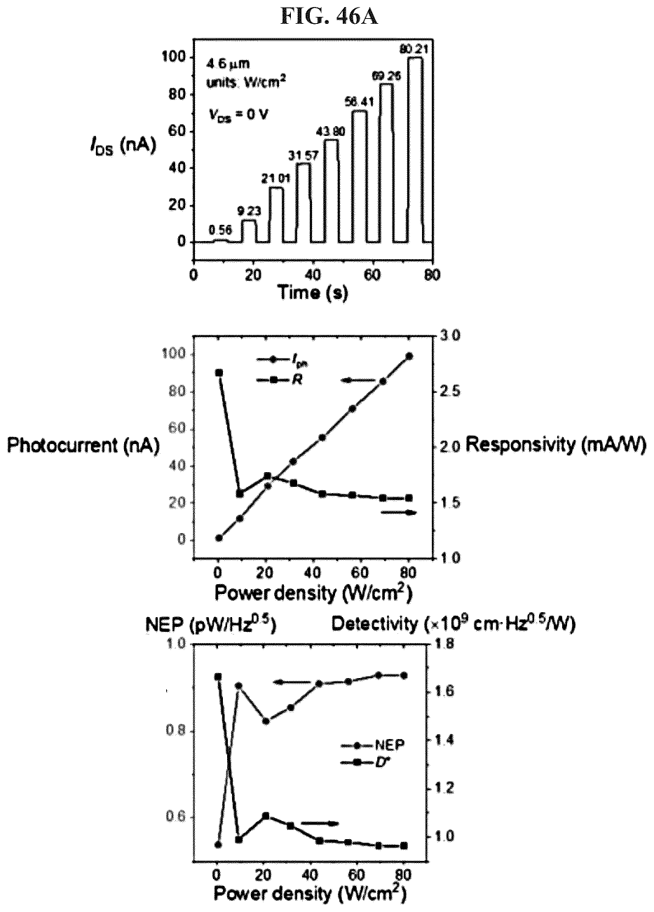

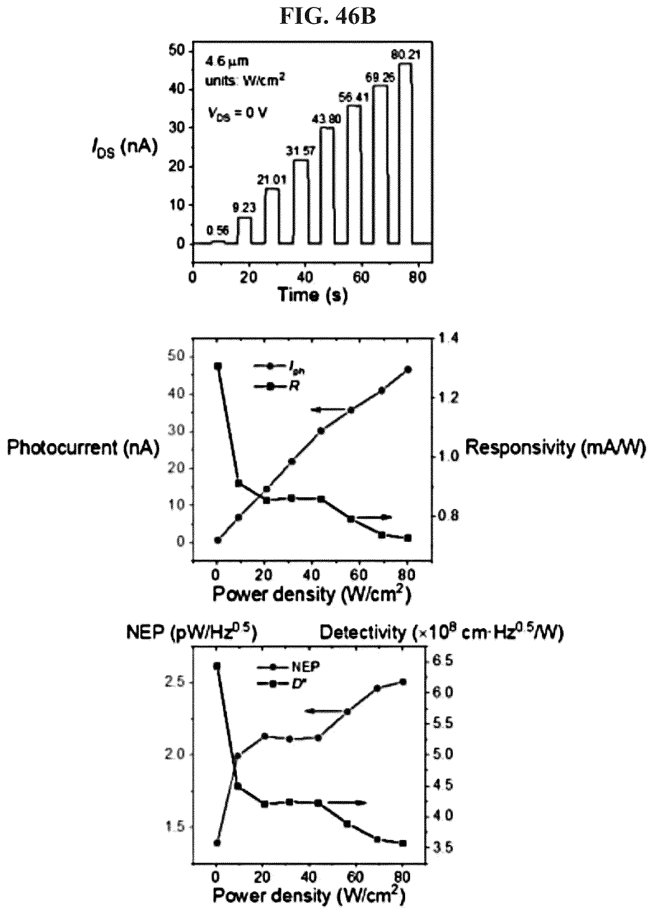

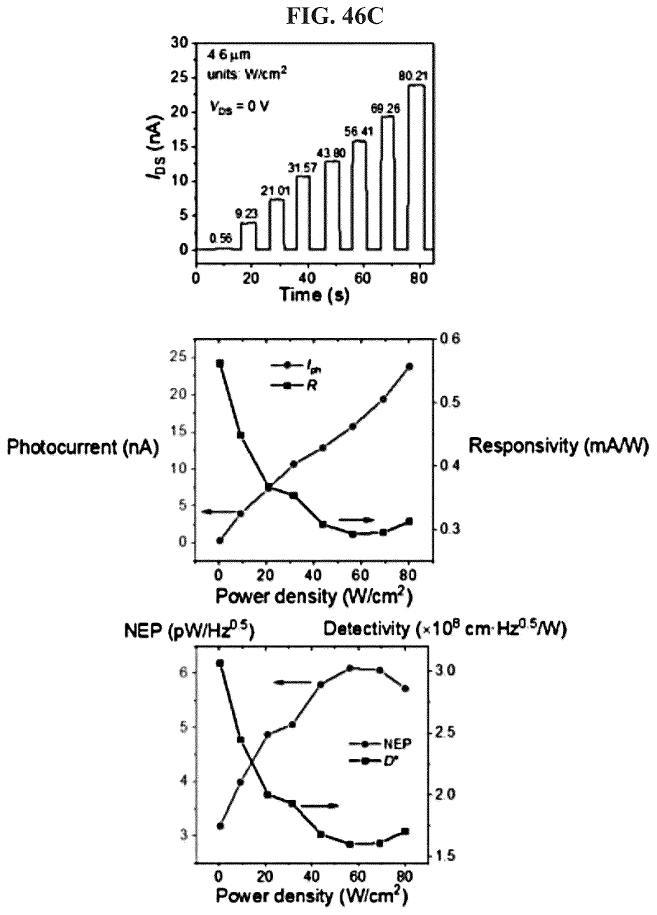

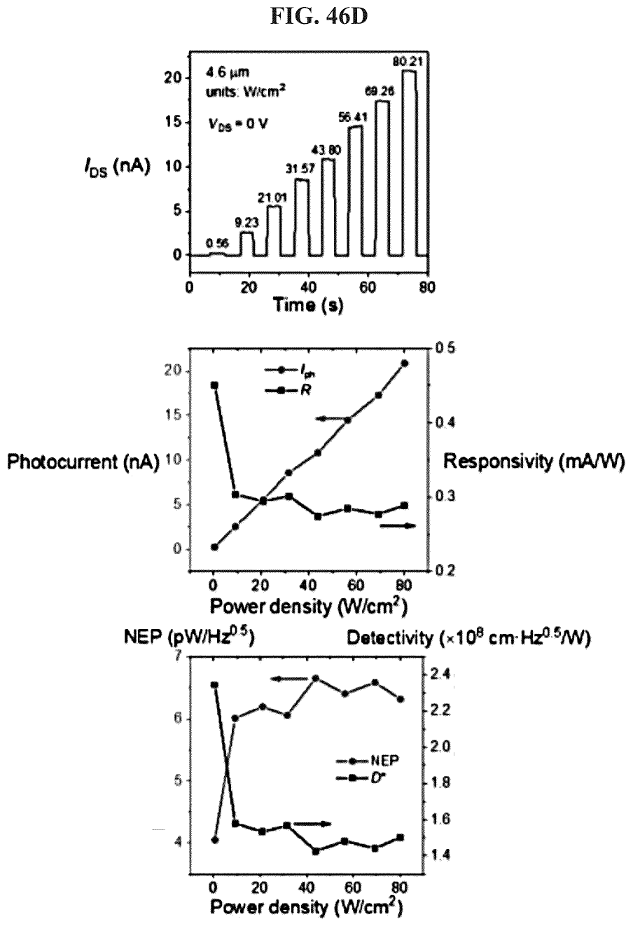

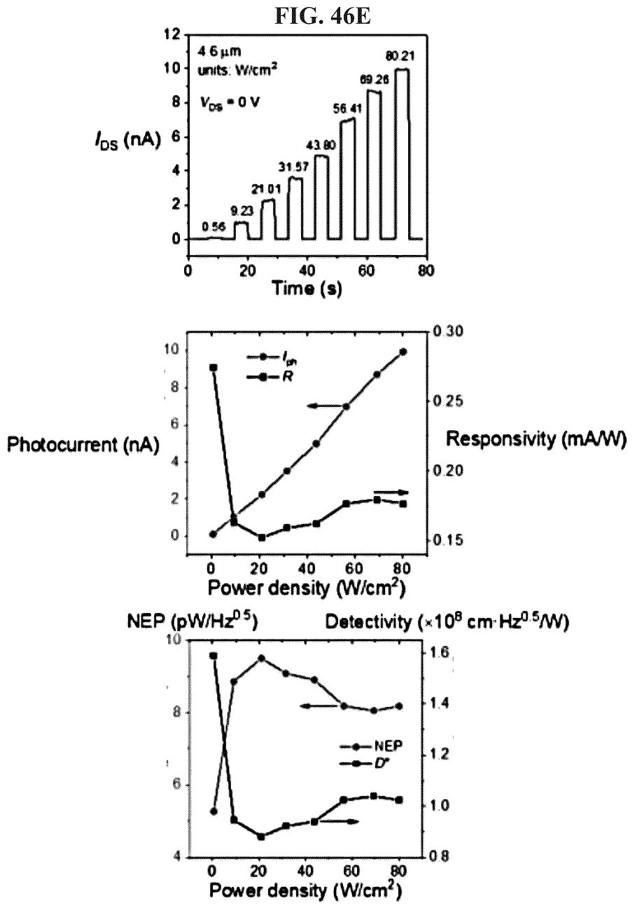

FIGS. 46A-E relate to the MIR (4.6 μm) photoresponse characteristics of the optoelectronic devices with various thicknesses at drain-source voltage V_{DS}=0 V. FIG. 46A shows (top) a plot of transduction current I_{DS} (in nano-Amperes or nA) as a function of time (in seconds or s) illustrating the time-resolved photoresponse of optoelectronic device 1 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 1 according to various embodiments under 4.6 μm illumination; and (bottom) a plot of noise equivalent power NEP (in pico-Watts per square root Hertz or pW Hz^{-0.5})/detectivity (×10⁹, in centimeter square root Hertz per Watt or cm·Hz^{0.5}/W) as a function of power density (in Watts per square centimeter or W/cm²) illustrating variation of NEP and detectivity of optoelectronic device 1 according to various embodiments under 4.6 μm illumination with power density. FIG. 46B shows (top) a plot of transduction current I_{DS} (in nano-Amperes or nA) as a function of time (in seconds or s) illustrating the time-resolved photoresponse of optoelectronic device 2 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 2 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 2 according to various embodiments under 4.6 μm illumination with power density. FIG. 46C shows (top) a plot of transduction current I_{DS} (in nano-Amperes or nA) as a function of time (in seconds or s) illustrating the time-resolved photoresponse of optoelectronic device 3 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 3 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 3 according to various embodiments under 4.6 μm illumination with power density. FIG. 46D shows (top) a plot of transduction current I_{DS} (in nano-Amperes or nA) as a function of time (in seconds or s) illustrating the time-resolved photoresponse of optoelectronic device 4 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 4 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 4 according to various embodiments under 4.6 μm illumination with power density. FIG. 46E shows (top) a plot of transduction current I_{DS} (in nano-Amperes or nA) as a function of time (in seconds or s) illustrating the time-resolved photoresponse of optoelectronic device 5 according to various embodiments under 4.6 μm illumination with various power densities; (middle) a plot of photocurrent (in nano-Amperes or nA)/responsivity (in milli-Amperes per Watt or mA/W) as a function of power density (in Watts per square centimeter or W/cm²) illustrating power density-dependent photocurrent and responsivity of optoelectronic device 5 according to various embodiments under 4.6 μm illumination; and (bottom) a plot of noise equivalent power NEP (in pico-Watts per square root Hertz or pW Hz^{-0.5})/detectivity (×10⁸, in centimeter square root Hertz per Watt or cm·Hz^{0.5}/W) as a function of power density (in Watts per square centimeter or W/cm²) illustrating variation of NEP and detectivity of optoelectronic device 5 according to various embodiments under 4.6 μm illumination with power density.

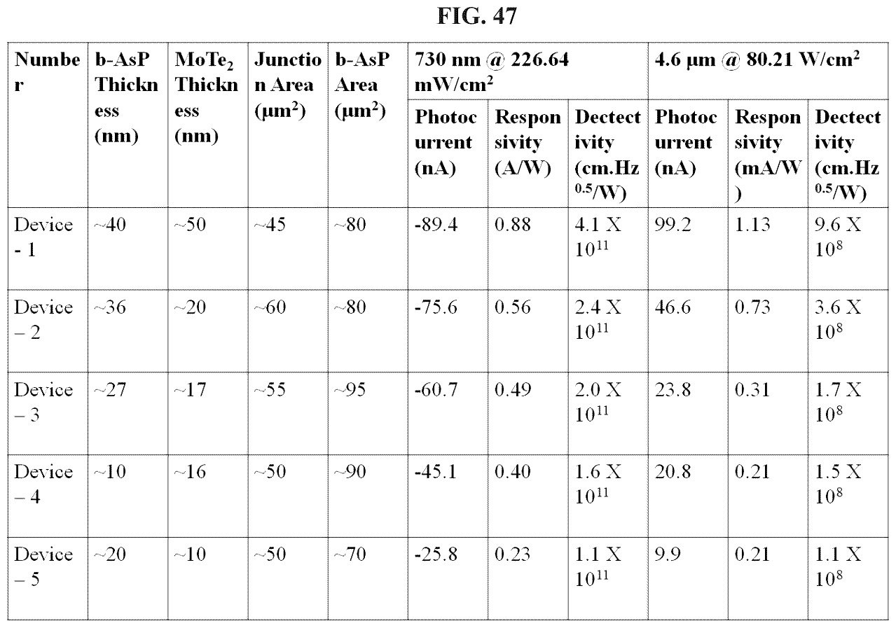

FIG. 47 shows a table comparing the photoresponse performances of the 5 optoelectronic devices with various thicknesses according to various embodiments.

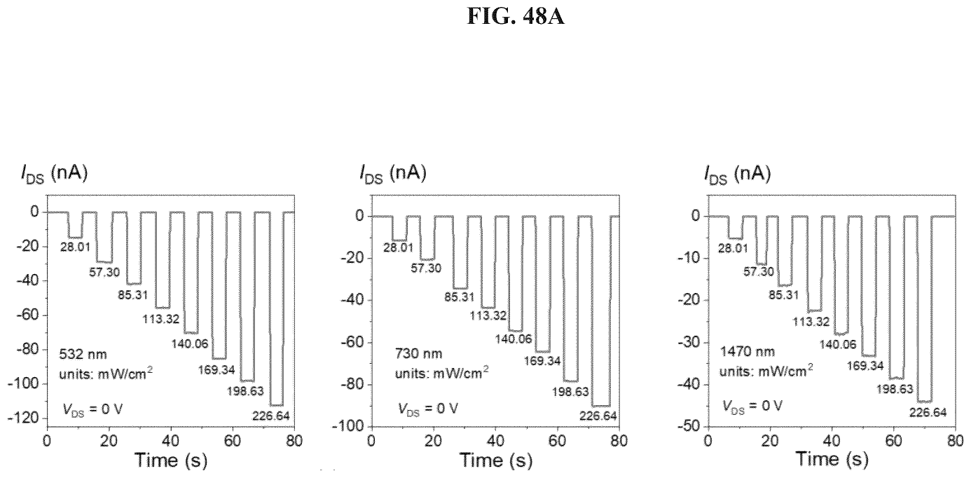

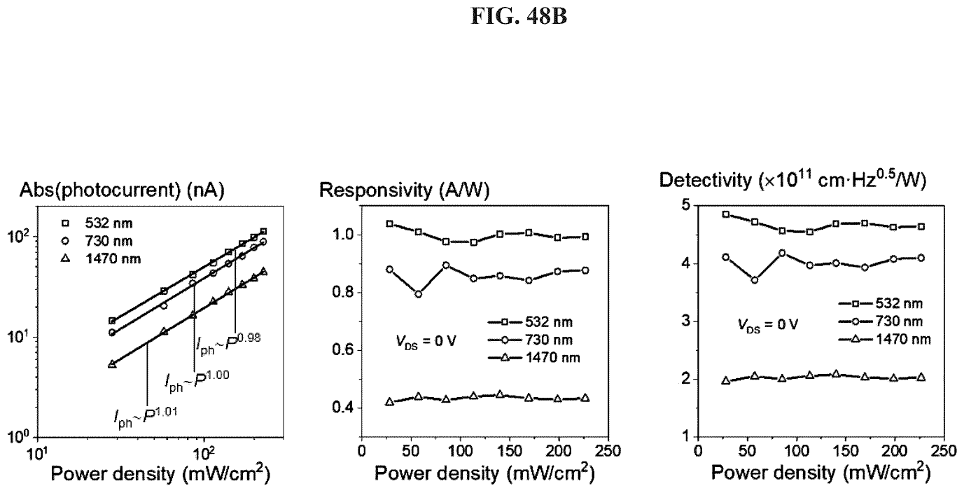

FIGS. 48A-B illustrate visible/near-infrared photoresponse characteristics of optoelectronic device 1 according to various embodiments at drain-source voltage V_{DS}=0 V. FIG. 48A shows (left) a plot of transduction current (in nano-Amperes or nA) as a function of time (in seconds or s) illustrating time-resolved photoresponse of optoelectronic device 1 according to various embodiments under 532 nm at various power densities; (middle) a plot of transduction current (in nano-Amperes or nA) as a function of time (in seconds or s) illustrating time-resolved photoresponse of optoelectronic device 1 according to various embodiments under 730 nm at various power densities; and (right) a plot of transduction current (in nano-Amperes or nA) as a function of time (in seconds or s) illustrating time-resolved photoresponse of optoelectronic device 1 according to various embodiments under 1470 nm at various power densities. FIG. 48B shows (left) a plot of absolute (abs) photocurrent (in nanometers or nm) as a function of power density (in milli-Watts per square centimeter or mW/cm²) illustrating the power dependence of photocurrent of optoelectronic device 1 according to various embodiments; (middle) a plot of responsivity (in Amperes per Watt or A/W) as a function of power density (in milli-Watts per square centimeter or mW/cm²) illustrating the power dependence of responsivity of optoelectronic device 1 according to various embodiments; and (right) a plot of detectivity (×10¹¹, in centimeter square root Hertz per Watt or cm·Hz^{0.5}/W) as a function of power density (in milli-Watts per square centimeter or mW/cm²) illustrating the power dependence of detectivity of optoelectronic device 1 according to various embodiments.

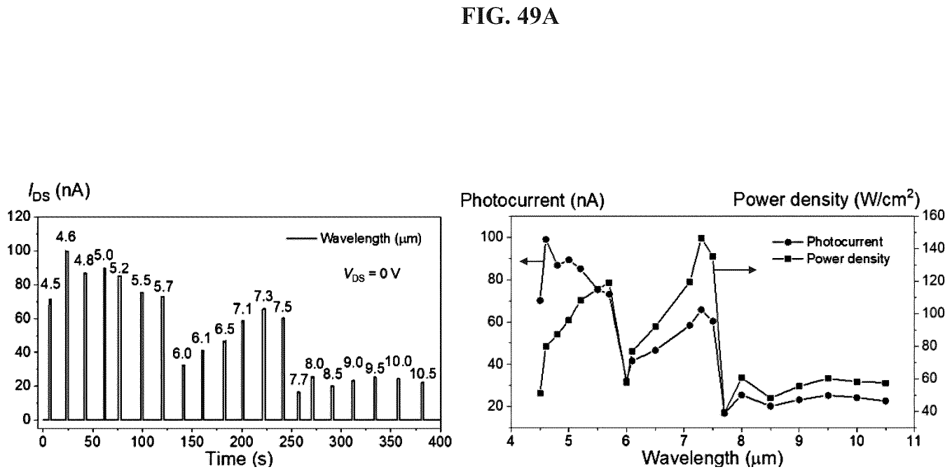

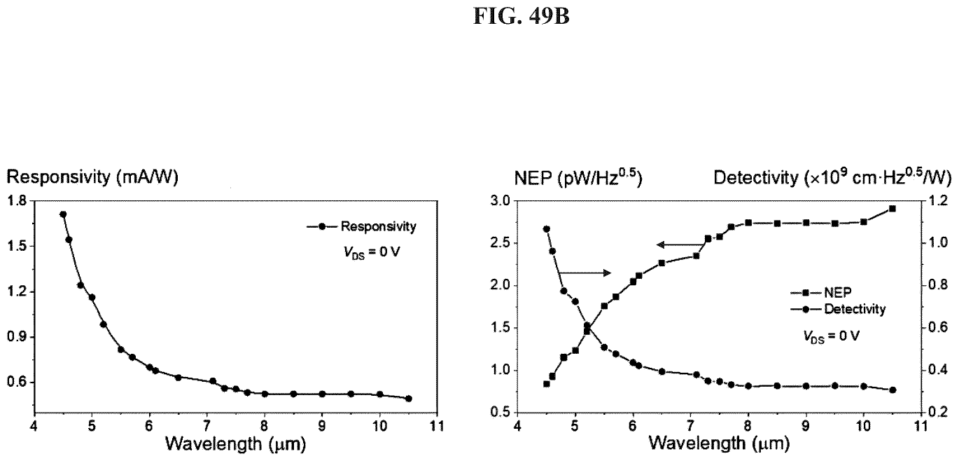

FIGS. 49A-B illustrate broadband MIR photoresponse characteristics of optoelectronic device 1 according to various embodiments at drain-source voltage V_{DS}=0 V. FIG. 49A shows (left) a plot of transduction current I_{DS} (in nano-Amperes or nA) as a function of time (in seconds or s) illustrating time-resolved photoresponse of optoelectronic device 1 under illumination according to various embodiments with various wavelengths from 4.5 μm to 10.5 μm; and (right) a plot of photocurrent (in nano-Amperes or nA)/power density (in Watts per square centimeters or W/cm²) illustrating the photocurrent and power density corresponding to each wavelength according to various embodiments. FIG. 49B shows (left) a plot of responsivity (in milli-Amperes per Watt or mA/W) as a function of wavelength (in micrometers or μm) illustrating the wavelength-dependent responsivity of optoelectronic device 1 according to various embodiments, and (right) noise equivalent power NEP (in picoWatts per square root Hertz or pW Hz^{-0.5})/detectivity (×10⁹, in centimeter square root Hertz per Watt or cm·Hz^{0.5}/W) as a function of wavelength (in micrometers or μm) illustrating variation of NEP and detectivity with wavelength according to various embodiments.

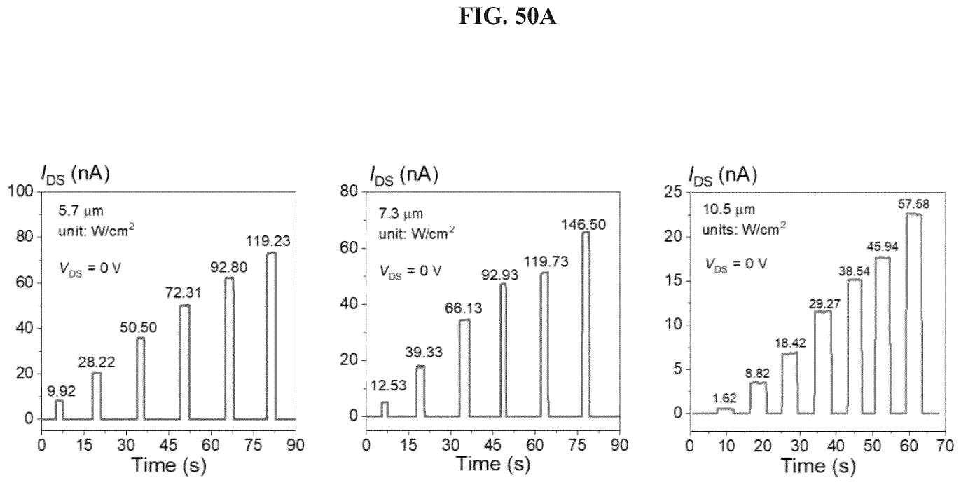

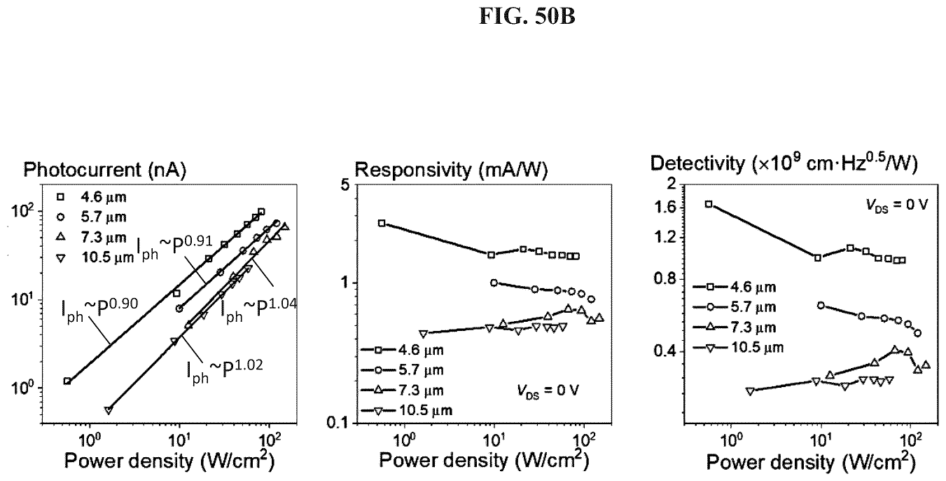

FIGS. 50A-B illustrate MIR photoresponse characteristics of optoelectronic device 1 according to various embodiments at drain-source voltage V_{DS}=0 V. FIG. 50A shows (left) a plot of transduction current I_{DS} (in nano-Amperes or nA) as a function of time (in seconds or s) illustrating time-resolved photoresponse of optoelectronic device 1 according to various embodiments under 5.7 μm laser illumination with various power densities; (middle) a plot of transduction current I_{DS} (in nano-Amperes or nA) as a function of time (in seconds or s) illustrating time-resolved photoresponse of optoelectronic device 1 according to various embodiments under 7.3 μm laser illumination with various power densities; and (right) a plot of transduction current I_{DS} (in nano-Amperes or nA) as a function of time (in seconds or s) illustrating time-resolved photoresponse of optoelectronic device 1 according to various embodiments under 10.5 μm laser illumination with various power densities. FIG. 50B shows (left) a plot of photocurrent (in nano-Amperes or nA) as a function of power density (in Watts per square centimeter or W/cm²) illustrating the power dependence of photocurrent of optoelectronic device 1 according to various embodiments; (middle) a plot of responsivity (in milli-Amperes per Watt or mA/W) as a function of power density (in Watts per square centimeter or W/cm²) illustrating the power dependence of responsivity of optoelectronic device 1 according to various embodiments; and (right) a plot of detectivity (×10⁹, in centimeter square root Hertz per Watt or cm·Hz^{0.5}/W) as a function of power density (in Watts per square centimeter or W/cm²) illustrating the power dependence of detectivity of the device according to various embodiments.

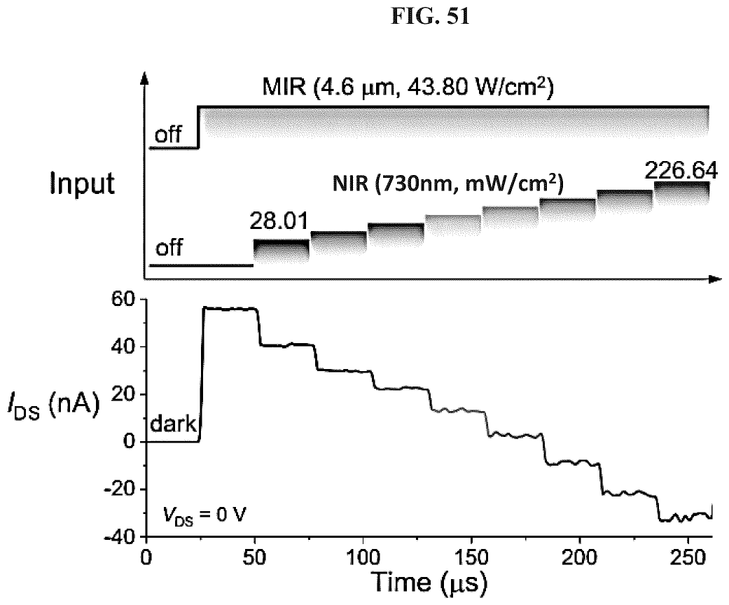

For encoding operations, the MIR stimulus signals and NIR sampling terminal are simultaneously input onto the device. The photoresponse of optoelectronic device 1 is demonstrated under simultaneous illuminations of both MIR and NIR lasers. FIG. 51 shows (above) input as a function of time (in micro-seconds or μs) illustrating the input illumination provided to optoelectronic device 1 according to various embodiments as a function of time (in micro-seconds or μs); and (below) a plot of the transduction current I_{DS} (in nano-Amperes of nA) as a function of time (in micro-seconds or μs) of optoelectronic device 1 according to various embodiments under the input illumination. The power densities of MIR and NIR are indicated in the upper panel. As shown in FIG. 51, distinct output photocurrents (I_{DS}) can be observed when the device is simultaneously illuminated by MIR with a certain power density and NIR with various power densities. The photoresponse under the simultaneous illuminations shows high repeatability and stability, evidenced by multiple and reproducible switching.

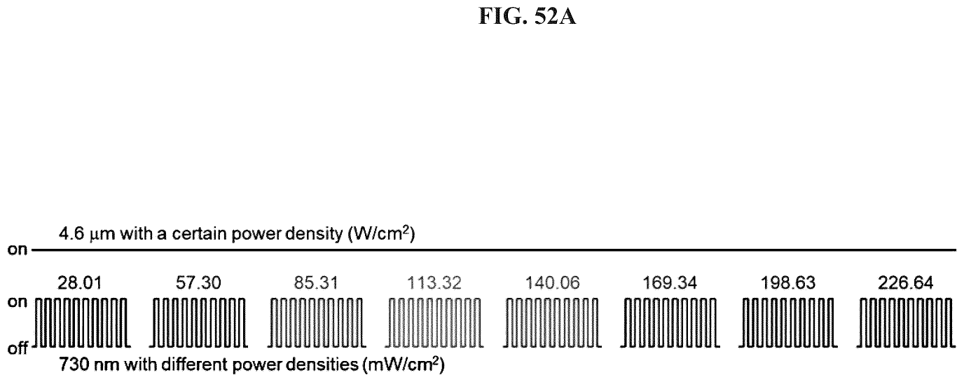

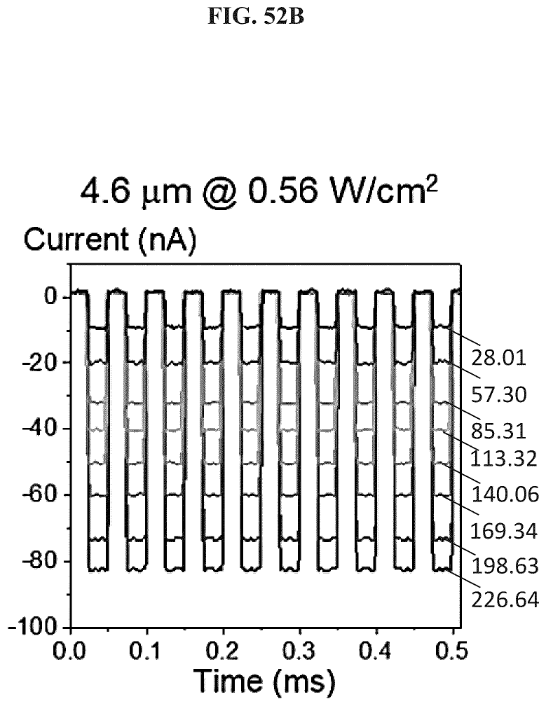

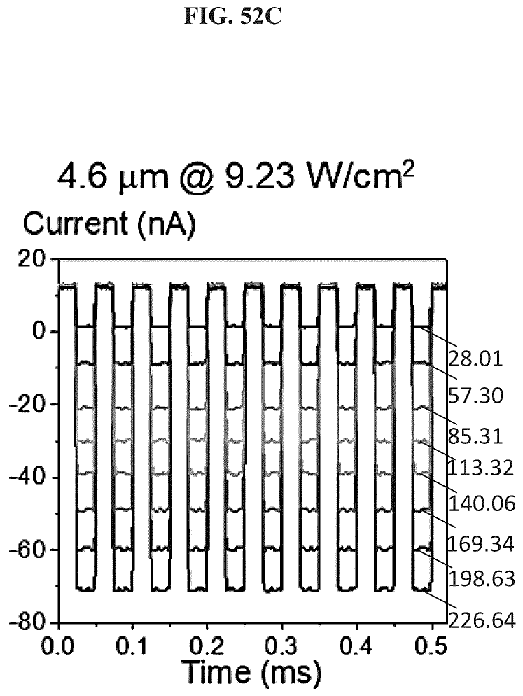

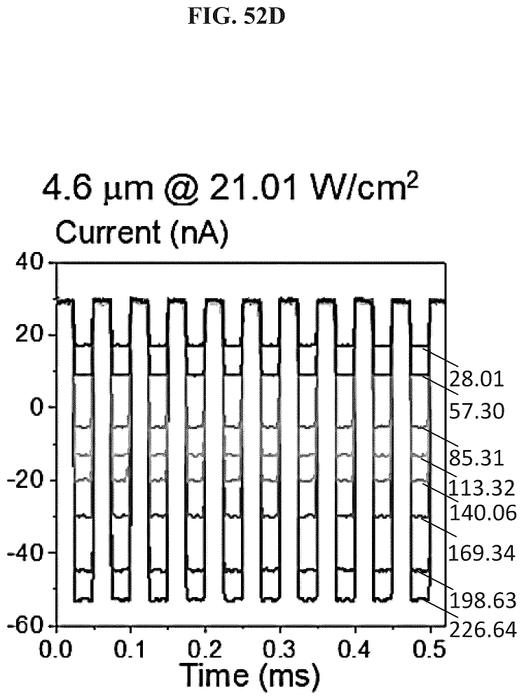

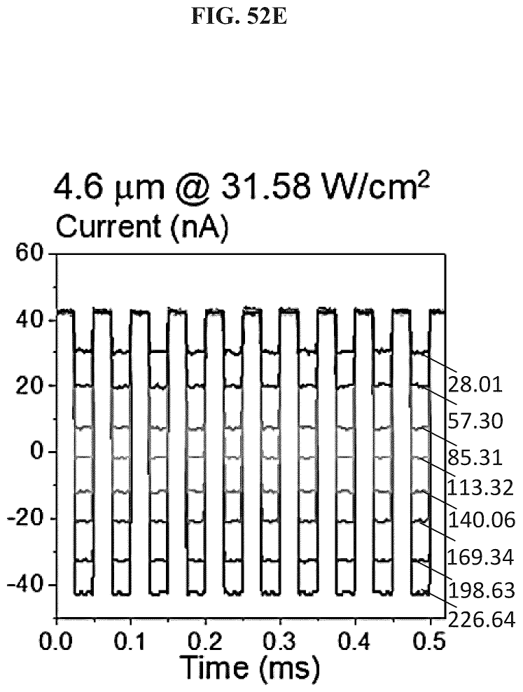

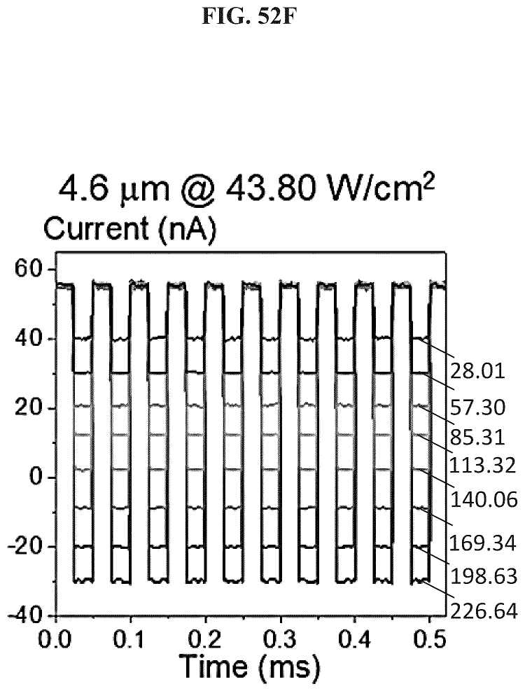

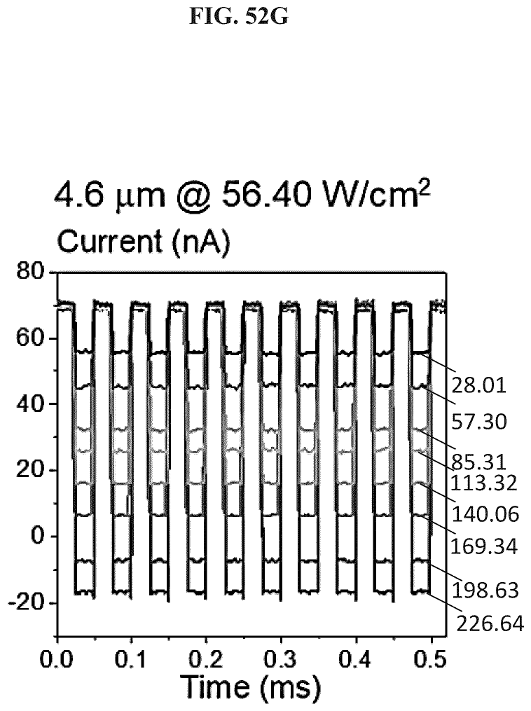

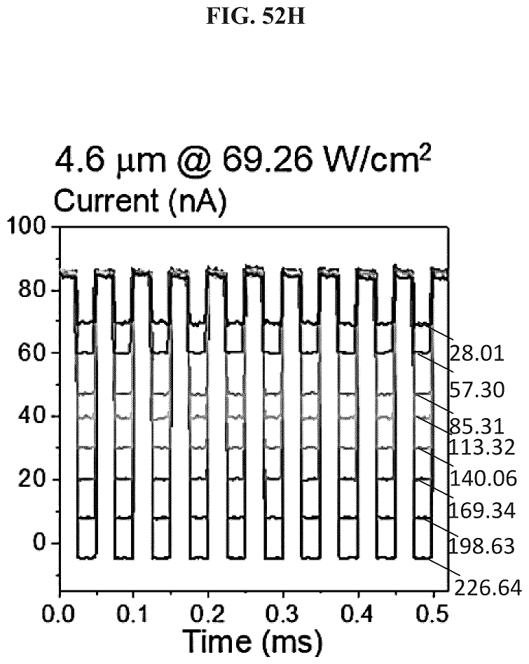

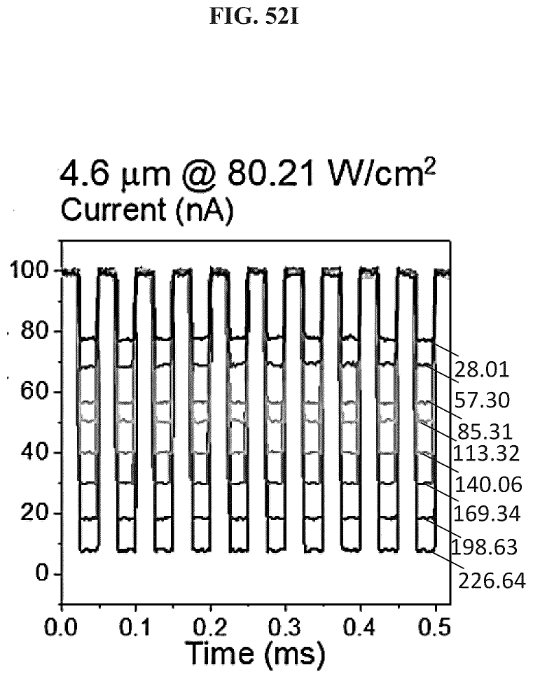

FIG. 52A shows the measurement conditions of optoelectronic device 1 according to various embodiments, i.e. under simultaneous illumination of 4.6 μm illumination and various power densities of 730 nm illumination. FIG. 52B shows a plot of current (in nano-Amperes or nA) as a function of time (in milliseconds or ms) illustrating the photoresponse of optoelectronic device 1 according to various embodiments under 0.56 W/cm² of 4.6 μm illumination and various power densities of 730 nm illumination. FIG. 52C shows a plot of current (in nano-Amperes or nA) as a function of time (in milliseconds or ms) illustrating the photoresponse of optoelectronic device 1 according to various embodiments under 9.23 W/cm² of 4.6 μm illumination and various power densities of 730 nm illumination. FIG. 52D shows a plot of current (in nano-Amperes or nA) as a function of time (in milliseconds or ms) illustrating the photoresponse of optoelectronic device 1 according to various embodiments under 21.01 W/cm² of 4.6 μm illumination and various power densities of 730 nm illumination. FIG. 52E shows a plot of current (in nano-Amperes or nA) as a function of time (in milliseconds or ms) illustrating the photoresponse of optoelectronic device 1 according to various embodiments under 31.58 W/cm² of 4.6 μm illumination and various power densities of 730 nm illumination. FIG. 52F shows a plot of current (in nano-Amperes or nA) as a function of time (in milliseconds or ms) illustrating the photoresponse of optoelectronic device 1 according to various embodiments under 43.80 W/cm² of 4.6 μm illumination and various power densities of 730 nm illumination. FIG. 52G shows a plot of current (in nano-Amperes or nA) as a function of time (in milliseconds or ms) illustrating the photoresponse of the optoelectronic device (optoelectronic device 1) according to various embodiments under 56.40 W/cm² of 4.6 μm illumination and various power densities of 730 nm illumination. FIG. 52H shows a plot of current (in nano-Amperes or nA) as a function of time (in milliseconds or ms) illustrating the photoresponse of optoelectronic device 1 according to various embodiments under 69.26 W/cm² of 4.6 μm illumination and various power densities of 730 nm illumination. FIG. 52I shows a plot of current (in nano-Amperes or nA) as a function of time (in milliseconds or ms) illustrating the photoresponse of optoelectronic device 1 according to various embodiments under 80.21 W/cm² of 4.6 μm illumination and various power densities of 730 nm illumination.

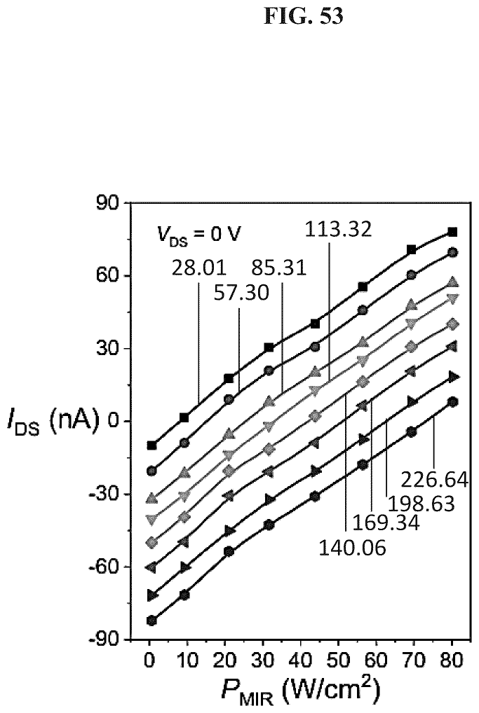

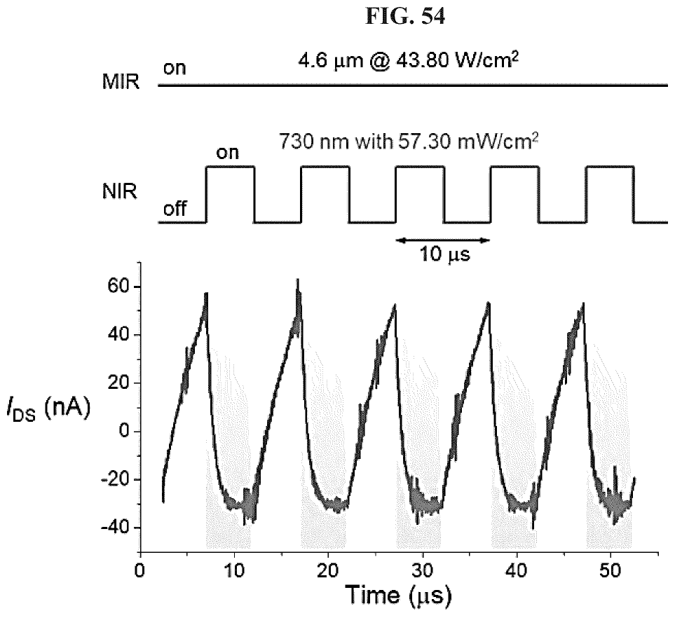

FIG. 53 shows a plot of transduction current I_{DS} (in nano-Amperes or nA) as a function of mid-infrared power density P_{MIR} (in Watts per square centimeter or W/cm²) illustrating the dependence of output current of the optoelectronic device (optoelectronic device 1) according to various embodiments on the MIR power density under the modulation of near-infrared (NIR light) with various power densities (P_{NIR}, in milli-Watts per square centimeter or mW/cm²). FIG. 53 depicts the dependence of I_{DS} on the MIR illumination intensity at different NIR power densities, which is an important reference to obtain dynamic encoding range for MIR power density (P_{MIR}) once the I_{TC} and NIR power density (P_{NIR}) distribution are given. More important, the stable photoresponse can be still maintained under NIR illumination with a frequency of 100 KHz. FIG. 54 shows a plot of a plot of transduction current I_{DS} (in nano-Amperes or nA) as a function of time (in microseconds or μs) illustrating the fast response of the optoelectronic device (optoelectronic device 1) according to various embodiments under simultaneous illuminations of both 4.6 μm and 730 nm. Such a fast and stable response makes it possible to generate higher spiking rates and provides a guarantee for high-precision MIR intensity coding.

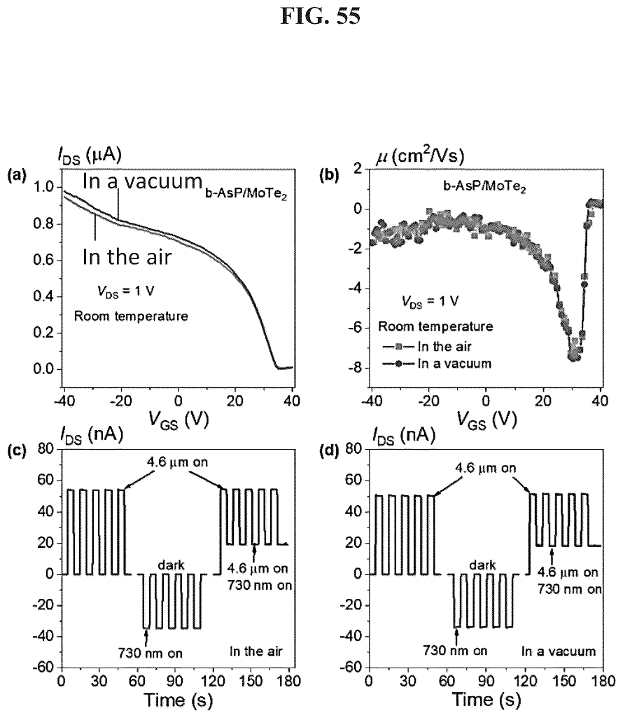

FIG. 55 illustrates the comparison of carrier mobility and photoresponse characteristics of the b-AsP/MoTe₂ device (optoelectronic device 1) in the air and a vacuum (~10⁻⁶ Torr). FIG. 55 shows (a) a plot of transduction current I_{DS} (in micro-Amperes or μA) as a function of gate voltage V_{GS} (in volts or V) illustrating the I_{DS}−V_{DS} curves of the optoelectronic device (optoelectronic device 1) according to various embodiments in the air and in vacuum at room temperature; (b) a plot of mobility μ (in square centimeter per volt-second or cm²/Vs) as a function of gate voltage V_{DS} (in volts or V) illustrating the as-calculated carrier mobility from (a), showing a negligible change from the air to a vacuum; (c) a plot of transduction current I_{DS} (in nano-Amperes or nA) as a function of time (in seconds or s) illustrating the photoresponse characteristics of the optoelectronic device (optoelectronic device 1) according to various embodiments at drain-source voltage V_{DS}=0V in air; and (d) a plot of transduction current I_{DS} (in nano-Amperes or nA) as a function of time (in seconds or s) illustrating the photoresponse characteristics of the optoelectronic device (optoelectronic device 1) according to various embodiments at drain-source voltage V_{DS}=0V in vacuum. The almost unchanged carrier mobility and photoresponse indicates that the h-BN-encapsulated b-AsP/MoTe₂ device possesses good stability.

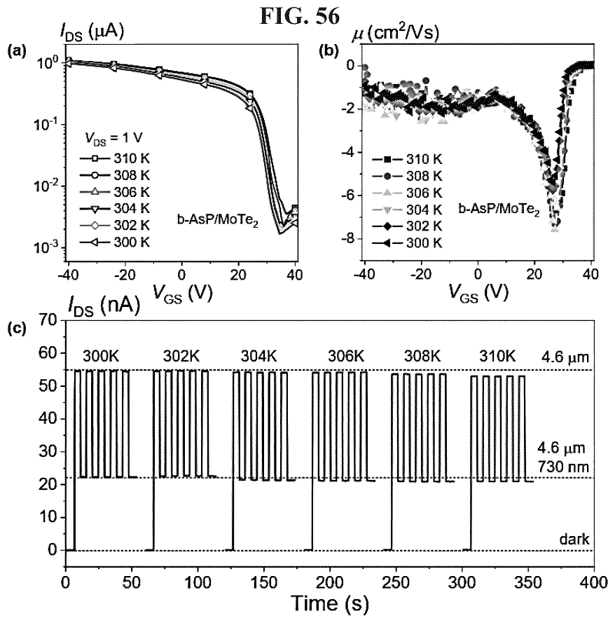

FIG. 56 illustrates the effect of temperature variation on carrier mobility and photoresponse of the optoelectronic device (optoelectronic device 1) according to various embodiments. FIG. 56 shows (a) a plot of transduction current I_{DS} (in micro-Amperes or μA) as a function of gate voltage V_{GS} (in volts or V) illustrating the I_{DS}−V_{GS} curves of the optoelectronic device (optoelectronic device 1) according to various embodiments at various temperatures from 300 K to 310 K; (b) a plot of mobility μ (in square centimeter per volt-second or cm²/Vs) as a function of gate voltage V_{GS} (in volts or V) illustrating the as-calculated carrier mobility from (a), showing little change from 300 K to 310 K; and (c) a plot of transduction current I_{DS} (in nano-Amperes or nA) as a function of time (in seconds or s) illustrating the photoresponse characteristics of the optoelectronic device (optoelectronic device 1) according to various embodiments at different temperatures, showing a slight decrease (<2 nA) with increasing temperatures from 300 K to 310 K. Such a small effect may not be enough to affect device performance.

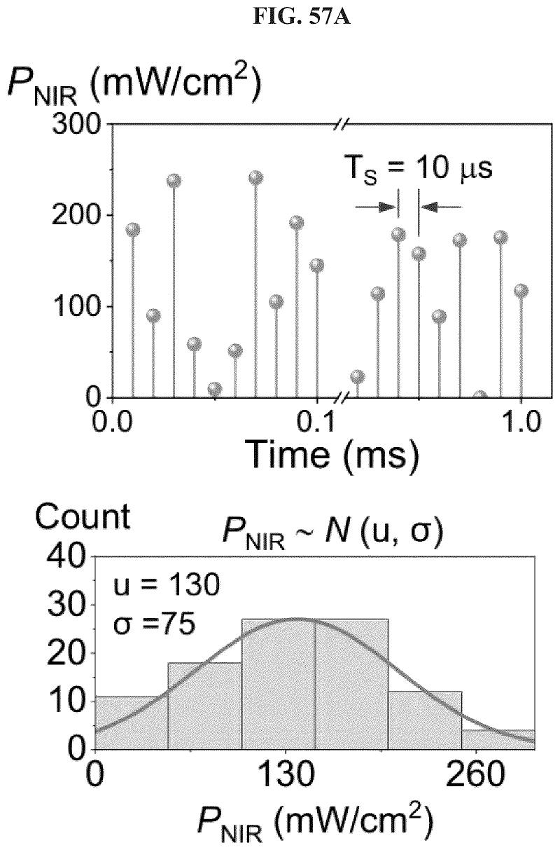

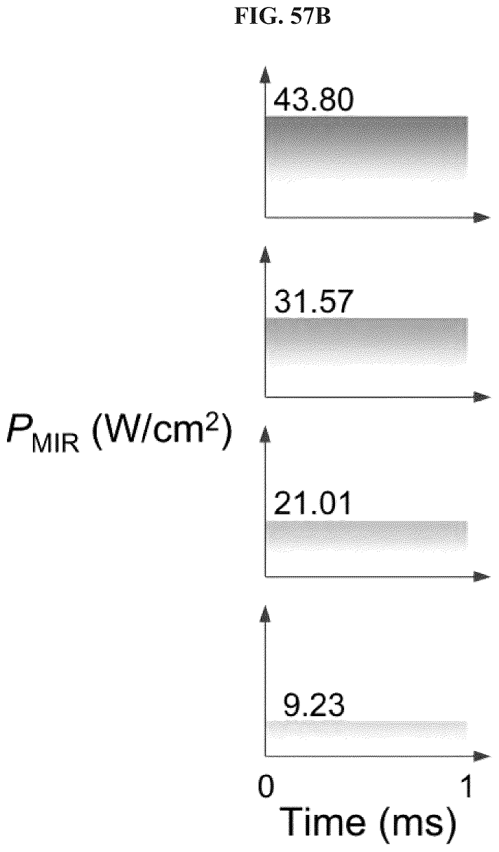

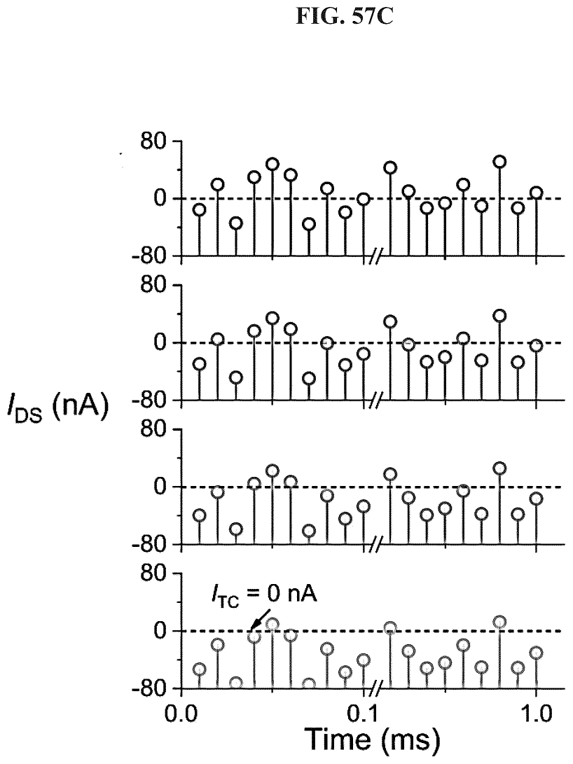

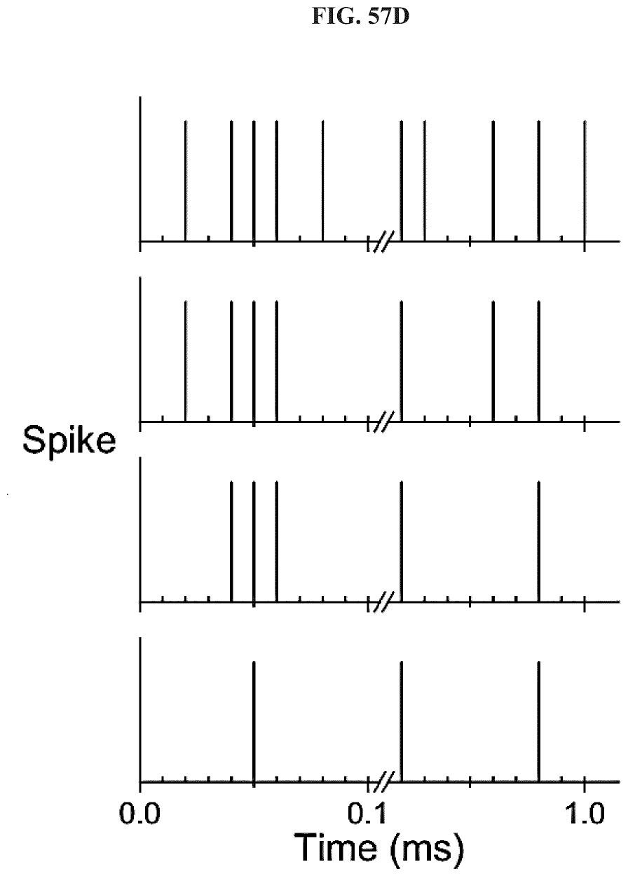

The function of simultaneous perception and spike rate-based encoding for P_{MIR} have also been demonstrated. The NIR laser is applied as sampling pulses with amplitude following a Gaussian distribution with a sampling period (T_{S}) of 10 μs (on/off=5/5 μs), which is analogous to inherent stochasticity. This sampling period is determined by taking into account the NIR response rate. FIG. 57A shows (above) one train of near infrared (NIR) optical pulses (100 time-steps (pulses) for one train) that is randomly sampled from a Gaussian distribution according to various embodiments for spike rate encoding; and (below) the Gaussian distribution of NIR power densities with mean of u=130 mW cm⁻² and a standard deviation of σ=75 mW cm⁻² according to various embodiments.

FIG. 57B shows plots of mid-infrared power density P_{MIR} (in Watts per square centimeter or W/cm²) as a function of time (in milliseconds or ms) illustrating the analog values of various intensities of mid-infrared (MIR) illumination according to various embodiments. When the NIR sampling pulse and MIR light with a specific intensity are simultaneously illuminated on the device (optoelectronic device 1), the response corresponding to each P_{MIR} (FIG. 57B) is recorded by I_{DS}. The P_{MIR} is encoded by one train of NIR optical pulses (100 time-steps for one train) and therefore results in a train of I_{DS} with 100 sampling points. As-recorded I_{DS} trains with I_{TC}=0 nA and corresponding spike trains are shown in FIGS. 57C-D, respectively. FIG. 57C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 57B according to various embodiments. The sampling rate for NIR light is 100 kHz. FIG. 57D shows a plot of spike as a function of time (in milliseconds or ms) illustrating the corresponding spike train for each transduction current (I_{DS}) waveform in FIG. 57C when the spike threshold current (I_{TC}) is set to 0 nA according to various embodiments.

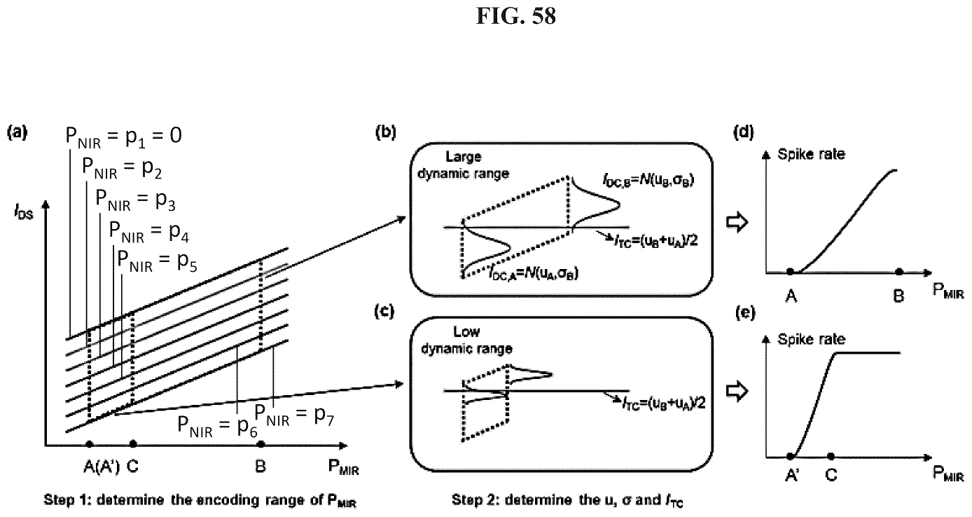

The delineation rule of I_{TC} is discussed in FIG. 58. FIG. 58 is a schematic diagram about how to determine the suitable encoding parameters (mean (u), variance (σ) and spiking threshold current (I_{TC})) to realize high encoding precision. FIG. 58 shows (a) a plot of transduction current I_{DS} as a function of mid-infrared power density P_{MIR} illustrating the variation of I_{DS} with P_{MIR} at various P_{NIR} according to various embodiments; (b) a schematic illustrating determining mean (u), standard deviation (σ) and spiking threshold current (I_{TC}) using a large encoding dynamic range of P_{MIR} according to various embodiments; (c) a schematic illustrating determining mean (u), standard deviation (σ) and spiking threshold current (I_{TC}) using a low encoding dynamic range of P_{MIR} according to various embodiments; (d) a plot of spike rate as a function of mid-infrared power density P_{MIR} illustrating the corresponding encoding transfer curve using parameters in (b) according to various embodiments; and (e) a plot of spike rate as a function of mid-infrared power density P_{MIR} illustrating the corresponding encoding transfer curve using parameters in (c) according to various embodiments. As shown in FIG. 58(a), the used optical power of NIR light (P_{NIR}) ranges from 0 to P₇. The first step is to determine the encoding dynamic range of P_{MIR}. Two encoding dynamic ranges of P_{MIR}, [A, B] and [A′, C], are marked by dashed lines. Two schematics representing using a large dynamic range and a low dynamic range of P_{MIR} are illustrated in FIGS. 58(b) and (c), respectively.

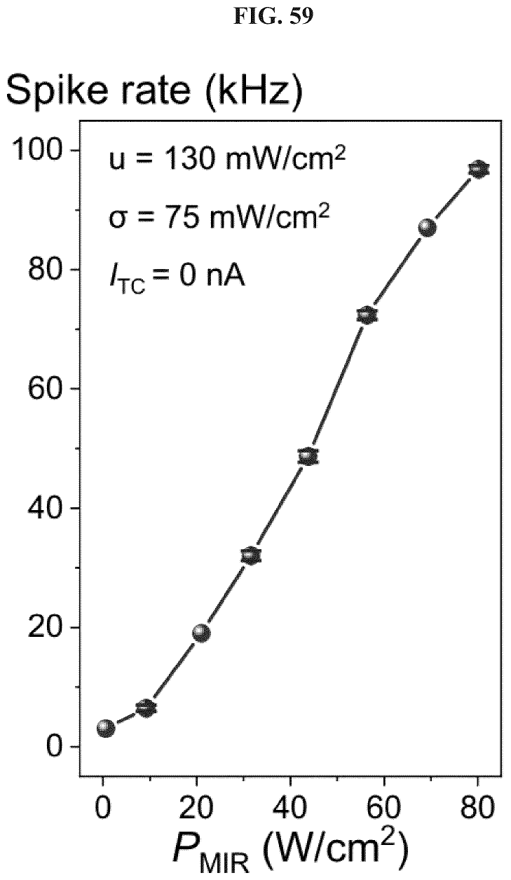

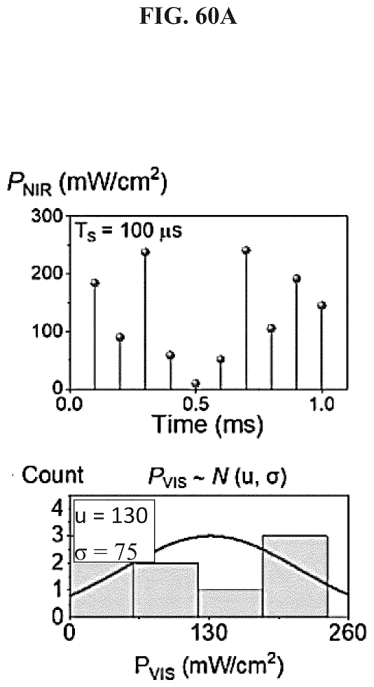

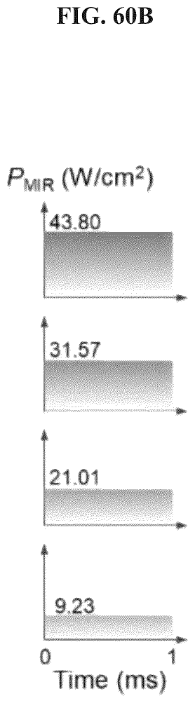

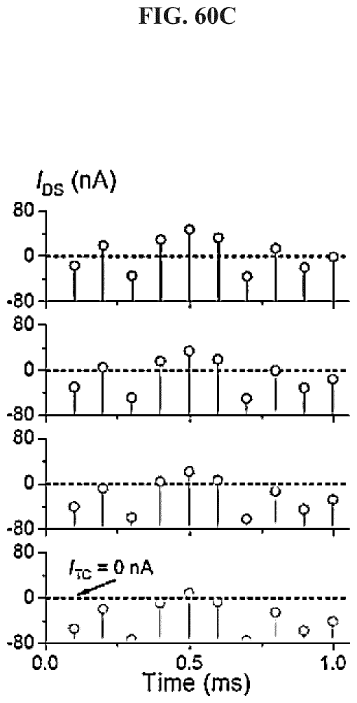

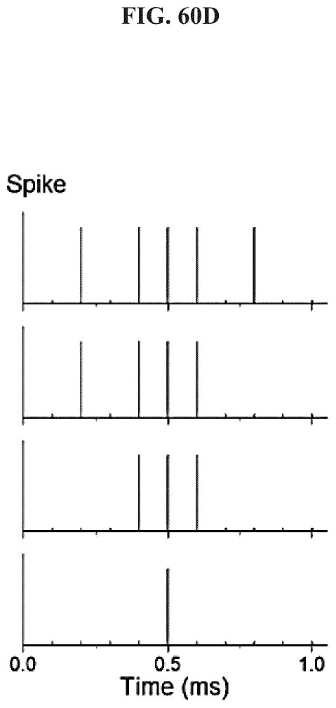

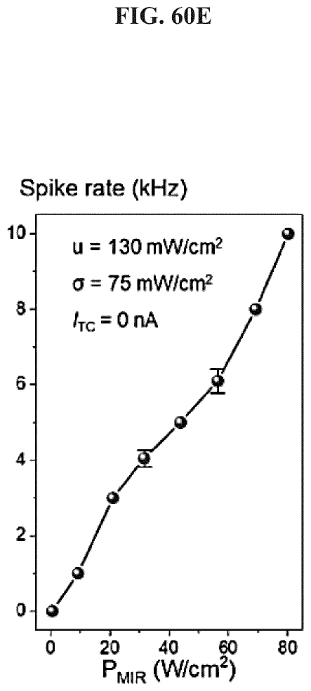

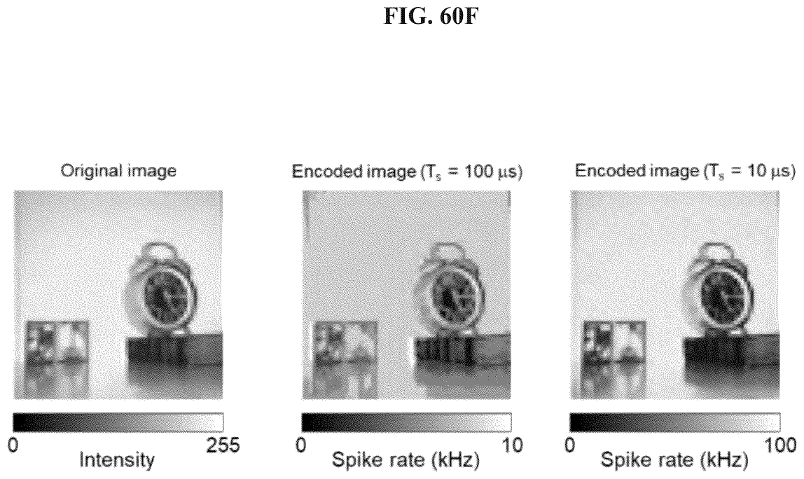

The I_{DS} value higher than I_{TC}=0 nA stimulates one spike. Average spike rate for each P_{MIR} is calculated according to the generated spike train

$$( spike rate = \frac{1}{{T}_{s}} \cdot \frac{n}{Time - steps} ( Hz ) ,$$

where n is the number of spikes in the output spike train), as shown in FIG. 59. FIG. 59 shows a plot of mean spike rate (in kilo-Hertz or kHz) as a function of mid-infrared power density P_{MIR} (in Watts per square centimeter or W/cm²) of the optoelectronic device (optoelectronic device 1) according to various embodiments when mean (u)=130 mW cm⁻², standard deviation (σ)=75 mW cm⁻² and threshold current (I_{TC})=0 nA, respectively. The error bars in FIG. 59 represent the variation (standard deviation) of spike rate. It may be clearly observed that the device is capable of simultaneously perceiving and encoding the P_{MIR} within ~80.21 W/cm². The error in spike rate is about 0.9% due to the fluctuation of I_{DS} waveform. Notably, a fast response speed to NIR light for the device is helpful to increase time-steps over a fixed encoding time which equals the multiplication of time-steps and T_{S}. Insufficient time-steps for one MIR intensity cannot guarantee high encoding accuracy (analyzed in FIGS. 60A-F).

FIGS. 60A-F show the experimental and simulation results when sampling period (T_{S}) for NIR light is 100 μs. FIG. 60A shows (above) a plot of near infrared power density P_{NIR} (in milli-Watts per square centimeter or mW/cm²) as a function of time (in milli-seconds or ms) illustrating one train of near infrared (NIR) optical pulses that is randomly sampled from a Gaussian distribution according to various embodiments for spike rate encoding; and (below) a plot of count as a function of visible power density (in milli-Watts per square centimeter or mW/cm²) illustrating the Gaussian distribution of near infrared NIR power densities with mean of u=130 mW cm⁻² and a standard deviation of σ=75 mW cm⁻² according to various embodiments. The time-steps are 10 given Tₛ=100 μs under a total encoding time of 1 ms. FIG. 60B shows plots of mid-infrared power density P_{MIR} (in Watts per square centimeter or W/cm²) as a function of time (in milliseconds or ms) illustrating the analog values of various intensities of mid-infrared (MIR) illumination according to various embodiments. FIG. 60C shows plots of transduction current I_{DS} (in nano-Amperes or nA) as a function of time (in milliseconds or ms) illustrating the corresponding time-domain transduction current (I_{DS}) waveform output from the source electrode for each mid-infrared (MIR) power density shown in FIG. 60B according to various embodiments. FIG. 60D shows a plot of spike as a function of time (in milliseconds or ms) illustrating the corresponding spike train for each transduction current (I_{DS}) waveform in FIG. 60C when the spike threshold current (I_{TC}) is set to 0 nA according to various embodiments. The I_{DS} higher than I_{TC} could stimulate one spike. FIG. 60E shows a plot of mean spike rate (in kilo-Hertz or kHz) as a function of mid-infrared power density P_{MIR} (in Watts per square centimeter or W/cm²) of the optoelectronic device (optoelectronic device 1) according to various embodiments when mean (u)=130 mW cm⁻², standard deviation (σ)=75 mW cm⁻² and threshold current (I_{TC})=0 nA, respectively. The error bars in FIG. 60E represent the variation (standard deviation) of spike rate. FIG. 60F shows (left) an original clock image (pixel values ranging from 0 to 255 are linearly mapped to mid-infrared MIR optical power density of 0 to 80.21 W/cm²; (middle) an encoded clock image at sampling period Tₛ of 100 μs according to various embodiments (the time-steps for encoding each pixel are 10; the maximal spike rate is 10 KHz; and (right) the encoded clock image at sampling period Tₛ of 10 μs according to various embodiments (the maximal spike rate is 100 KHz).

A testing setup similar to FIG. 24A in Example 1 is also established to demonstrate the adaption ability of the optoelectronic device. Similar to Example 1, a metal mask with nine hollow figures “3” illuminated by MIR laser is used to imitate the real MIR targets. The mask can move along the x and y axis to allow MIR light to pass each target in order. By adjusting the output optical power of MIR laser, the P_{MIR} distribution of each target “3” is different. The real P_{MIR} distribution of nine targets “3” is measured by photocurrent mapping method. The average optical power density P_{MIR} are distributed within 0 to 80.21 W/cm² by adjusting the output optical power of 4.6 μm laser.

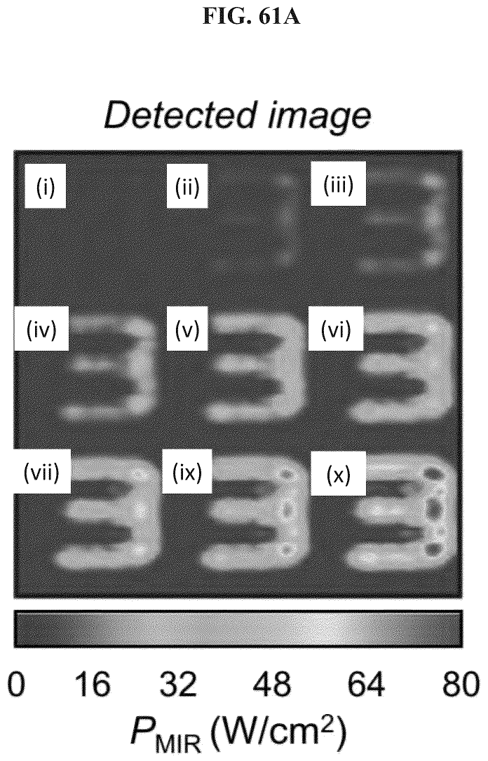

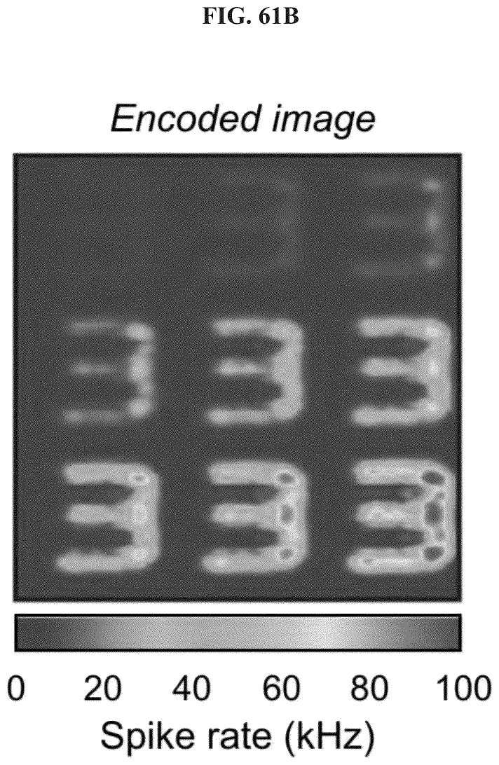

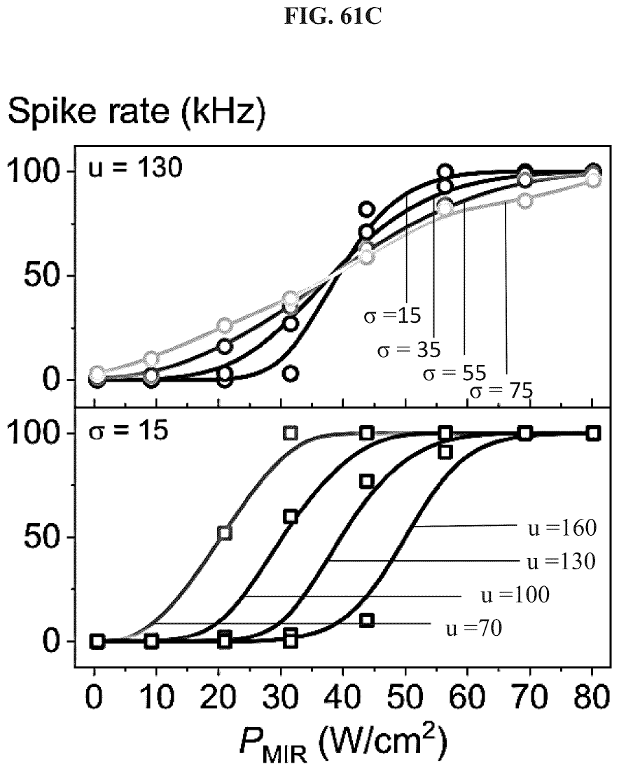

FIG. 61A shows a photocurrent map illustrating the mid-infrared power densities (P_{MIR}) of the nine targets according to various embodiments. For convenience, nine targets ‘3’ are named as (i) to (vii), (ix) and (x) in incremental order of P_{MIR}. To encode the P_{MIR} distribution of targets into corresponding spike trains, another NIR light, whose P_{NIR} is sampled from a Gaussian distribution with mean (u) of 130 mW cm⁻² and standard deviation (σ) of 75 mW cm⁻², is also incident into the optoelectronic device at the same time. The recognized image after rate encoding by the optoelectronic device (optoelectronic device 1) is shown in FIG. 61B. FIG. 61B shows an encoded image after encoding the mid-infrared power densities (P_{MIR}) of the nine targets in FIG. 61A into corresponding spike rates ranging from 0 kHz to 100 kHz according to various embodiments. The correlation coefficient (CC), which refers to the similarity of an encoded targets and a corresponding original one, exceeds 97% for each of the targets, validating that the optoelectronic device has an excellent encoding precision. This may be attributed to the fast response reaching 100 kHz that provides sufficient rate encoding resources for high P_{MIR} resolution.

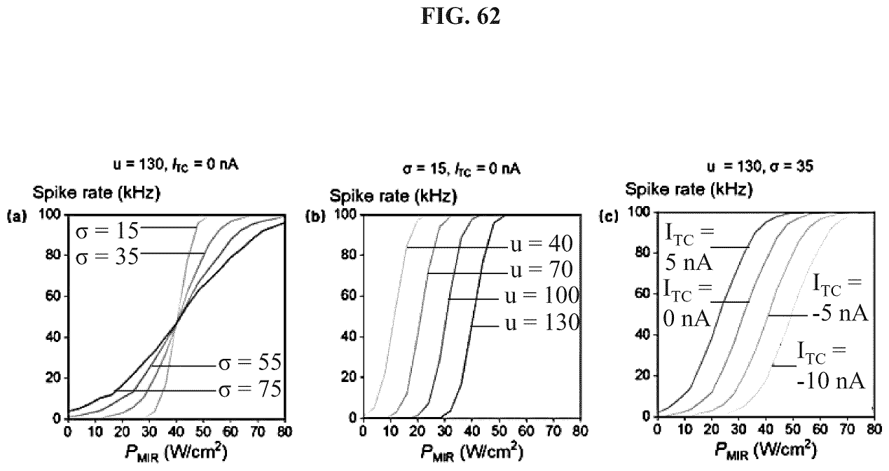

The adjustment of u and σ for sampling the P_{NIR} can conveniently tune the dynamic working range. The increase of σ extends the dynamic working range, while the increase of u shifts the dynamic working range to a high P_{MIR} range. The experimental and simulation results are presented in FIG. 61C and FIG. 62, respectively. FIG. 61C shows plots of spike rate (in kilo-Hertz or kHz) as a function of mid-infrared power density P_{MIR} (in Watts per square centimeters or W/cm²) illustrating experimental results of spike rate P_{MIR} with different means u and standard deviations σ for sampling 730 nm light according to various embodiments.

FIG. 62 shows (a) a plot of spike rate (in kilo-Hertz or kHz) as a function of mid-infrared power density P_{MIR} (in Watts per square centimeter or W/cm²) illustrating variation of spike rate with P_{MIR} for different standard deviations σ of the Gaussian distribution used for sampling 730 nm light according to various embodiments; (b) a plot of spike rate (in kilo-Hertz or kHz) as a function of mid-infrared power density P_{MIR} (in Watts per square centimeter or W/cm²) illustrating variation of spike rate with P_{MIR} for different means u of the Gaussian distribution used for sampling 730 nm light according to various embodiments; and (c) a plot of spike rate (in kilo-Hertz or kHz) as a function of mid-infrared power density P_{MIR} (in Watts per square centimeter or W/cm²) illustrating variation of spike rate with P_{MIR} for different threshold currents I_{TC} according to various embodiments.

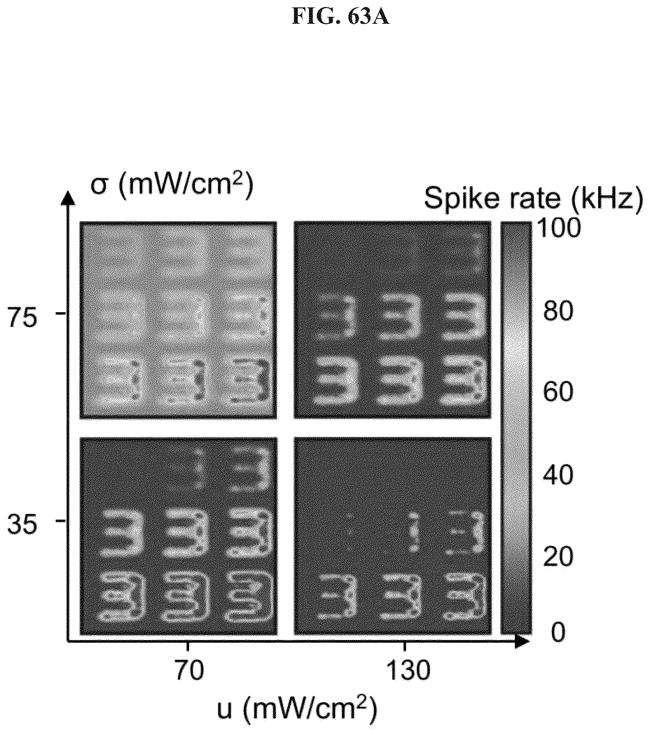

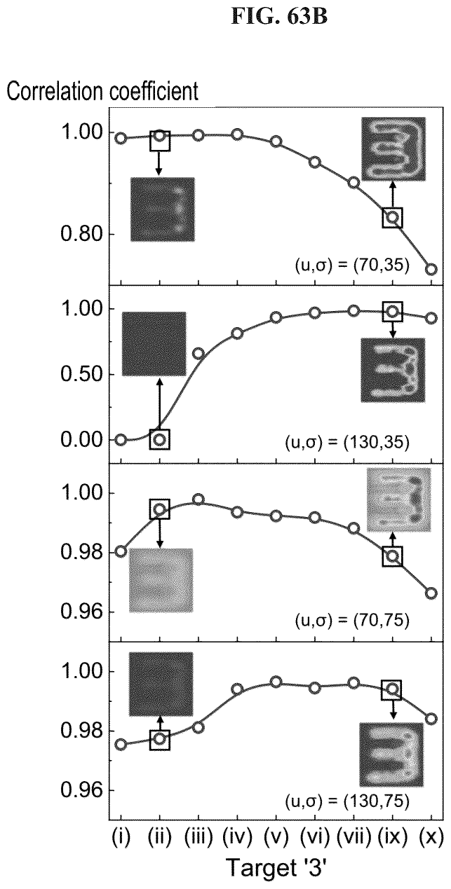

Such dependence can also be observed from the encoded images in FIG. 63A and correlation coefficients (CCs) in FIG. 63B in different cases of (u, σ). FIG. 63A shows plots of standard deviation σ (in milli-Watts per square centimeters or mW/cm²) as a function of mean u (in milli-Watts per square centimeters or mW/cm²) illustrating results of encoding images under different sets of u and σ according to various embodiments. Such parameter adjustment may allow the system to adjust dynamic working range and encoding precision to adapt different MIR targets with varied P_{MIR}. FIG. 63B illustrates the correlation coefficients (CC) between the results in FIG. 63A and the corresponding results in FIG. 61A for different cases of mean u and standard deviation σ according to various embodiments. A higher correlation coefficient indicates higher encoding precision. Four encoding cases with different (u, σ) are highlighted in the insets of FIG. 63B. For example, when the (u, σ) changes from (70, 35) to (130, 35), the dynamic working range shifts to the high P_{MIR} range, which results in the correct encoding of the high-power target (ix) with CC improving from 83% to 98%, but failed encoding of the low-power target (ii) with CC=0. When the σ is increased from 35 to 75 at u=130, the CCs of targets (ii) and (ix) both reach 98% without any encoding failure, which verifies the function of σ used to extend dynamic working range. The u should keep a high power when σ is relatively high (like σ=75 here). Otherwise, the background noise of the encoded image will be magnified due to the no-zero spike rate at P_{MIR}=0, such as the results at (u, σ)=(70, 75), causing an extra interference for identifying targets. To magnify the details of P_{MIR} distribution inside one certain target, a high encoding precision is required and can be achieved by decreasing σ under a suitable u. For example, the target (ii) at (u, σ)=(70, 35) has a higher contrast than the case at (u, σ)=(70, 75). Therefore, optimizing the u and σ values is critical in achieving a suitable dynamic working range and high encoding precision and help exhibit the eye's visual adaption ability to different MIR targets in our device.

An optoelectronic device may also be used to encode the MIR MNIST data set into spike trains, which enables the successful realization of SNN-based digit classification tasks with inference accuracy of more than 96%. Compared to traditional artificial neural network (ANN), SNN is believed to be a more efficient neural network that rarely requires high-precise multiplication. Also, the density of binary spikes required for SNN is much sparser than that for ANN, mitigating the storage memory and energy requirements. The energy-delay product of SNN running on a spike-based neuromorphic hardware has been proved by four-orders magnitude lower than that of the traditional deep neural network (DNN) running on a central processing unit (CPU) over one batch size. The sunTorch platform introduced by Jason K. Eshraghian may be used to establish a fully-connected three-layers SNN that consists of the input layer, hidden layer and output layer with 784, 200 and 10 neurons, respectively, as shown in FIG. 26A under Example 1. As mentioned above, the corresponding digit of the output neuron having the highest spike rate is the predicted result. Each image in the MIR MNIST data set with a size of 28×28 pixels is perceived and encoded by the optoelectronic device into 784 spike trains that concurrently enter into the input layer of a trained SNN. The training and parameters optimization methods for SNN are described below. The 10 spiking neurons in the output layer shown in FIG. 26A represent digits from 0 to 9. The neuron producing the spike train with the highest spike rate corresponds to the digit that SNN predicts.

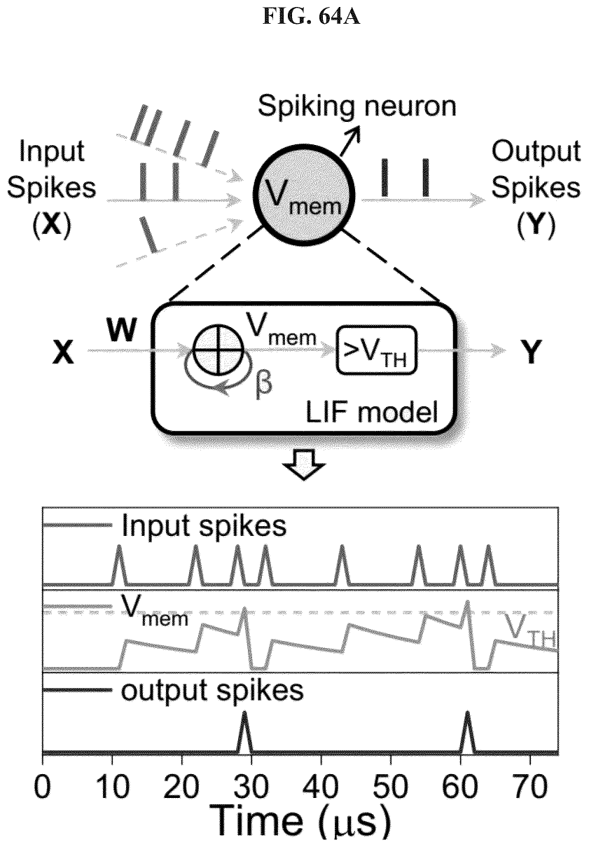

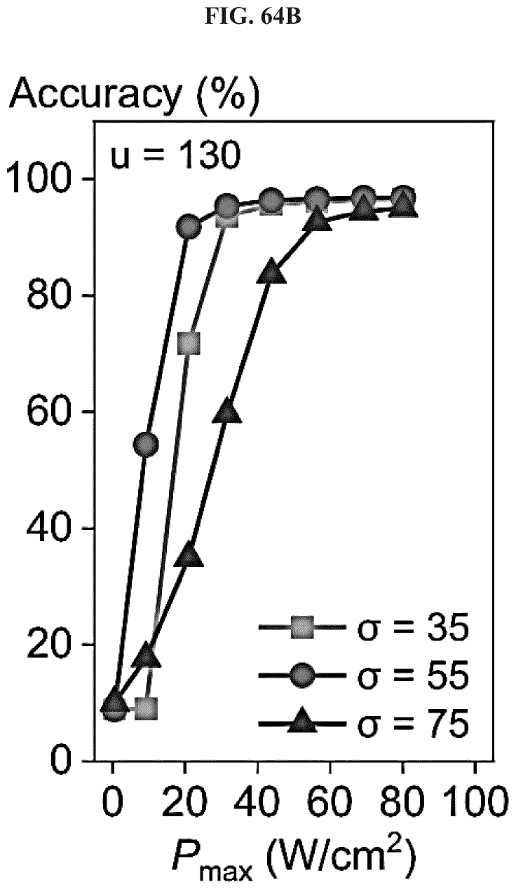

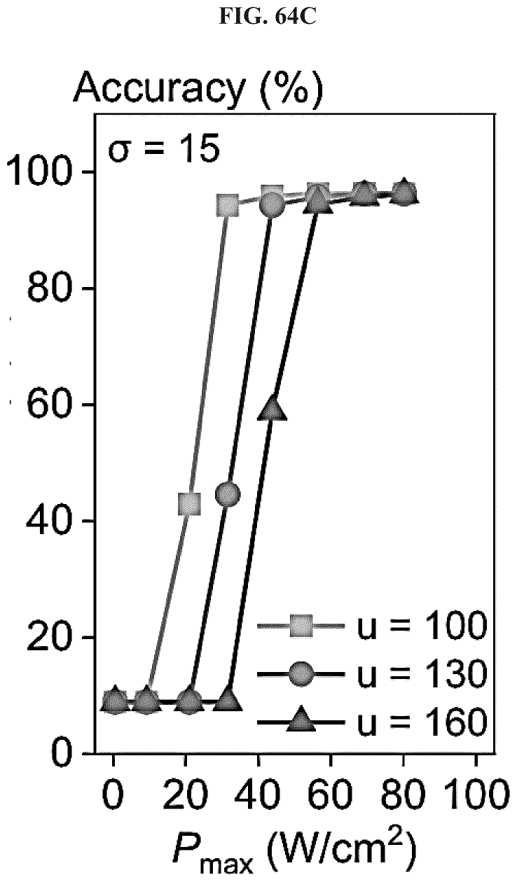

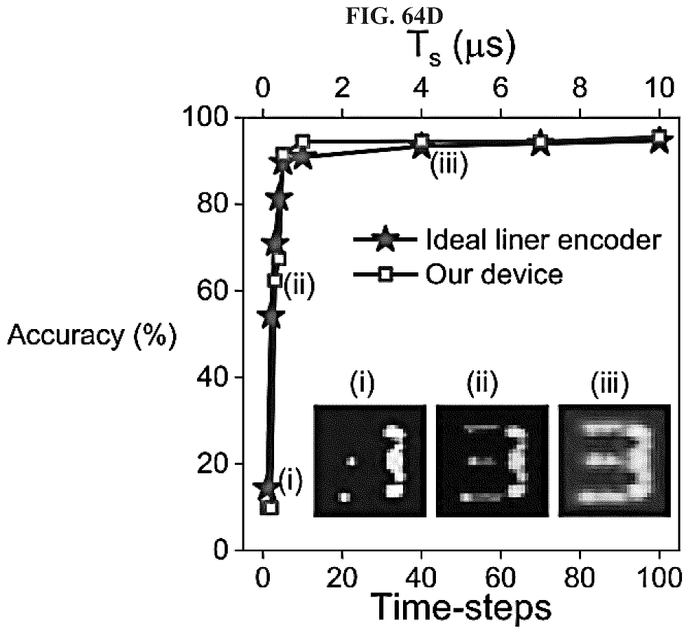

Each spiking neuron in every layer is described by a leaky integrated-and-fire (LIF) neuron model as shown in FIG. 64A. FIG. 64A shows a schematic of the leaky integrated-and-fire (LIF) neuron model used in each node of the spiking neural network (SNN) according to various embodiments. The membrane voltage (Vₘₑₘ) increases with the weighted input spikes (W·X) until it reaches a constant threshold (V_{TH}) at which an output spike appears in the output spike train (Y) and the Vₘₑₘ is reset to zero. During the period without input spike, the Vₘₑₘ decays with the membrane potential decay rate (β) of 0.95.

As also mentioned above, the input pre-neuronal spikes Xᵢ(t) of the ith spiking neuron are modulated by synaptic weights Wᵢ to produce a resultant current

$${\sum }_{i = 1}^{k} {W}_{i}^{T} {X}_{i} ( t ) ,$$

which affects the membrane potential Vₘₑₘ of the post-neuron in the next neuron layer, given as:

$${V}_{mem} ( t + 1 ) = {βV}_{mem} ( t ) + {\sum }_{i = 1}^{k} {W}_{i}^{T} {X}_{i} ( t ) - R [ {βV}_{mem} ( t ) + {\sum }_{i = 1}^{k} {W}_{i}^{T} {X}_{i} ( t ) ] \\ R = \{ \begin{matrix}1 , if {V}_{mem} > {V}_{TH} \\ 0 , otherwise\end{matrix}$$

where β and k are membrane potential decay rate and the number of neurons in this layer, respectively. The Tis the transposition operation. The Vₘₑₘ of the post-neuron will integrate incoming spikes until it reaches membrane threshold V_{TH} where the Vₘₑₘ is reset to zero. Meanwhile, the post-neuron generates an output spike which acts as the input spike of next neuron layer. In the device, I_{TC} may be equivalent to the V_{TH}.

The classification performance of SNN significantly depends on the dynamic working range and encoding precision of the device. As mentioned above, the u and σ values of Gaussian distribution for sampling NIR light control the dynamic working range and encoding precision. If the dynamic working range mismatches the P_{MIR} range of the target within [0, Pₘₐₓ] or the encoding precision is insufficient, the inaccurate translation of the target by encoded spikes will increase the inference error of SNN.

FIG. 64B is a plot of accuracy (in percent or %) as a function of maximum power density Pₘₐₓ (in Watts per square centimeter or W/cm²) illustrating variation of classification accuracy with Pₘₐₓ at various standard deviations σ according to various embodiments. FIG. 64C is a plot of accuracy (in percent or %) as a function of maximum power density Pₘₐₓ (in Watts per square centimeters or W/cm²) illustrating variation of classification accuracy with Pₘₐₓ at various means u according to various embodiments. The u, I_{TC} and time steps in FIG. 64B are 130 mW cm⁻², 0 nA and 100, respectively. The σ, I_{TC} and time steps in FIG. 64C are 15 mW cm⁻², 0 nA and 100, respectively.

FIGS. 64B-C show the classification accuracy of SNN when the Pₘₐₓ of MIR MNIST test set varies from 0 to 80.21 W/cm² at different values of u and σ. A relatively low σ of 35 makes the dynamic working range too narrow to encode the digits with Pₘₐₓ lower than 10 W/cm², resulting in 9.8% classification accuracy. When σ increases to 55, the enlarged dynamic working range can cover both low and high Pₘₐₓ and allows the classification accuracy to become higher than 96%. However, the further increase of σ to 75 decreases the encoding precision. The spike rate resolution is not sufficient to support accurate classification for the low-Pₘₐₓ case. Additionally, the background noise is a little magnified, hampering the inference of SNN. The u value controls the position of the dynamic working range, and it therefore controls the position of high-accuracy working range of SNN. For example, the working range with classification accuracy higher than 96% gradually moves to higher P_{MIR} range when u increases from 100 to 130 with σ=15, shown in FIG. 64C.

The time-steps, representing the number of sampling points for NIR light to encode one MIR intensity, also influences the classification accuracy of SNN. FIG. 64D shows a plot of accuracy (in percent or %) as a function of sampling period Tₛ (in micro-seconds or μs)/time steps illustrating the classification accuracy of the spiking neural network (SNN) according to various embodiments versus the time steps of one spike train when Pₘₐₓ is 21 W cm⁻², with insets (i)-(iii) showing the encoded images of “3” when the time steps are 1, 5 and 10, respectively, σ and u are set to 25 mW/cm² and 70 mW/cm² respectively, with I_{TC} of 0 nA. As shown in FIG. 64D, classification accuracy increases as the increase of time-stops, and reaches 96% at the time-steps of 100 at an optimal (u, σ)=(70, 25) to encode the target with Pₘₐₓ of 21 W/cm². The performance of the device may already be comparable to an ideal encoder. However, insufficient time-steps result in inadequate representation of targets, and therefore significantly decline the classification accuracy. The insets of FIG. 64D highlight the significance of sufficient time-steps for accurate encoding and inference of SNN.

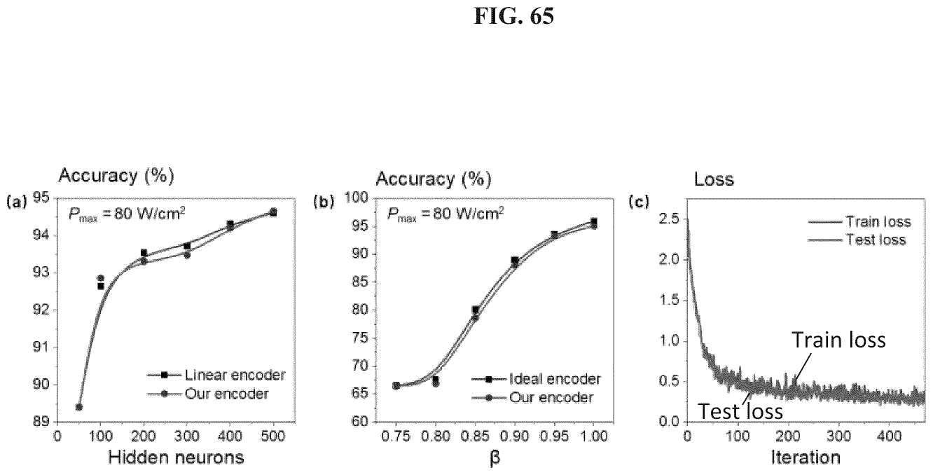

FIG. 65 shows (a) a plot of accuracy (in percent or %) as a function of number of hidden neurons for data set with Pₘₐₓ of 80.21 W/cm² according to various embodiments; (b) a plot of accuracy (in percent or %) as a function of membrane potential decay rate (β) for data set with Pₘₐₓ of 80.21 W/cm² according to various embodiments; and (c) a plot of loss as a function of iteration illustrating the cross-entropy loss of the spiking neural network verses iteration for the train set and the test set according to various embodiments.

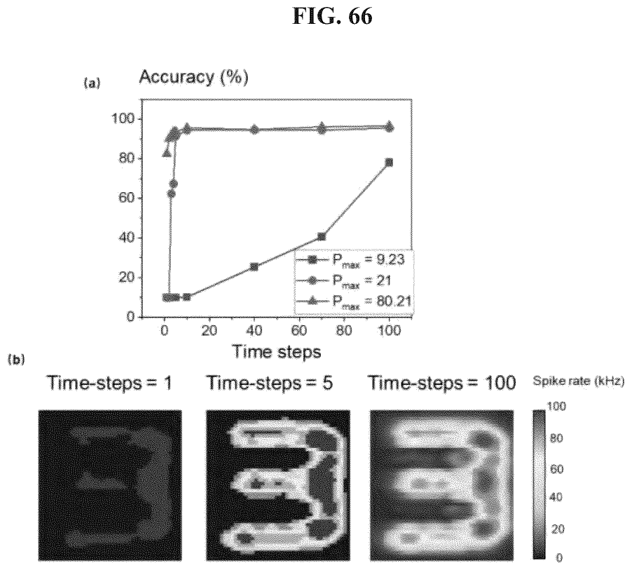

The results of the accuracy vs. time-steps for other Pₘₐₓ are also provided in FIG. 66. FIG. 66 shows (a) a plot of accuracy (in percent or %) as a function of time steps illustrating the interference accuracy of the spiking neural network (SNN) when the optoelectronic device (optoelectronic device 1) according to various embodiments uses different time-steps for encoding mid-infrared (MIR) object with different maximum power densities Pₘₐₓ, and (b) the encoded images of the mid-infrared (MIR) object with Pₘₐₓ=80.21 W/cm² at time-steps of 1, 5, and 100. The results show that MIR objects with lower optical power require more time-steps for accurate encoding and recognition (i.e. to achieve accurate classification) compared to high-power MIR objects. That means high-speed or fast response of the device to NIR light is critical for accurate and fast MIR objects classification under a certain constraint in encoding time.

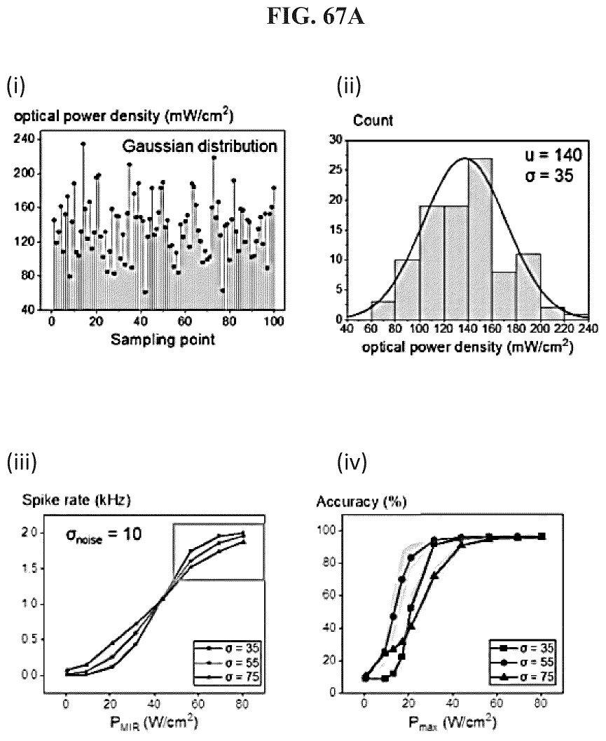

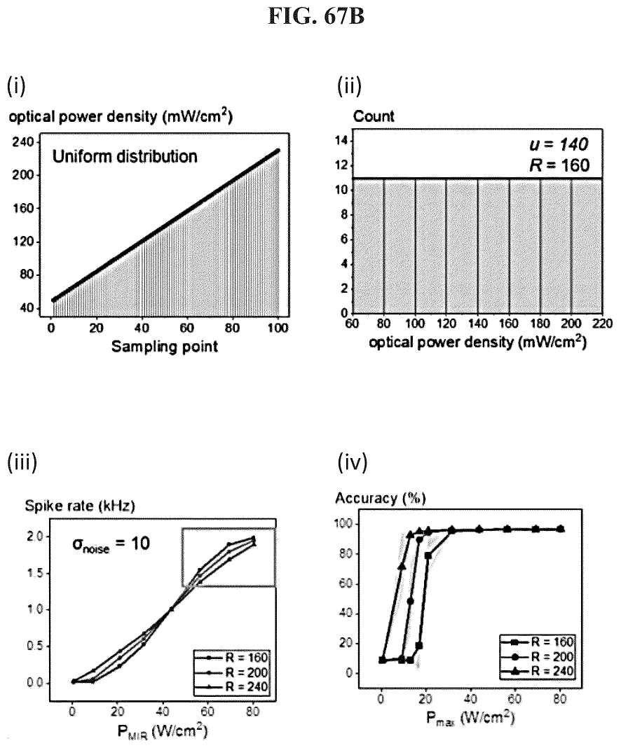

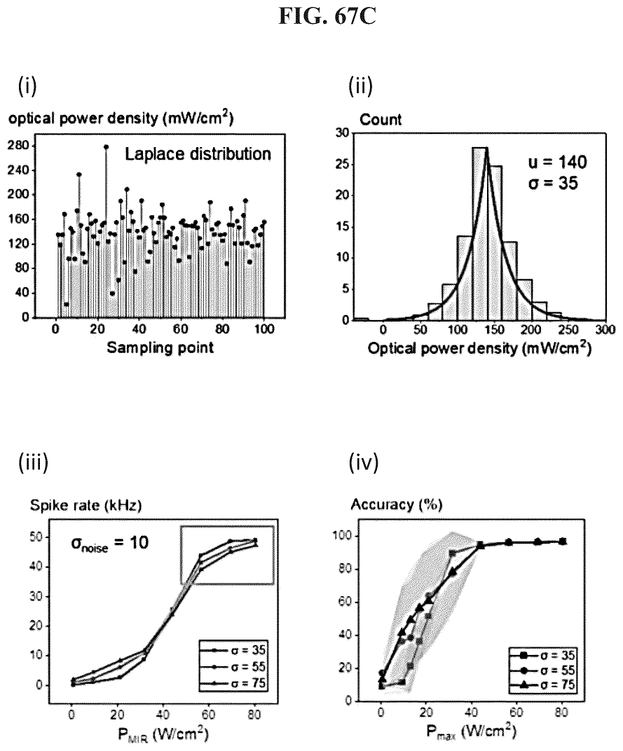

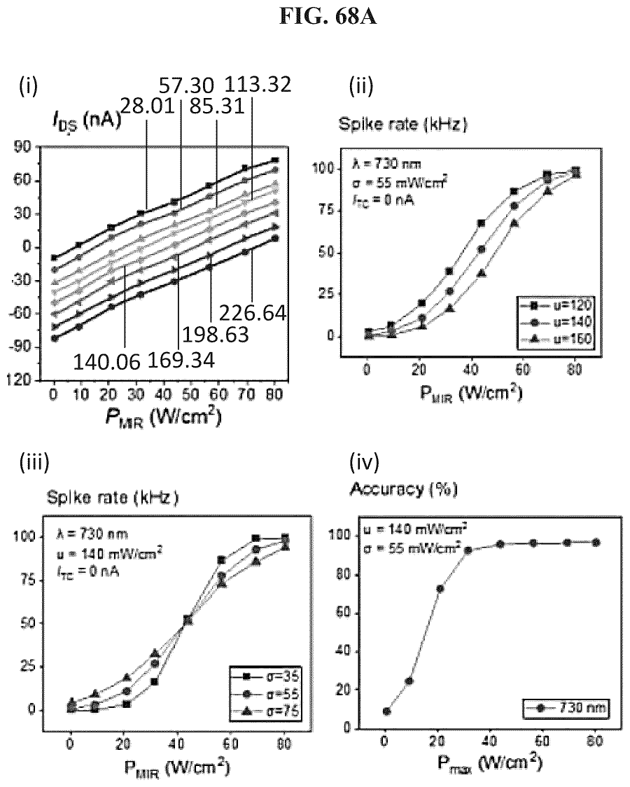

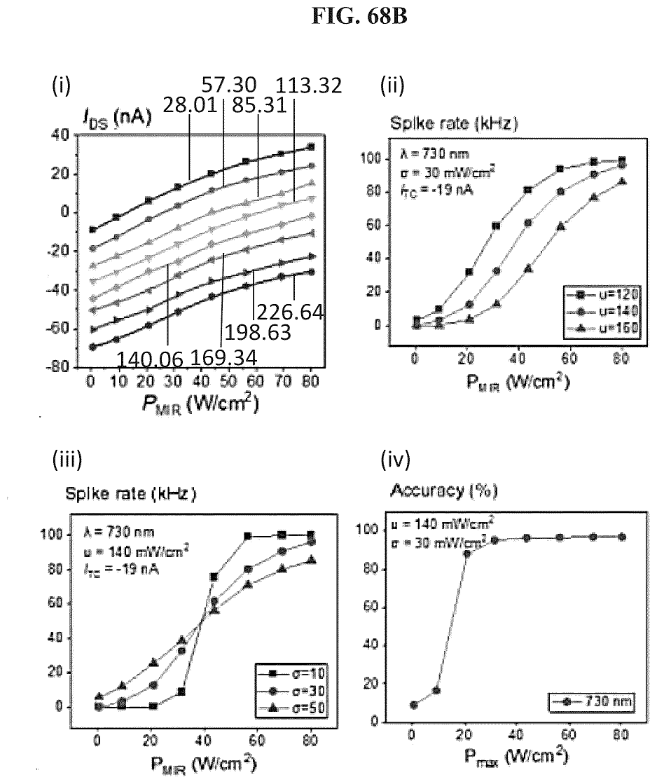

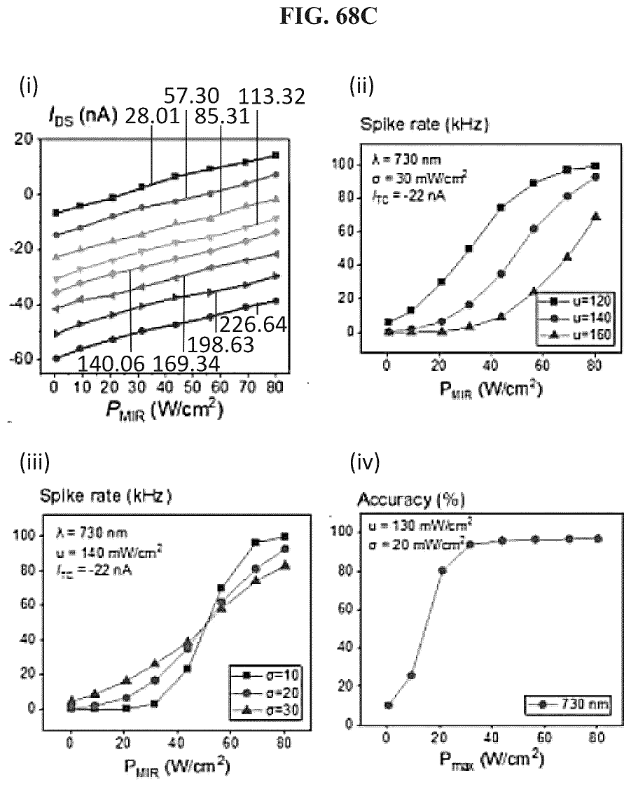

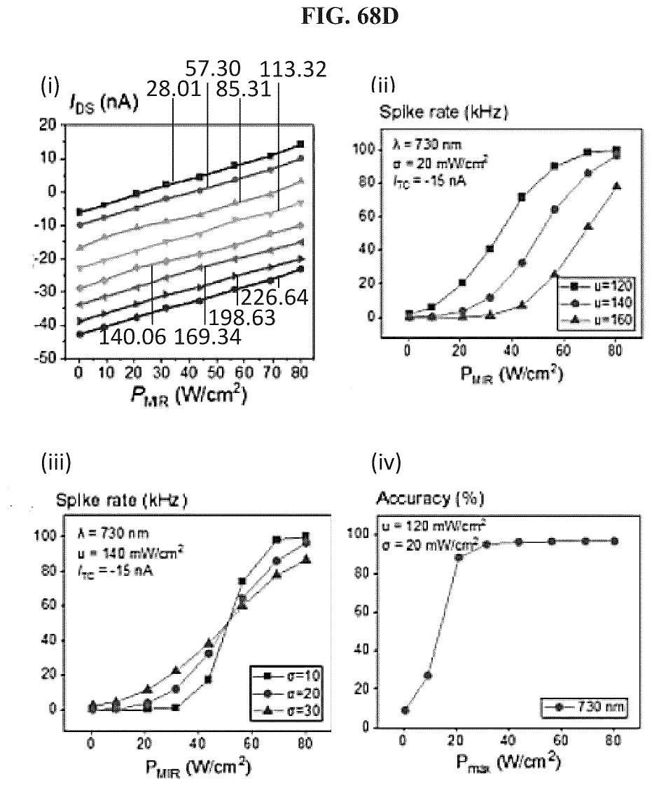

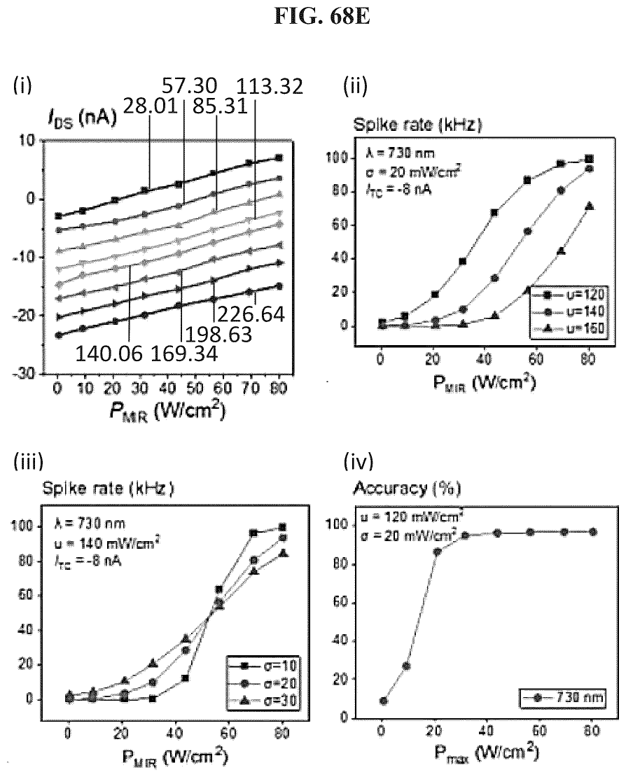

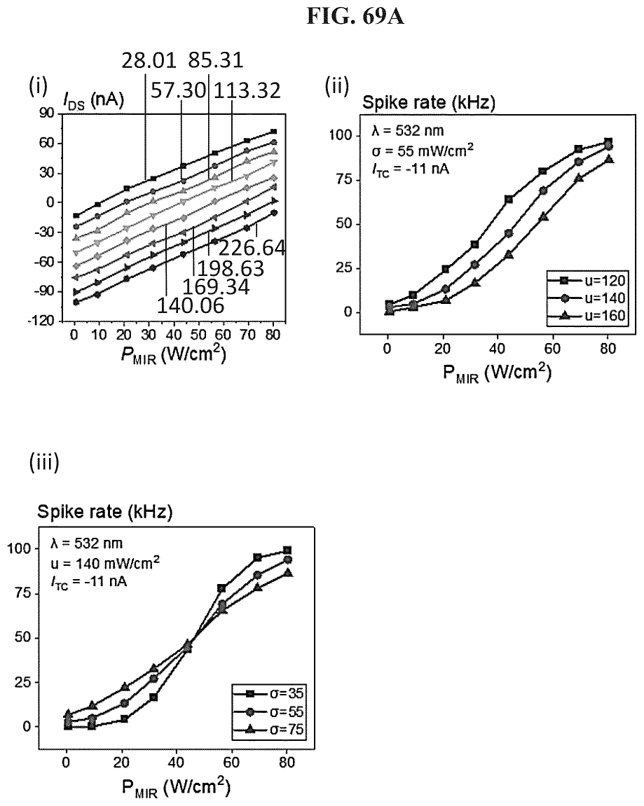

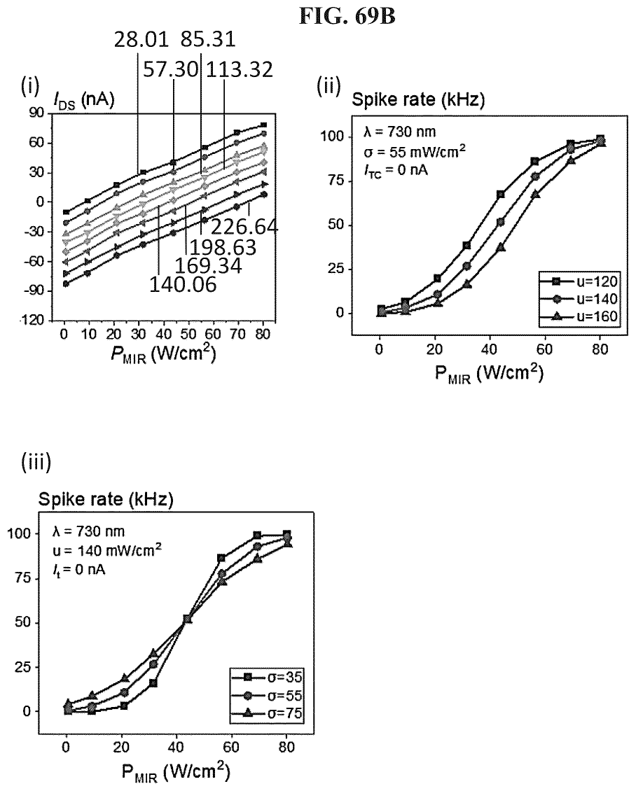

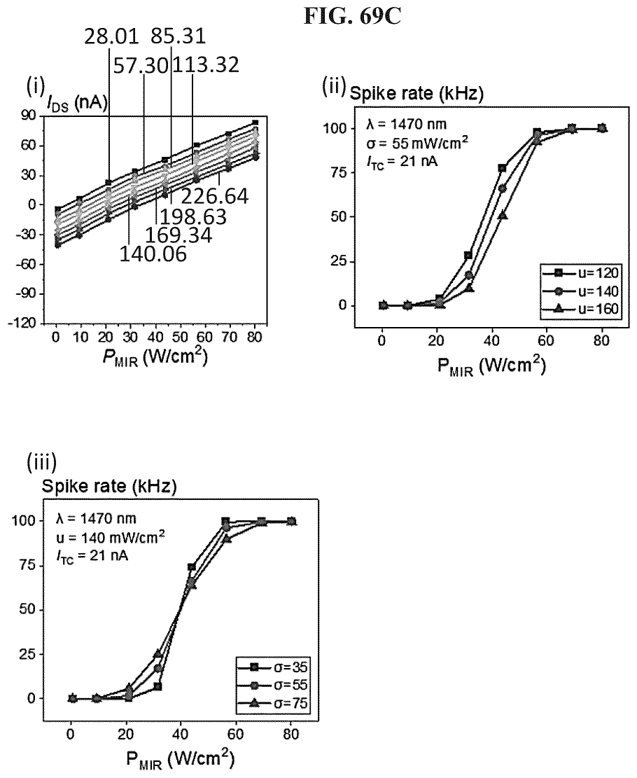

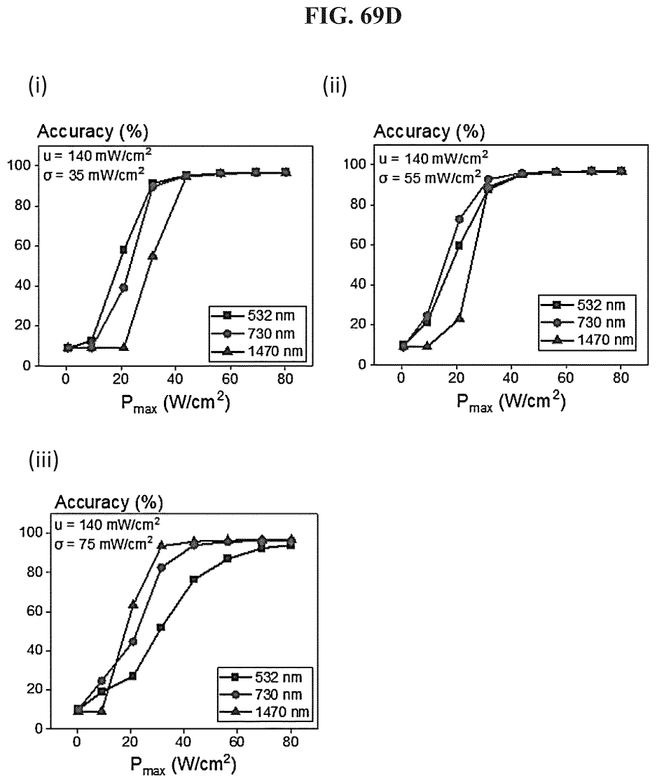

Besides, the impact of device thicknesses, different wavelengths and distribution of the sampled stochastic light on encoding precision and classification accuracy of SNN are also discussed in FIGS. 67A-C, FIGS. 68A-E and FIGS. 69A-D.

FIGS. 67A-C illustrate the impact of different distributions for sampling NIR light on the encoding precision and image recognition accuracy. The Gaussian, uniform and Laplace distributions are shown in FIGS. 67A-C respectively. The white noise with variance (σₙₒᵢₛₑ) of 10 mW/cm² is introduced to the simulation to investigate the noise-tolerance of different distribution. FIG. 67A shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the Gaussian fitting curve (u=140 mW/cm² and σ=35 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments.

FIG. 67B shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the uniform fitting curve (u=140 mW/cm² and optical power density range for sampling NIR light (R) of 160 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments.

FIG. 67C shows (i) a plot of optical power density (in milli-Watts per square centimeter or mW/cm²) as a function of sampling points illustrating the sampling sequence of near-infrared NIR optical power according to various embodiments; (ii) a plot of count as a function of optical power density (in milli-Watts or mW) illustrating the Laplace fitting curve (u=140 mW/cm² and σ=35 mW/cm²) according to various embodiments; (iii) a plot of spike rate (in kilo-Hertz or kHz) as a function of mid-infrared power density P_{MIR} (in Watts per square centimeter or W/cm²) illustrating the encoding transfer curves according to various embodiments; and (iv) a plot of accuracy (in percent or %) as a function of maximum mid-infrared power density Pₘₐₓ (in Watts per square centimeter or W/cm²) illustrating the recognition accuracy of the optoelectronic system according to various embodiments. The recognition accuracy variations (standard deviations) of different distributions are shown as the shaded area in FIG. 67A(iv), FIG. 67B(iv) and FIG. 67C(iv).

FIG. 68A shows (i) a plot of transduction current I_{DS} (in nano-Amperes or nA) as a function of mid-infrared power density P_{MIR} (in Watts per square centimeter or W/cm²) illustrating the photocurrent response of optoelectronic device 1 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 1 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 1 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 1 according to various embodiments towards mid-infrared Modified National Institute of Standards and Technology (MIR MNIST) data sets.

FIG. 68B shows (1) a plot of transduction current I_{DS} (in nano-Amperes or nA) as a function of mid-infrared power density P_{MIR} (in Watts per square centimeter or W/cm²) illustrating the photocurrent response of optoelectronic device 2 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 2 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 2 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 2 according to various embodiments towards mid-infrared Modified National Institute of Standards and Technology (MIR MNIST) data sets.

FIG. 68C shows (i) a plot of transduction current I_{DS} (in nano-Amperes or nA) as a function of mid-infrared power density P_{MIR} (in Watts per square centimeter or W/cm²) illustrating the photocurrent response of optoelectronic device 3 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 3 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 3 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 3 according to various embodiments towards mid-infrared Modified National Institute of Standards and Technology (MIR MNIST) data sets.

FIG. 68D shows (i) a plot of transduction current I_{DS} (in nano-Amperes or nA) as a function of mid-infrared power density P_{MIR} (in Watts per square centimeter or W/cm²) illustrating the photocurrent response of optoelectronic device 4 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 4 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 4 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 4 according to various embodiments towards mid-infrared Modified National Institute of Standards and Technology (MIR MNIST) data sets.

FIG. 68E shows (i) a plot of transduction current I_{DS} (in nano-Amperes or nA) as a function of mid-infrared power density P_{MIR} (in Watts per square centimeter or W/cm²) illustrating the photocurrent response of optoelectronic device 5 according to various embodiments; (ii) a plot of spike rate (in kilo-Hertz or kHz) as a function of mid-infrared power density P_{MIR} (in Watts per square centimeter or W/cm²) illustrating the encoding transfer curves of optoelectronic device 5 according to various embodiments at different means u; (iii) a plot of spike rate (in kilo-Hertz or kHz) as a function of mid-infrared power density P_{MIR} (in Watts per square centimeter or W/cm²) illustrating the encoding transfer curves of optoelectronic device 5 according to various embodiments at different standard deviations σ; and (iv) a plot of accuracy (in percent or %) as a function of mid-infrared power density P_{MIR} (in Watts per square centimeter or W/cm²) illustrating the recognition accuracy of the optoelectronic system including optoelectronic device 5 according to various embodiments towards mid-infrared Modified National Institute of Standards and Technology (MIR MNIST) data sets.

FIG. 69A shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 532 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 532 nm light according to various embodiments; and (iii) a plot of spike rate (in kilo-Hertz or kHz) as a function of mid-infrared power density P_{MIR} (in Watts per square centimeter or W/cm²) illustrating variation of spike rate with PMI under different standard deviations σ of sampling (in milli-Watts or mW/cm²) with 532 nm light according to various embodiments.

FIG. 69B shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 730 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 730 nm light according to various embodiments; and (iii) a plot of spike rate (in kilo-Hertz or kHz) as a function of mid-infrared power density P_{MIR} (in Watts per square centimeter or W/cm²) illustrating variation of spike rate with PMI under different standard deviations σ of sampling (in milli-Watts or mW/cm²) with 730 nm light according to various embodiments.

FIG. 69C shows (i) a transduction current I_{DS} (in nano-Amperes or nA) as a function of mid-infrared power density P_{MIR} (in Watts per square centimeter or W/cm²) illustrating the photocurrent response of the optoelectronic device (optoelectronic device 1) according to various embodiments under different near-infrared power densities of 1470 nm (P₅₃₂) illumination (in milli-Watts or mW/cm²); (ii) a plot of spike rate (in kilo-Hertz or kHz) as a function of mid-infrared power density P_{MIR} (in Watts per square centimeter or W/cm²) illustrating variation of spike rate with P_{MIR} under different means u of sampling (in milli-Watts or mW/cm²) with 1470 nm light according to various embodiments; and (iii) a plot of spike rate (in kilo-Hertz or kHz) as a function of mid-infrared power density P_{MIR} (in Watts per square centimeter or W/cm²) illustrating variation of spike rate with P_{MIR} under different standard deviations σ of sampling (in milli-Watts or mW/cm²) with 1470 nm light according to various embodiments.

FIG. 69D shows (i) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 35 mW/cm²; (ii) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 55 mW/cm²; and (iii) a plot of accuracy (in percent or %) as a function of maximum power density (in Watts per square centimeter or W/cm²) illustrating the recognition accuracy of the optoelectronic device (optoelectronic device 1) according to various embodiments under different wavelengths of near-infrared (NIR) illumination with sampling mean u of 140 mW/cm² and standard deviation σ of 75 mW/cm².

Overall, by optimizing the encoding parameters, the device can ensure the fast the fast and accurate encoding ability on MIR objects, as well as help SNN realize MIR objects classification tasks with the interference accuracy up to 96%.

### Device Fabrication and Characterization

As 2D b-AsP and MoTe₂ flakes are sensitive to the water and oxygen in the surrounding environment, a dry transfer method was applied to fabricate the 2D b-AsP/MoTe₂ vdWs heterostructure. The contact electrodes (5/50 nm Cr/Au) were first patterned on a SiO₂/Si substrate by standard photolithography and electron beam evaporation. The exfoliated 2D b-AsP and MoTe₂ flakes from bulk crystals were then dry transferred onto the electrodes. Finally, h-BN encapsulation was used to protect the device from degradation. The morphology and thickness of as-fabricated device were characterized by optical microscope (Nikon), atomic force microscope (Bruker Dimension Icon). Scanning photocurrent mapping was performed by using confocal micro-Raman spectroscopy (WITec alpha300) equipped with a focused 532 nm laser.

### Detection And Encoding Measurements

The measurements of electrical and photoelectric properties were performed at room temperature and under ambient air conditions. A digital source meter (Keysight, B2912A) was used to apply voltage to the device and record the generated current. A MIR quantum cascade laser (QCL) (Daylight Solution, MIRCat) with tunable wavelength from 3.5 to 11.0 μm was employed as the external stimuli. The power of MIR laser was recorded by a thermal power meter (OPHIR, Nova display-ROHS). A power adjustable 730 nm laser (HÜBNER Photonics, Cobolt 06-MLD) was applied as the stochastic terminal and its power density was measured using a power meter (Thorlabs, PM100D). The laser spots of MIR laser and 730 nm laser are about 100 μm, which is larger than the size scaling of the as-fabricated 2D b-AsP/MoTe₂ vdWs heterostructure. For the encoding measurements, the device is simultaneously illuminated by 4.6 μm MIR laser with a fixed power density and pulsed 730 nm laser with Gaussian distribution power densities. The sampling period (T_{S}) of 730 nm laser is set to 10 μs and its amplitude is determined by the desired encoding algorithm. The fast current sampling was collected by means of an oscilloscope (Keysight, DSOX3054T).

### Photocurrent Mapping Method to Recognize P_{MIR} Distribution Image

To recognize the P_{MIR} distribution image of figure “3” targets in mask, the responding photocurrent of device to every pixel of mask is collected by oscilloscope. The mask has 300× 300 pixels in which each “3” target occupies 100×100 pixels. The P_{MIR} of 4.6 μm laser from QCL on every “3” region (100×100 pixels) is different. When the mask is scanned by pixels, the responding photocurrent of each pixel depends on the optical flux of 4.6 μm laser passing through this pixel region. According to the mapping relation of photocurrent and P_{MIR} given in FIGS. 45A-E, the corresponding P_{MIR} for each pixel can be estimated from the photocurrent obtained by experiment, and finally constitutes the P_{MIR} distribution image shown in FIG. 61A.

### Preparation of MIR MNIST Data Set

The MIR MNIST data set is obtained by mapping pixel values of traditional MNIST data set ranging in [0, 255] to optical power density of 4.6 μm laser ranging in [0, Pₘₐₓ]. Once the Pₘₐₓ is set, every image in the prepared MIR MINST data set with a size of 28×28 pixels is first flattened to obtain 784 analog optical power density of MIR laser. The MIR laser with a certain optical power density can be detected and encoded by the device into spike trains as the input of SNN.

### Training and Parameters Optimization of SNN

For training of SNN, a surrogate gradient descent algorithm is used to update synaptic weights in order to avoid dead neuron problem. The loss function and optimizer used here are cross-entropy loss and Adam optimizer. There are 60,000 and 10,000 MIR MNIST images used for training and test, behavior respectively. The number of hidden neurons and membrane potential decay rate are two super-parameters affecting classification ability of SNN. More hidden neurons and higher β can enhance the classification accuracy (FIG. 65(a)-(b)). The β of real synaptic devices hardly reaches 100%, and therefore the β as described herein is set to 0.95. The number of hidden neurons is set to 200 considering the trade-off between performance and complexity. After training around 450 iterations in one epoch with the batch size of 128, the loss of train and test sets all converge to a steady level, verifying SNN is well trained without under-fitting and over-fitting problems (FIG. 65(c)).

Supplementary Note 1: Electrical Characterizations of the b-AsP/MoTe₂ Heterostructure

The carrier mobility and contact barrier of individual b-AsP and MoTe₂ are evaluated, as shown in FIGS. 30-33. The nearly linear I_{DS}−V_{DS} curves suggest that good contacts are formed between the b-AsP (MoTe₂) and Au electrodes. According to the I_{DS}−V_{DS} curves, both b-AsP and MoTe₂ exhibit p-type conduction behavior, in line with Example 1. As mentioned above in Example 1, the hole-dominated carrier mobilities (u) are calculated using the relation:

$$μ = \frac{{dI}_{DS}}{{dV}_{GS}} \frac{L}{{WV}_{DS} {C}_{ox}}$$

where L and W are the length and width of the channel, respectively, I_{DS}, V_{DS} and V_{GS} refer to the source-drain current, bias voltage and gate voltage, respectively, and Cₒₓ is the dielectric oxide capacitance (13.4 nF cm⁻² for used SiO₂). The as-calculated mobility of the b-AsP and MoTe₂ are reach up to ~145 and ~15 cm² V⁻¹ s⁻¹, which is consistent with previous reports. The contact barriers (Schottky barriers) between b-AsP (MoTe₂) and Au electrodes are extracted by temperature-dependent electrical characteristics. The extraction of Schottky barrier is based on a thermionic model by using Arrhenius plots with the following equation:

$$ln ( \frac{{I}_{DS}}{{T}^{2}} ) = - \frac{{Φ}_{SB}}{kT} + c$$

where I_{DS} is the source-drain current, Tis temperature, Φ_{SB} is the Schottky barrier height, k is the Boltzmann constant and c is a constant. The as-extracted Φ_{SB} for b-AsP/Au and MoTe₂/Au junction are 35 meV and 42 meV under the flat-band condition, respectively. The individual b-AsP, MoTe₂ and b-AsP/MoTe₂ heterostructure devices are fabricated by dry transferring the exfoliated b-AsP and MoTe₂ flakes onto the prefabricated Au electrodes. Therefore, such small Schottky barriers may be attributed to the non-destructive contact form. The good contacts and high carrier mobility enable the b-AsP/MoTe₂ heterostructure to have excellent photoresponse performance. The image and device configuration of an as-fabricated b-AsP/MoTe₂ heterostructure (optoelectronic device 1) in FIG. 34(a)-(b). More b-AsP/MoTe₂ heterostructures (devices 1-5) with various thicknesses are presented in FIGS. 35A-C. All devices are finally encapsulated by insulating h-BN flakes to prevent them from being corroded by water and oxygen in the air. The I_{DS}−V_{DS} curve of the b-AsP/MoTe₂ heterostructure (FIG. 34(c)) shows diode-like rectification characteristics, indicating the existence of built-in electric field in the overlap region. Note that the rectification characteristics induced by metal-semiconductor junction could be neglected due to their small Schottky barrier heights. FIG. 34(d)-(e) depict the band alignments of the b-AsP/MoTe₂ heterostructure before and after contact, in which the energy level positions are obtained from the references. Based on the band alignments, the diode-like rectification characteristics can be easily understood. In equilibrium state (V_{DS}=0 V), the minority electrons in b-AsP would move into MoTe₂, thereby causing a wider depletion layer at MoTe₂ side and creating more holes at b-AsP side. In other words, a built-in electric field with direction pointing to MoTe₂ side is formed at the interface of the b-AsP/MoTe₂ heterostructure. At positive bias (V_{DS}>0 V), the majority holes in MoTe₂ and minority electrons in b-AsP easily cross over the interface barrier, forming a large current. At negative bias (V_{DS}<0 V), the electrons can hardly be injected into MoTe₂ due to the high Schottky barrier for electrons, while the holes in b-AsP could cross the interface barrier due to the small valance band offset (~0.2 eV). Even so, the current at negative bias is lower than that at positive bias.
Supplementary Note 2: Photoresponse Characteristics of the b-AsP/MoTe₂ Heterostructure

The laser spots of MIR (4.6 μm) laser and NIR (730 nm) laser are about 100 μm, which is larger than the size scaling of the as-fabricated 2D b-AsP/MoTe₂, heterostructures. Thus, the entire device can be considered to be uniformly illuminated. As shown in FIG. 36(a)-(b), optoelectronic device 1 shows negative and positive photoresponse under 730 nm and 4.6 μm laser illumination, respectively. The same photoresponse behaviors have been observed in other b-AsP/MoTe₂ devices with various thicknesses (FIGS. 45A-E, FIGS. 46A-E). Moreover, the negative photoresponse behavior also can be observed by using 532 nm and 1470 nm laser illumination (FIGS. 48A-B), and the positive photoresponse behavior also can be observed by applying other MIR lasers with wavelengths ranging from 4.5 μm to 10.5 μm (FIGS. 49A-B, FIGS. 50A-B). For the illumination, the visible/NIR light could be absorbed by both MoTe₂ and b-AsP, while the MIR absorption mainly occurs in b-AsP, because the MIR absorption of MoTe₂ can be ignored due to its large bandgap of ~1.0 eV. In addition, the thermal conductivity of b-AsP (~33 W/mK) and MoTe₂ (~40 W/mK) is less than that of Au electrode (~200 W/mK), and the Seebeck coefficient of b-AsP (~803 μV/K) is higher than that of MoTe₂ (~230 μV/K). In view of these, it may be gathered that the negative photoresponse under visible and NIR illumination is caused by the photovoltaic (PV) effect driven by the built-in electrical filed of b-AsP/MoTe₂ junction, while the positive photoresponse is induced by the photothermoelectric (PTE) effect in b-AsP (in line with conclusions obtained for Example 1). More experiments are performed to support the above points, which are described as follows:

First, the Seebeck coefficient of b-AsP is measured by fabricating a thermoelectric device. As shown in FIGS. 38A-B, by applying a certain voltage to the heater, the heating power is injected into the device, and a temperature gradient (ΔT) across the b-AsP is created.

The local temperature at both ends of b-AsP could be read out by the pre-calibrated thermometer-1 and thermometer-2. Simultaneously, the thermoelectric voltage (ΔV) induced by temperature gradient was measured by thermometer-1/2. The thermoelectric voltage ΔV) is plotted against the temperature gradient (ΔT) with a linear trend, from whose slope we extract the Seebeck coefficient of b-AsP to be S=ΔV/ΔT=723.66 μV/K. In the same way, the Seebeck coefficient of MoTe₂ was measured to be 142.59 μV/K (FIGS. 39A-B). In addition, the photo-Seebeck coefficient of b-AsP is evaluated by combing temperature-dependent and power-dependent Raman spectra as well as local illumination induced photo-voltage measurements. As shown in FIGS. 40A-B, 41A-B, the photo-Seebeck coefficient of b-AsP was evaluated to be 703.64 μV/K, which is close to the value measured by thermoelectric device.

The Schottky barrier heights of b-AsP/Au and MoTe₂/Au contacts via temperature-dependent electrical characteristics, which are extracted to be 35 meV and 42 meV, respectively. Although there are asymmetric Schottky barriers between b-AsP/Au and MoTe₂/Au, such small barrier heights and barrier differences are difficult to contribute significant photocurrent.

Thirdly, scanning photocurrent mapping is carried out to distinguish the photocurrent generation locations by using a focused 532 nm laser with a laser spot of ~1 μm, as shown in FIGS. 37A-B. It can be observed that the photocurrents mainly originated from the junction region and b-AsP on the Au electrode, while there is no obvious photocurrent in the MoTe₂/Au region even though its contact barrier is higher than that of b-AsP/Au. Therefore, the Schottky photovoltaic effect may be negligible in the device. The photocurrent generated in the b-AsP/MoTe₂ junction region should be contributed to the photovoltaic effect. When the laser is illuminated on the b-AsP/MoTe₂ junction region, electron-hole pairs are generated in both b-AsP and MoTe₂. Then, the photo-generated electrons and holes are driven to b-AsP (source electrode) and MoTe₂ (drain electrode) under the built-in field, respectively, thus resulting in negative photocurrent. As for the photocurrent in the b-AsP/Au junction, it may be caused by photothermoelectric effect of As-P. As mentioned above, b-AsP possesses a high Seebeck coefficient, which enables a significant temperature gradient from the b-AsP/Au to b-AsP/MoTe₂ when the laser locally illuminated on the b-AsP/Au junction. Thus, the hot holes could transfer from b-AsP/Au side to b-AsP/MoTe₂ side, resulting in a negative photocurrent. Note that the near-zero photocurrent in the b-AsP/MoTe₂ junction region may be due to the cancellation of the positive and negative photocurrents caused by PTE and PV respectively in the junction. The schematic diagram of the photocurrent generation in the b-AsP/MoTe₂ device under local illumination is described in FIG. 37B.

Based on the above results, the schematic diagram of the photocurrent generation in the b-AsP/MoTe₂ device under visible/NIR and MIR global illumination are depicted in FIG. 36(c)-(d), respectively. Under visible or NIR laser global illumination, both b-AsP and MoTe₂ layers generate electron-hole pairs which are separated by the built-in electrical field with direction pointing from b-AsP to MoTe₂ side at the junction. The photo-generated electrons and holes move toward b-AsP and MoTe₂, respectively, which contributes to the negative photovoltaic photocurrent. Under MIR laser global illumination, an unbalanced lattice temperature distribution is generated in b-AsP layer due to the asymmetric contacts of b-AsP with MoTe₂ and Au electrode. The lattice temperature of b-AsP at the MoTe₂ conduct side is higher than that at Au electrode contact side because the Seebeck coefficient of b-AsP is higher than that of MoTe₂ and the thermal conductivity of MoTe₂ is lower than that of Au. Such lattice temperature distribution promotes the diffusion of holes in the b-AsP from the MoTe₂ contact side to Au electrode contact side, thus forming a positive PTE photocurrent under zero bias with b-AsP as the source terminal. In addition, the photocurrent generation mechanism of the as-fabricated b-AsP/MoTe₂ devices may not be dependent on the thickness and overlap area, because similar photoresponse characteristics are observed in devices with different thicknesses and overlap area (FIGS. 37A-B, FIGS. 45A-E, FIGS. 46A-E).

Supplementary Note 3: Photodetection Performance of the b-AsP/MoTe₂ Heterostructures

Photoresponse rate is a key figure of merit of photodetectors. FIGS. 43A-B present the photoswitching behavior and response rate of the b-AsP/MoTe₂ heterostructure under 730 nm and 4.6 μm illumination at V_{DS}=0 V, respectively. There is no obvious declination of the photoresponse amplitude as the NIR pulse frequency increases from 2.5 kHz to 25 kHz and MIR pulse frequency increases from 2 to 3 kHz, indicating the potential of high-speed operation. The NIR and MIR photoresponse rate of the heterostructure are as fast as 600 ns/3.7 us and 2.3 μs/20 μs, respectively, which are faster than most PV and PTE photodetectors. In addition, as mentioned in Example 1, two other important figure of merits, namely responsivity (R) and detectivity (*), are also calculated by the following equations:

$$R = \frac{{I}_{p h}}{P \times A} \\ {D}^{*} = \frac{{( AB )}^{0.5}}{NEP}$$

where Iₚₕ, P, A, B and NEP refer to photocurrent, incident power density, the effective device area, measuring bandwidth and noise equivalent power, respectively. The effective device areas of the five devices are listed in FIG. 47. Note that the visible/NIR photoresponse is mainly contributed by the b-AsP/MoTe₂ junction areas, while the MIR photoresponse mainly come from b-AsP. So, the junction areas and b-AsP areas are used to calculate the visible/NIR and MIR performance, respectively. The NEP can be obtained following NEP=i_{N}/R, where in is noise current density. The noise spectral densities of the as-fabricated five devices are displayed in FIG. 44, which are all measured at V_{DS}=0 V. Based on this, the NEP, R and D* of the five devices under 730 nm and 4.6 μm illumination with various power densities are accordingly calculated, which are shown in FIGS. 45A-E, FIGS. 46A-E, respectively. FIG. 47 presents the comparison of photoresponse performance of the five b-AsP/MoTe₂ devices with various thicknesses. As can be seen that the responsivity and detectivity show a decreasing trend with thinning thickness, which may be attributed to the weaker optical absorption of thinner device. For 4.6 μm, a competitive responsivity of 1.13 mA/W with a high detectivity of 9.6×10⁸ cm·Hz^{0.5}/W is obtained in b-AsP/MoTe₂ (device 1) with thickness of 40/50 nm under the power density of 80.21 W/cm². In terms of 730 nm, the values of R and D* are about 0.88 A/W and 4.1×10¹¹ cm Hz^{0.5}/W at the power density of 226.64 mW/cm², respectively. These figures of merits are competitive in both MIR and NIR photodetectors based on 2D van der Waals heterostructures.

Furthermore, the photoresponse performance of the b-AsP/MoTe₂ heterostructure (device 1) under 532 nm and 1470 nm laser illumination are evaluated, as shown in FIGS. 48A-B. Moreover, the device demonstrates broadband MIR photodetection capability up to 10.5 μm at V_{DS}=0 V, as shown in FIGS. 49A-B, FIGS. 50A-B. The responsivity and detectivity of the heterostructure monotonously decrease from 1.7 to 0.5 mA/W and 1.1×10⁹ to 3.1×10⁸ cm·Hz^{0.5}/W as the wavelength increases from 4.5 to 10.5 μm, respectively, which is attributed the decreasing MIR absorption of b-AsP at the longer wavelength.

In addition, the b-AsP/MoTe₂ heterostructure (device 1) demonstrates stable and repeatable photoresponse under simultaneous MIR and NIR illumination, as shown in FIGS. 52A-I. Note that the simultaneous illumination is carried out by using continuous 4.6 μm laser and pulsed 730 nm laser. It can be observed that the device maintains fast and stable photoresponse under pulsed 730 nm illumination at a frequency of 20 kHz, which is attributed to the fast NIR photoresponse rate. Moreover, the stable photoresponse can be still maintained under 730 nm laser illumination with a frequency of 100 kHz (FIG. 54). Such a fast and stable response makes it possible to generate higher spiking rates and provides a guarantee for high-precision MIR intensity coding.

### Supplementary Note 4: Rule for Determining the Encoding Parameters for High Precise Encoding

FIG. 58 shows the schematic diagram about how to determine the suitable encoding parameters (mean (u), variance (σ) and spiking threshold current (I_{TC})) to realize high encoding precision. If the linear region of encoding transfer curve is shifted to the middle of the MIR power range of interest, the corresponding parameters can be regarded to be optimal. The rules of setting the encoding parameters are given as follows:

First, the photocurrent (I_{DS}) as a function of P_{MIR} and P_{NIR} is obtained (FIG. 58(a)). The largest P_{MIR} range of interest to encode is determined. Two examples are provided: a relatively large dynamic range [A, B] and a relatively low dynamic range [A′, C]. Their corresponding ranges of I_{DS} when adding NIR light with P_{NIR} ranging from 0 to p₇. The mean u and standard deviation σ of the Gaussian distribution for sampling the NIR light is determined. In real operation, the available NIR power range is exploited to decrease the demand on the fineness of NIR laser for tuning its optical power. The mean u is set to p₇₂ to allow the distribution of I_{DS,B} and I_{DS,A} to occupy whole available I_{DS} range, depicted in FIG. 58(b). The distributions of I_{DS,B}=N(u_{B}, σ_{B}) and I_{DS,A}=N(u_{A}, σ_{B}). To make the linear region of encoding transfer curve in the middle of the dynamic range, the value of I_{TC} is set to (u_{B}+u_{A})/2, which is roughly estimated as

$${I}_{TC} = ( \frac{{I}_{DS} ( B , {p}_{1} ) - {I}_{DS} ( B , {p}_{7} )}{2} + \frac{{I}_{DS} ( A , {p}_{1} ) + {I}_{DS} ( A , {p}_{7} )}{2} ) / 2$$

that is convenient to directly extract from the I_{DS} curve. For a relatively low P_{NIR} range, the high precise encoding can be realized by properly decreasing u and σ at a fixed I_{TC}. The final encoding transfer curve is given in FIG. 58(d)-(e).

### Supplementary Note 5; Analytical Results of the Device and Spiking Neural Network

Response speed to NIR light in our device is a critical metric that determines how fast the device can encode input MIR signal, and how many time-steps in one trail of NIR optical pulses that the devices can afford within a fixed encoding time. The rising time of the device to NIR light is 600 ns, and the falling time is 3.7 μs. The fast response speed allows the sampling period (T_{S}) to be reduced to 10 μs. For comparison, the encoding performance of the device at T_{S}=100 μs is presented in FIGS. 60A-F. The time-steps are 10 if the encoding time is fixed to 1 ms. The inadequate time-steps hinders correct representation of MIR power, reflected as irregular nonlinearity in the encoding transfer curve and serious error of spike rate in FIG. 60F. Simulation is carried out to encode the intensity of a clock image using time-steps of 10 and 100, respectively. The results indicate that more time-steps due to high response speed of the device may enable highly-precise encoding.

A current response model of the device to P_{MIR} and P_{NIR} can be fitted by measured data. By this model, simulation results of spike rate as a function of P_{MIR} is given in FIG. 62. It is observed that a higher σ can extend to cover P_{MIR} range from 0 to 80.21 W/cm². The location of dynamic working range moves with u and I_{TC}.

As shown in FIG. 65(a)-(b), more hidden neurons improve the classification ability of SNN traded from the structure complexity. Membrane potential decay rate (β) means the ability of the synaptic neuron memorizing the former information. When β reaches 100%, the accuracy exceeds 95% thanks to ideal memory of neurons, but a real synaptic device hardly has β of 100% without any memorized voltage decay, so the β is set to 95%. The u, σ, I_{TC} and sampling points for two figures are 130 mW/cm², 55 mW/cm², 0 nA and 50. FIG. 65(c) verifies that training parameters and iteration numbers of SNN is sufficient for loss convergence without underfitting problem. Additionally, the loss convergence of test set proves the SNN has no over-fitting problem.

The impact of other distributions for sampling NIR light on encoding precision and recognition accuracy of SNN are investigated in FIGS. 68A-C. To imitate the stochasticity and help device to have a good noise-tolerance, the NIR light is sampled with the Gaussian distribution to match the distribution of the noise in opto-electric receivers. Most kinds of noises in opto-electric receivers, such as shot noise and thermal noise, are white noises following the normal Gaussian distribution. That is also why other Gaussian distributions like sub-Gaussian and super-Gaussian distributions may not be considered. In addition, sub-Gaussian and super-Gaussian distributions have an uncertain super-parameter: fourth-order moment, which needs extra discussion that will increase the complexity and uncertainty of the encoding algorithm. Regarding to other distributions, only the distributions with adjustable mean and variance are considered here. The distributions without the two parameters such as Poisson's distribution may not endow the device with the eye's visual adaptivity to different light intensity. Here, three different distributions, e.g. Gaussian distribution, uniform distribution and Laplace distribution are discussed. Their sampling sequence, distribution curve and the encoding transfer curve under additive white noise with variance of 10 mW/cm² are compared in FIGS. 67A-C. It is found that all distributions can realize encoding functions, but the Gaussian distribution has the highest noise-tolerance with the smallest error in spike rate under the same additive white noise.

Regarding to the recognition accuracy, the results are shown in FIG. 67A(iv), FIG. 67B(iv) and FIG. 67C(iv). When the encoding parameters (u, σ, R) are optimized, the three distributions have the similar highest recognition accuracy up to 96.7% for high-Pₘₐₓ objects. However, the uniform distribution has the highest recognition accuracy for the objects with Pₘₐₓ lower than 20 W/cm² followed by Gaussian distribution and Laplace distribution. This is because the SNN is trained by ideal linear encoding. The linearity of encoding transfer curve using uniform distribution is better than that of other two distributions, and therefore the uniform distribution may match better to the trained SNN even its encoding precision may be lower than Gaussian distribution. Nevertheless, it may be noted that the uniform distribution could pose a challenge on the resolution of output optical power for the NIR laser if time steps increase. Considering the resolution of the output optical power for the laser is only 0.1 mW that limits the use of uniform distribution in a relatively low encoding range, the Gaussian distribution may be chosen to demonstrate the concept and the functionality of the optoelectronic system despite a little performance sacrifice on the digit recognition task.

The impact of different devices thicknesses and the different wavelengths of stochastic light sources are investigated in FIGS. 68A-E, FIGS. 69A-D. The results reveal that the devices at different thicknesses and different wavelengths of stochastic light source can possess similar encoding and recognition accuracy if encoding parameters including u, σ and I_{TC} are optimized.

1. An optoelectronic system comprising:
an optoelectronic device for receiving a first electromagnetic wave of a first wavelength and a second electromagnetic wave of a second wavelength, the optoelectronic device comprising:
a substrate;
a first contact electrode over the substrate;
a second contact electrode over the substrate;
a first two-dimensional van der Waal material layer in contact with the first contact electrode; and
a second two-dimensional van der Waal material layer in contact with the second contact electrode, the second two-dimensional van der Waal material layer also forming a heterojunction with the first two-dimensional van der Waal material layer; and
a neural network for identifying or determining an object providing or transmitting the first electromagnetic wave;
wherein the neural network is coupled to the optoelectronic device.

2. The optoelectronic system according to claim 1,
wherein the first two-dimensional van der Waal material layer comprises black phosphorus-arsenic (b-AsP), black phosphorous (BP), palladium selenide (PdSe₂) or tellurium (Te); and
wherein the second two-dimensional van der Waal material layer comprises molybdenum (IV) telluride (MoTe₂).

3. The optoelectronic system according to claim 1,
wherein the first electromagnetic wave is mid infrared (MIR) radiation; and
wherein the second electromagnetic wave is near infrared (NIR) radiation.

4. The optoelectronic system according to claim 1,
wherein the optoelectronic device is configured such that the first electromagnetic wave provided to the optoelectronic device generates a first photoexcited current flowing in a first direction when the first contact electrode and the second electrode are at zero voltage bias; and
wherein the optoelectronic device is configured such that the second electromagnetic wave provided to the optoelectronic device generates a second photoexcited current flowing in a second direction opposite the first direction when the first contact electrode and the second electrode are at zero voltage bias.

5. The optoelectronic system according to claim 4,
wherein the first photoexcited current flowing in the first direction is generated via a photothermoelectric (PTE) effect; and
wherein the second photoexcited current flowing in the second direction is generated via a photovoltaic (PV) effect.

6. The optoelectronic system according to claim 1,
wherein the optoelectronic device is configured to generate a spike train based on a portion of a time-domain transduction current (I_{DS}) waveform output above a threshold current (I_{TC}); and
wherein the time-domain transduction current (I_{DS}) waveform output is generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

7. The optoelectronic system according to claim 6,
wherein a power of the second electromagnetic wave is selected from a range greater than 0 mW cm⁻² to 255 mW cm⁻²; and
wherein the power of the first electromagnetic wave is selected from a range from 0 W cm⁻² to 56 W cm⁻².

8. The optoelectronic system according to claim 6, wherein the neural network is configured to identify or determine the object providing or transmitting the first electromagnetic wave based on the spike train.

9. The optoelectronic system according to claim 1, further comprising:
a controller configured to move the object providing or transmitting the first electromagnetic wave such that the first electromagnetic wave from different portions of the object is provided to the optoelectronic device at different periods of time.

10. The optoelectronic system according to claim 1, further comprising:
a first electromagnetic source configured to emit the first electromagnetic wave; and
a second electromagnetic source configured to emit the second electromagnetic wave.

11. The optoelectronic system according to claim 1, wherein the neural network is a trained spiking neural network (SNN).

12. A method of forming an optoelectronic system, the method comprising:
providing an optoelectronic device for receiving a first electromagnetic wave of a first wavelength and a second electromagnetic wave of a second wavelength, the optoelectronic device comprising:
a substrate;
a first contact electrode over the substrate;
a second contact electrode over the substrate;
a first two-dimensional van der Waal material layer in contact with the first contact electrode; and
a second two-dimensional van der Waal material layer in contact with the second contact electrode, the second two-dimensional van der Waal material layer also forming a heterojunction with the first two-dimensional van der Waal material layer; and
coupling a neural network for identifying or determining an object providing or transmitting the first electromagnetic wave to the optoelectronic device.

13-14. (canceled)

15. The method according to claim 12,
wherein the optoelectronic device is configured such that the first electromagnetic wave provided to the optoelectronic device generates a first photoexcited current flowing in a first direction when the first contact electrode and the second electrode are at zero voltage bias; and
wherein the optoelectronic device is configured such that the second electromagnetic wave provided to the optoelectronic device generates a second photoexcited current flowing in a second direction opposite the first direction when the first contact electrode and the second electrode are at zero voltage bias.

16. (canceled)

17. The method according to a m claim 12,
wherein the optoelectronic device is configured to generate a spike train based on a portion of a time-domain transduction current (I_{DS}) waveform output above a threshold current (I_{TC}); and
wherein the time-domain transduction current (I_{DS}) waveform output is generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

18-21. (canceled)

22. A method of operating an optoelectronic system, the method comprising:
providing a first electromagnetic wave of a first wavelength and a second electromagnetic wave of a second wavelength different from the first wavelength to an optoelectronic device, the optoelectronic device comprising:
a substrate;
a first contact electrode over the substrate;
a second contact electrode over the substrate;
a first two-dimensional van der Waal material layer in contact with the first contact electrode; and
a second two-dimensional van der Waal material layer in contact with the second contact electrode, the second two-dimensional van der Waal material layer also forming a heterojunction with the first two-dimensional van der Waal material layer;
wherein the optoelectronic system also comprises a neural network for identifying or determining an object providing or transmitting the first electromagnetic wave; and
wherein the neural network is coupled to the optoelectronic device.

23. The method according to claim 22,
wherein the first electromagnetic wavelength is mid infrared (MIR) radiation; and
wherein the second electromagnetic wavelength is near infrared (NIR) radiation.

24. The method according to claim 22, further comprising:
biasing the first electrode and the second electrode at zero voltage such that the first electromagnetic wave provided to the optoelectronic device generates a first photoexcited current flowing in a first direction, and the second electromagnetic wave provided to the optoelectronic device generates a second photoexcited current flowing in a second direction opposite the first direction.

25. The method according to claim 24,
wherein the first photoexcited current flowing in the first direction is generated via a photothermoelectric (PTE) effect; and
wherein the second photoexcited current flowing in the second direction is generated via a photovoltaic (PV) effect.

26. The method according to claim 22,
wherein the optoelectronic device is configured to generate a spike train based on a portion of a time-domain transduction current (I_{DS}) waveform output above a threshold current (I_{TC}); and
wherein the time-domain transduction current (I_{DS}) waveform output is generated at the first electrode or the second electrode of the optoelectronic device upon the optoelectronic device simultaneously receiving the second electromagnetic wave in form of a plurality of optical pulses and the first electromagnetic wave in which a power of the first electromagnetic wave is above a predetermined spiking threshold.

27. The method according to am claim 22, further comprising:
moving the object providing or transmitting the first electromagnetic wave such that the first electromagnetic wave from different portions of the object is provided to the optoelectronic device at different periods of time.
